(19) United States
(12) Patent Application Publication
(10) Pub. No.: US 2020/0257027 A1
(43) Pub. Date: Aug. 13, 2020

(54) OPTICAL FILTER, SOLID-STATE IMAGING ELEMENT, AND ELECTRONIC APPARATUS

(71) Applicant: SONY CORPORATION, Tokyo (JP)

(72) Inventor: NOZOMI TAKIGUCHI, KANAGAWA (JP)

(21) Appl. No.: 15/781,553

(22) PCT Filed: Dec. 8, 2016
(86) PCT No.: PCT/JP2016/086617

§ 371 Date: Jun. 5, 2018

(30) Foreign Application Priority Data
Dec. 25, 2015 (JP) 2015-253068
May 12, 2016 (JP) 2016-096163

(51) Int. Cl. G02B 5/22; C09B 23/01; H01L 27/146; H04N 5/225

(52) U.S. Cl. CPC G02B 5/223; C09B 23/0066; H01L 27/1462; H04N 5/2254; H01L 27/14627; H01L 27/14645; H01L 27/14621

(57) ABSTRACT

An optical filter according to an embodiment of the present disclosure includes one or more kinds of squarylium compounds represented by the following general formula (1) or the following general formula (2).

### TECHNICAL FIELD

The present disclosure relates to an optical filter that is usable as, for example, an infrared cut filter, and to a solid-state imaging element and an electronic apparatus each of which includes the optical filter.

### BACKGROUND ART

An imaging device such as a video camera and a digital still camera typically includes a solid-state imaging element (image sensor) having a CCD (Charge Coupled Device) or CMOS (Complementary Metal Oxide Semiconductor) configuration. A CCD image sensor and a CMOS image sensor have sensitivity to a range from a near-ultraviolet wavelength band to a near-infrared wavelength band. In the imaging device, optical signals in wavelength bands other than a visible wavelength band for humans (a visible range; a wavelength from about 400 nm to about 700 nm) are regarded as noise components, which result in degradation in image quality. Hence, in a typical imaging device, an infrared cut filter is provided in front of a solid-state imaging element (a light entering direction) to remove light in the near-infrared wavelength band.

As the infrared cut filter, for example, PTL 1 discloses an absorptive infrared cut filter using a material that absorbs light in a infrared region. A cyanine-based compound, a phthalocyanine-based compound, and a squarylium-based compound each of which absorbs light in the infrared region are used as the material of the absorptive infrared cut filter. In particular, the squarylium-based compound has a steep absorption peak around 750 nm, for example, as described in PTL 2, and has attracted attention accordingly.

### CITATION LIST

### Patent Literature

PTL 1: International Publication No. WO2004/030628
PTL 2: Japanese Unexamined Patent Application Publication No. 2006-011225

### SUMMARY OF THE INVENTION

However, a squarylium dye has a slight absorption property in the visible region. It is therefore desirable to improve transparency to the visible region.

It is desirable to provide an optical filter, a solid-state imaging element, and an electronic apparatus each of which allows for improvement in transparency to the visible region.

An optical filter according to an embodiment of the present disclosure includes one or more kinds of squarylium compounds represented by the following general formula (1) or the following general formula (2).

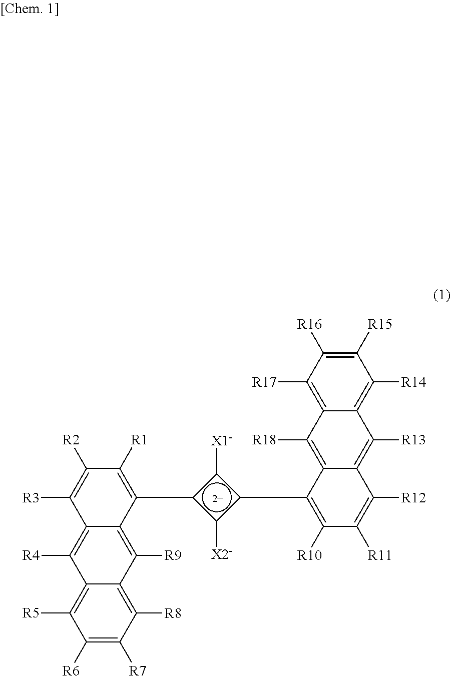

(where each of X1 and X2 is independently an oxygen atom or a dicyanomethylene (—C(CN)₂) group, each of R3 and R12 is independently a straight-chain or cyclic alkyl group having a carbon number of 1 to 8 both inclusive or a derivative thereof, each of R4, R5, R13, and R14 is independently a hydrogen atom, a straight-chain or cyclic alkyl group having a carbon number of 1 to 10 both inclusive, or a derivative thereof, each of R1, R2, R6 to R11, and R15 to R18 is independently a hydrogen atom, a halogen atom, a straight-chain, branched, or cyclic alkyl group, a phenyl group, a group having a straight-chain or condensed ring aromatic compound, a group having a halide, a partial fluoroalkyl group, a perfluoroalkyl group, a silylalkyl group, a silyl alkoxy group, an arylsilyl group, an arylsulfanyl group, an alkylsulfanyl group, an arylsulfonyl group, an alkylsulfonyl group, an arylsulfide group, an alkylsulfide group, an amino group, an alkylamino group, an arylamino group, a hydroxy group, an alkoxy group, an acylamino group, an acyloxy group, a carbonyl group, a carboxy group, a carboxyamide group, a carboalkoxy group, an acyl group, a sulfonyl group, a cyano group, a nitro group, a group having a chalcogenide, a phosphine group, a phosphone group, or a derivative thereof.)

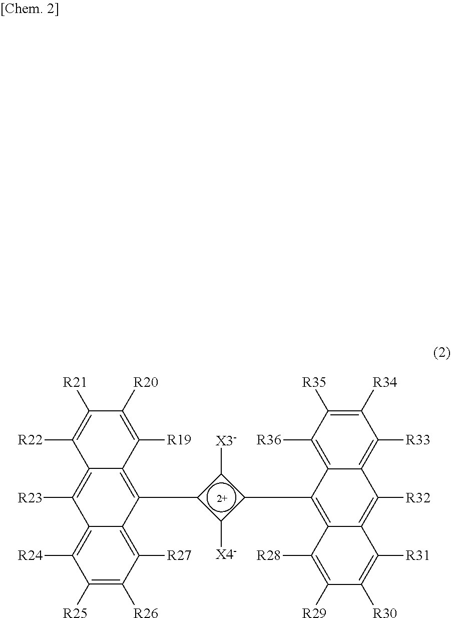

(where each of X3 and X4 is independently an oxygen atom or a dicyanomethylene (—C(CN)₂) group, each of R20 to R22, R24 to R26, R29 to R31, and R33 to R35 is independently a hydrogen atom, or a straight-chain or cyclic alkyl group having a carbon number of 1 to 10 both inclusive or a derivative thereof, each of R23 and R32 is independently a straight-chain or cyclic alkyl group having a carbon number of 1 to 10 both inclusive or a derivative thereof, each of R19, R27, R28, and R36 is independently an hydrogen atom, a halogen atom, a straight-chain, branched, or cyclic alkyl group, a phenyl group, a group having a straight-chain or condensed ring aromatic compound, a group having a halide, a partial fluoroalkyl group, a perfluoroalkyl group, a silylalkyl group, a silyl alkoxy group, an arylsilyl group, an arylsulfanyl group, an alkylsulfanyl group, an arylsulfonyl group, an alkylsulfonyl group, an arylsulfide group, an alkylsulfide group, an amino group, an alkylamino group, an arylamino group, a hydroxy group, an alkoxy group, an acylamino group, an acyloxy group, a carbonyl group, a carboxy group, a carboxyamide group, a carboalkoxy group, an acyl group, a sulfonyl group, a cyano group, a nitro group, a group having a chalcogenide, a phosphine group, a phosphone group, or a derivative thereof.)

A solid-state imaging element according to an embodiment of the present disclosure includes a photoelectric converter, an on-chip lens provided on the photoelectric converter, and the foregoing optical filter according to the embodiment of the present disclosure.

An electronic apparatus according to an embodiment of the present disclosure includes the foregoing solid-state imaging element according to the embodiment of the present disclosure.

In the optical filter according to the embodiment of the present disclosure, the solid-state imaging element according to the embodiment of the present disclosure, and the electronic apparatus according to the embodiment of the present disclosure, one or more kinds of the squarylium compounds represented by the foregoing general formula (1) or the foregoing general formula (2) are included. This reduces absorption characteristics in a visible region.

According to the optical filter of the embodiment of the present disclosure, the solid-state imaging element of the embodiment of the present disclosure, and the electronic apparatus of the embodiment of the present disclosure, one or more kinds of the squarylium compounds represented by the foregoing general formula (1) or the foregoing general formula (2) are included, which makes it possible to reduce absorption characteristics in the visible region and improve transparency in the visible region. Accordingly, it is possible to provide a solid-state imaging element and an electronic apparatus each of which has high optical characteristics.

It is to be noted that effects described herein are not necessarily limited, and any of effects described in the present disclosure may be included.

### BRIEF DESCRIPTION OF THE DRAWINGS

FIG. 1 is a schematic view of an example of a cross-sectional configuration of a solid-state imaging element according to a first embodiment of the present disclosure.

FIG. 2 is a schematic view of another example of the cross-sectional configuration of the solid-state imaging element according to the first embodiment of the present disclosure.

FIG. 3 is a light absorption characteristic diagram of a typical squarylium-based compound.

FIG. 4 is a light absorption characteristic diagram of a squarylium-based compound of the present disclosure.

FIG. 5 is a schematic view of a cross-sectional configuration of a solid-state imaging element according to a modification example 1 of the present disclosure.

FIG. 6 is a schematic view of a cross-sectional configuration of a solid-state imaging element according to a modification example 2 of the present disclosure.

FIG. 7 is a schematic view of a cross-sectional configuration of a solid-state imaging element according to a modification example 3 of the present disclosure.

FIG. 8 is a schematic view of a cross-sectional configuration of a solid-state imaging element according to a modification example 4 of the present disclosure.

FIG. 9 is a schematic view of a cross-sectional configuration of a reversible recording medium according to a second embodiment of the present disclosure.

FIG. 10 is a plan view of an entire configuration of an imaging device according to an application example 1.

FIG. 11 is a block diagram illustrating an entire configuration according to an application example 2 (an electronic apparatus).

FIG. 12 is a block diagram illustrating an entire configuration according to an application example 3 (a plasma display unit).

FIG. 13 is a light absorption characteristic diagram at respective wavelengths in experimental examples 1 to 6.

### MODES FOR CARRYING OUT THE INVENTION

In the following, some embodiments of the present disclosure are described in detail with reference to the drawings. It is to be noted that description is given in the following order.

1. First Embodiment (an example in which an infrared absorption layer is provided on an on-chip lens)

1-1. Configuration of Solid-state Imaging Element

1-2. Operation of Solid-state Imaging Element

1-3. Workings and Effects

### 2. Modification Examples

2-1. Modification Example 1

2-2. Modification Example 2

2-3. Modification Example 3

2-4. Modification Example 4

3. Second Embodiment (an example in which a squarylium compound is used as a photothermal conversion material)

3-1. Configuration of Reversible Recording Medium

3-2. Workings and Effects

### 4. Application Examples

### 5. Examples

### 1. FIRST EMBODIMENT

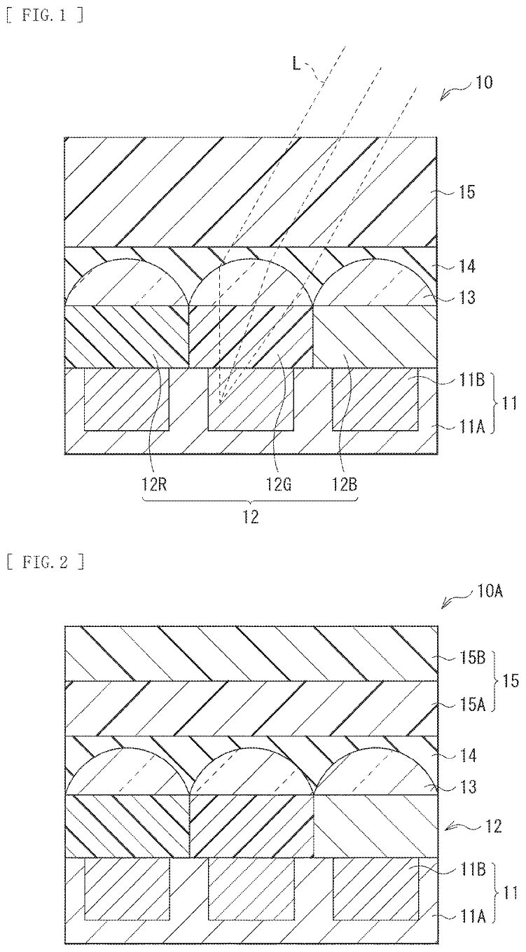

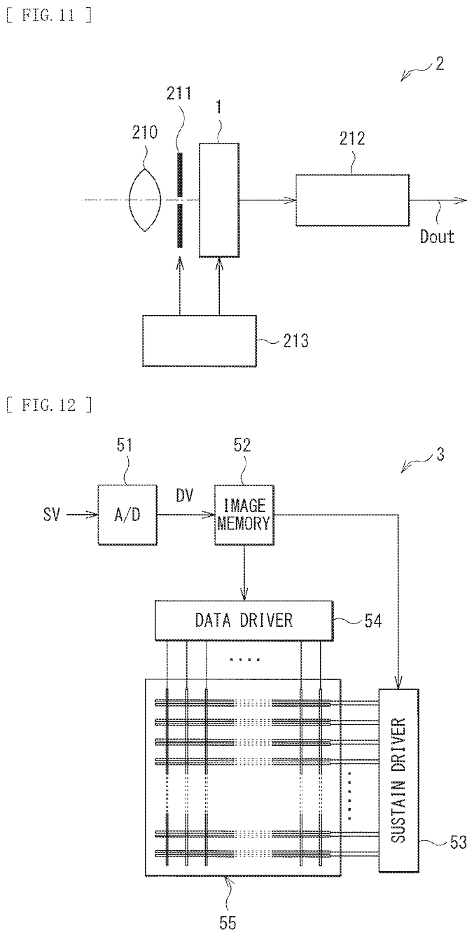

FIG. 1 illustrates a cross-sectional configuration of a solid-state imaging element (a solid-state imaging element 10) according to a first embodiment of the present disclosure. The solid-state imaging element 10 configures one pixel (for example, a unit pixel P) of an imaging device (for example, a solid-state imaging device 1) such as a CCD image sensor or a CMOS image sensor (both refer to FIG. 10). The solid-state imaging element 10 has a configuration in which a color filter layer 12, an on-chip lens 13, a planarization layer 14, and an infrared absorption layer 15 are stacked in this order on a photoelectric conversion layer 11 in which a photoelectric converter 11B is formed. In the present embodiment, the infrared absorption layer 15 is formed using a squarylium compound, and the squarylium compound is a compound in which first and third sites of a squaric acid are substituted by an anthracene derivative.

### 1-1. Configuration of Solid-State Imaging Element

The photoelectric conversion layer 11 detects incident light as an electrical signal, and a plurality of photoelectric converters 11B are formed in a substrate 11A including, for example, silicon (Si), etc. A configuration of the photoelectric conversion layer 11 is not particularly limited, and may adopt a CCD configuration, a CMOS configuration, etc. The photoelectric converters 11B may be arranged one-dimensionally (linearly) or two-dimensionally (in rows and columns).

The color filter layer 12 includes, for example, a red filter 1 that allows light in a red wavelength region to pass therethrough, a green filter 12G that allows light in a green wavelength region to pass therethrough, and a blue filter 12B that allows light in a blue wavelength region to pass therethrough. These color filters (the red filter 12R, the green filter 12B, and the blue filter 12B) are arranged regularly (for example, in a Bayer arrangement). Providing such a color filter layer 12 makes it possible for a solid-state imaging device 1 to obtain light reception data of colors corresponding to the color arrangement. It is to be noted that wavelengths that pass through the respective color filters 12R, 12B, and 12B are not limited to three colors of red, green, and blue mentioned above, and are selectable as appropriate in accordance with specifications, etc. of the solid-state imaging element. Moreover, materials that form the red filter 12R, the green filter 12B, and the blue filter 12B are not particularly limited, and it is possible to use a known material for each of the color filters 12R, 12B, and 12B.

The red filter 12R, the green filter 12G, and the blue filter 12B are provided on the respective corresponding photoelectric converters 11B. Thus, light in specific wavelength regions having passed through each of the color filters 12R, 12B, and 12B enters the respective photoelectric converters 11B. Outputs of the photoelectric converters 11B each have intensity of light having passed through each of the color filters 12R, 12B, and 12B.

Moreover, the color filter layer 12 may have a maximal absorption wavelength in an infrared wavelength region (for example, from 600 nm to 1500 nm both inclusive). Providing infrared absorption ability to the color filter layer 12 in addition to an infrared absorption layer 15 to be described later makes it possible to further improve infrared light removal performance. To provide infrared absorption ability to the color filter layer 12, it is only necessary for each of the color filters 12R, 12B, and 12B to include, for example, a material that absorbs infrared light (an infrared light absorption material).

Examples of the infrared light absorption material include KCuPO₄, a compound, such as iron oxide and tungsten oxide, including a transition metal belonging to the fourth period of the periodic table, an conductive oxide such as indium tin oxide (ITO), a diimmonium compound, an anthraquinone compound, an cyanine compound, a phthalocyanine compound, an azo complex, a Ni complex, a Co complex, a Cu complex, a Fe complex, a pyrrolopyrrole compound, a thiourea compound, and acetylene polymer, in addition to the squarylium compound that configures the infrared absorption layer 15 to be described later and in which first and third sites of a squaric acid are substituted by an anthracene derivative. In particular, the squarylium compound, the compound including the transition metal, the conductive oxide, the phthalocyanine compound, the azo complex, the Ni complex, the Co complex, the Cu complex, the Fe complex, and the pyrrolopyrrole compound among these infrared light absorption materials are preferably used in terms of heat resistance.

It is to be noted that the color filter layer 12 is provided on an as-needed basis, and in a case where an monochrome image is obtained from an output of each of the photoelectric converters 11B, the color filter layer 12 is unnecessary. In a case where the color filter layer 12 is not provided, the on-chip lens 13 may be stacked directly on the photoelectric conversion layer 11, or may be stacked on the photoelectric conversion layer 11 with some layer in between.

The on-chip lens 13 has light transparency, and concentrates incident light toward the photoelectric converters 11B. The on-chip lens 13 is formed using, for example, a high refractive index material having a refractive index higher than 1.5. Examples of such a material include inorganic materials such as silicon oxide (SiO₂) and silicon nitride (SiN). Alternatively, an organic high refractive index material such as an episulfide-based resin, a thietane compound, and a resin thereof may be used. Moreover, in addition thereto, using a metal thietane compound or a polymerizable composition including the metal thietane compound makes it possible to further raise the refractive index of the on-chip lens 13. Further, adding, to these resins, an oxide or nitride, such as TiO₂, ZrO₂, Ta₂O₅, Nb₂O₅, ZnO, and Si₃N₄, having a refractive index of about 2 to about 2.5 makes it possible to form the on-chip lens 13 having a higher refractive index.

A shape of the on-chip lens 13 is not particularly limited, and it is possible to use any of various lens shapes such as a semispherical shape and a semicylindrical shape. The on-chip lens 13 is provided for each of the photoelectric converters 11B as illustrated in FIG. 1, and has a same shape. Herein, “same” means manufacturing with use of a same material by a same process; however, variations caused by various conditions during manufacturing are not eliminated. Moreover, one on-chip lens 13 may be provided for a plurality of photoelectric converters 11B.

For example, it is possible to form the on-chip lens 13 by forming a resist film having a lens shape on a lens material film, and thereafter performing an etch back process on the resist film. Alternatively, the on-chip lens 13 may be formed, for example, by pattern-processing a photosensitive resin film by photolithography technology and thereafter deforming the photosensitive resin film into a lens shape by a reflow process.

The planarization layer 14 covers projections and depressions formed by the on-chip lens 13 to planarize a surface. As a material forming the planarization layer 14, a low refractive index material having light transparency and a lower refractive index than the refractive index of the on-chip lens 13 is preferably used. Through the use of such a material, light having entered the on-chip lens 13 from the planarization layer 14 is refracted at an interface between the planarization layer 14 and the on-chip lens 13 to be concentrated onto the photoelectric converter 11B corresponding to each of the on-chip lenses 13.

The refractive index of the planarization layer 14 is desirably smaller than that of the on-chip lens 13, and in terms of a lens effect by the on-chip lens 13, a larger difference in refractive index between the planarization layer 14 and the on-chip lens 13 is preferable. Examples of the low-refractive index material forming the planarization layer 14 include porous silica (having a refractive index n≤1.2), a fluorine compound (having a refractive index n≤1.2) such as MgF, and a silicone-based resin (having a refractive index n=1.3 to 1.4). A film thickness in a staking direction (hereinafter simply referred to as thickness) of the planarization layer 14 is, for example, but not limited to, from about 10 nm to about 2 μm, and a thinner thickness is preferable.

The infrared absorption layer 15 removes an infrared light component included in light entering the photoelectric converter 11B, and is provided, for example, on the planarization layer 14. The infrared absorption layer 15 includes an infrared light absorption material, and is formed including one or more kinds of squarylium compounds, represented by the following general formula (1) and the following general formula (2), in which first and third sites of a squaric acid mother nucleus forming a squarylium molecule are substituted by an anthracene derivative. The infrared absorption layer 15 that selectively absorbs infrared light is formed with use of the squarylium compound represented by the general formula (1) or the general formula (2).

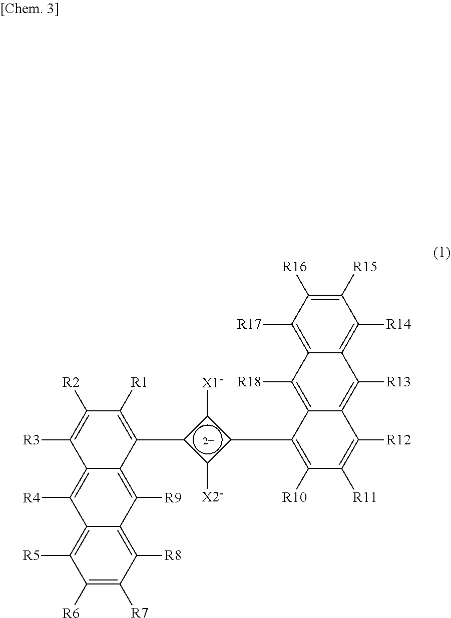

(where each of X1 and X2 is independently an oxygen atom or a dicyanomethylene (—C(CN)₂) group, each of R3 and R12 is independently a straight-chain or cyclic alkyl group having a carbon number of 1 to 8 both inclusive or a derivative thereof, each of R4, R5, R13, and R14 is independently a hydrogen atom, a straight-chain or cyclic alkyl group having a carbon number of 1 to 10 both inclusive, or a derivative thereof, each of R1, R2, R6 to R11, and R15 to R18 is independently a hydrogen atom, a halogen atom, a straight-chain, branched, or cyclic alkyl group, a phenyl group, a group having a straight-chain or condensed ring aromatic compound, a group having a halide, a partial fluoroalkyl group, a perfluoroalkyl group, a silylalkyl group, a silyl alkoxy group, an arylsilyl group, an arylsulfanyl group, an alkylsulfanyl group, an arylsulfonyl group, an alkylsulfonyl group, an arylsulfide group, an alkylsulfide group, an amino group, an alkylamino group, an arylamino group, a hydroxy group, an alkoxy group, an acylamino group, an acyloxy group, a carbonyl group, a carboxy group, a carboxyamide group, a carboalkoxy group, an acyl group, a sulfonyl group, a cyano group, a nitro group, a group having a chalcogenide, a phosphine group, a phosphone group, or a derivative thereof.)

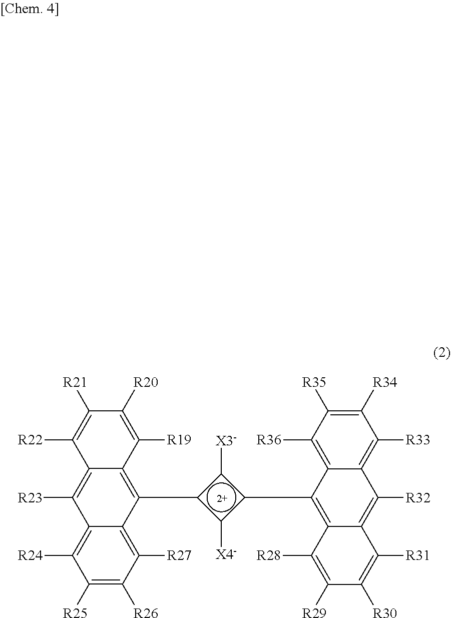

(where each of X3 and X4 is independently an oxygen atom or a dicyanomethylene (—C(CN)₂) group, each of R20 to R22, R24 to R26, R29 to R31, and R33 to R35 is independently a hydrogen atom, or a straight-chain or cyclic alkyl group having a carbon number of 1 to 10 both inclusive or a derivative thereof, each of R23 and R32 is independently a straight-chain or cyclic alkyl group having a carbon number of 1 to 10 both inclusive or a derivative thereof, each of R19, R27, R28, and R36 is independently an hydrogen atom, a halogen atom, a straight-chain, branched, or cyclic alkyl group, a phenyl group, a group having a straight-chain or condensed ring aromatic compound, a group having a halide, a partial fluoroalkyl group, a perfluoroalkyl group, a silylalkyl group, a silyl alkoxy group, an arylsilyl group, an arylsulfanyl group, an alkylsulfanyl group, an arylsulfonyl group, an alkylsulfonyl group, an arylsulfide group, an alkylsulfide group, an amino group, an alkylamino group, an arylamino group, a hydroxy group, an alkoxy group, an acylamino group, an acyloxy group, a carbonyl group, a carboxy group, a carboxyamide group, a carboalkoxy group, an acyl group, a sulfonyl group, a cyano group, a nitro group, a group having a chalcogenide, a phosphine group, a phosphone group, or a derivative thereof.)

Moreover, one or both of R1 and R10 in the general formula (1) are preferably independently a group that is able to form a hydrogen bond in a molecule. One or more of R19, R27, R28, and R36 in the general formula (2) are preferably independently a group that is able to form a hydrogen bond in a molecule. Examples of such a group include a hydroxy (—OH) group, an amino (—NH₂) group, amide (—C(═O)—NR37R38, where each of R37 and R38 is independently a hydrogen atom or an alkyl group). Heat resistance of the infrared absorption layer 15 is improved with use of a squarylium compound in which one or both of R1 and R10 of the squarylium compound represented by the general formula (1) or one or more of R19, R27, R28, and R36 of the squarylium compound represented by the general formula (2) are substituted by a group that is able to form a hydrogen bond in a molecule.

Moreover, each of R3 and R12 in the general formula (1) and R23 and R32 in the general formula (2) is preferably independently a group having a higher electron donation property than hydrogen (H). The group having a higher electron donation property than hydrogen (H) is, for example, a straight-chain, branched, or cyclic alkyl group, a phenyl group, a group having a straight-chain or condensed ring aromatic compound, an amino group, an alkylamino group, an arylamino group, an alkoxy group, or a derivative thereof. It is to be noted that the number of carbons in an alkyl chain is desirably from 1 to 10 both inclusive. This reduces difficulty in synthesis of a squarylium compound having the foregoing configuration.

Examples of such a squarylium compound, e.g. the squarylium compound represented by the general formula (1) include squarylium compounds, as represented by the following formulas (1-1) to (1-47), having a symmetric structure in which oxygen atoms are provided at second and fourth sites (X1 and X2) of a squaric acid and anthracene derivatives having a same molecular structure are bonded to first and third sites.

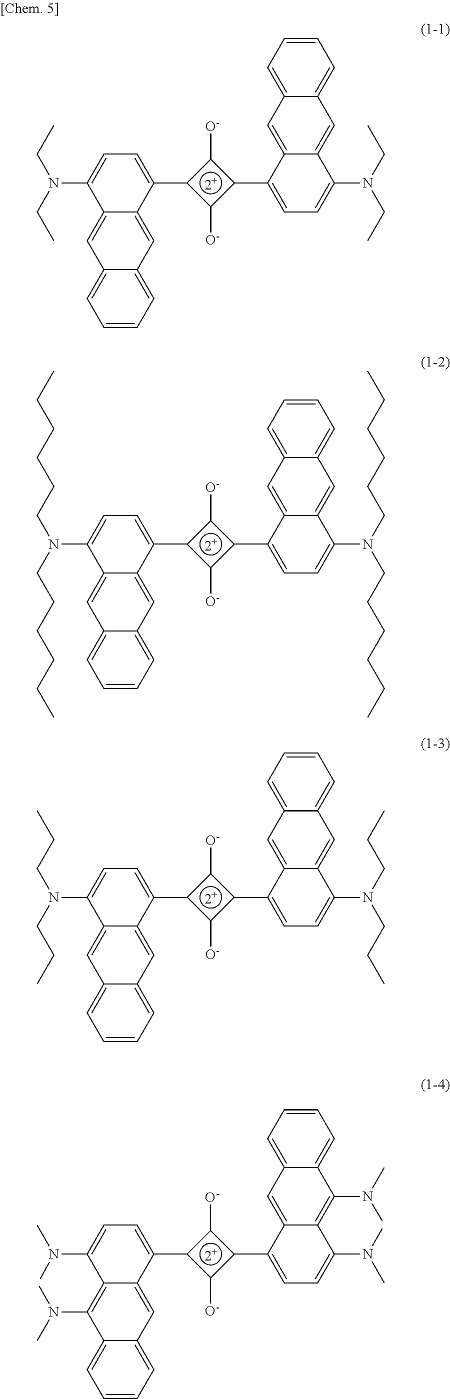

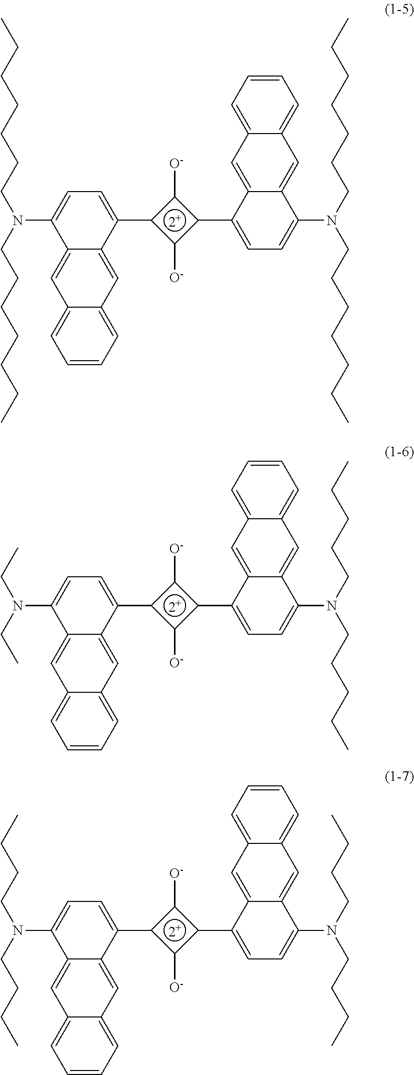

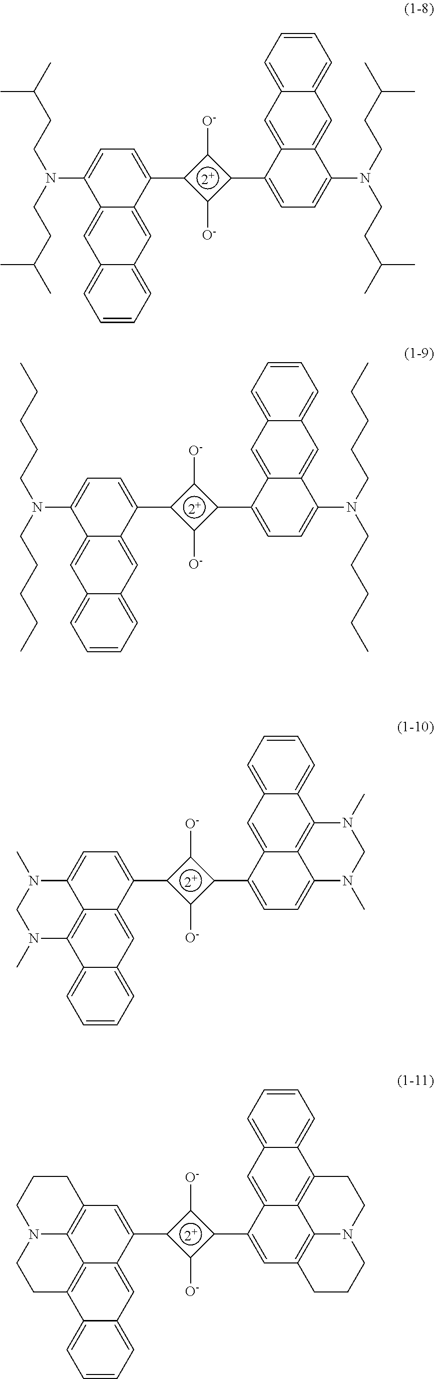

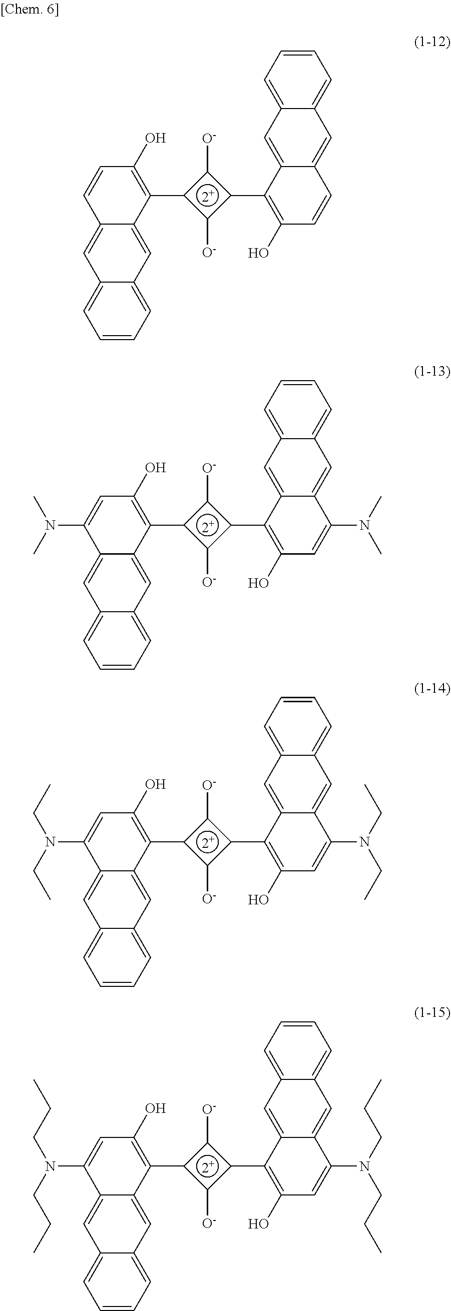

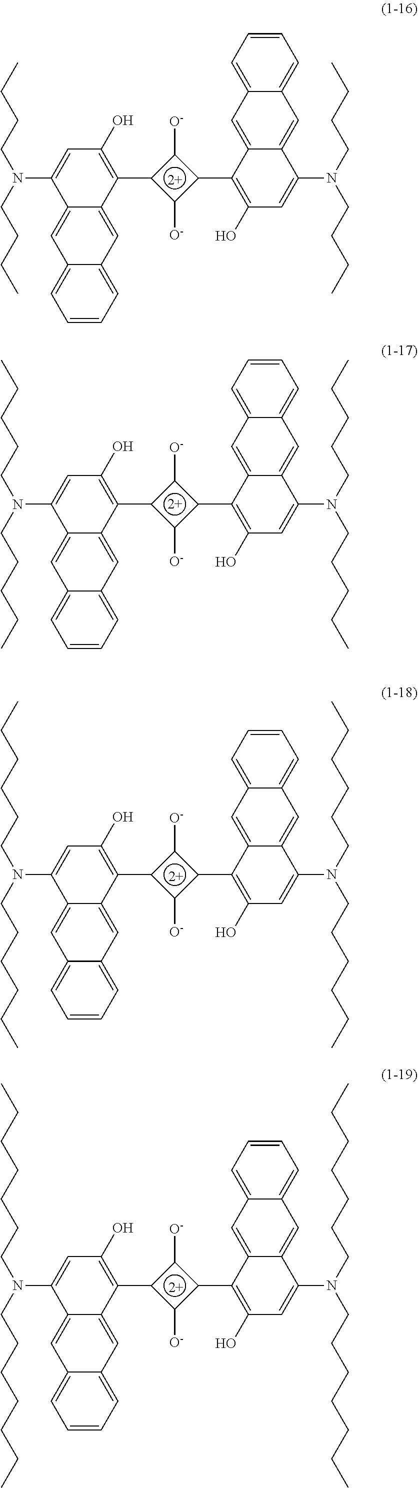

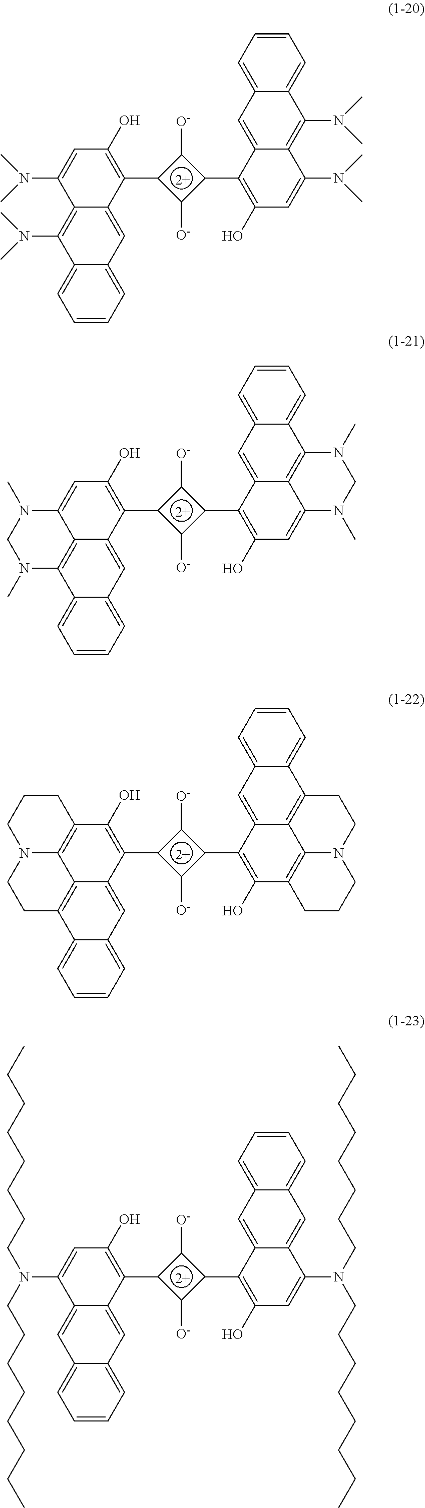

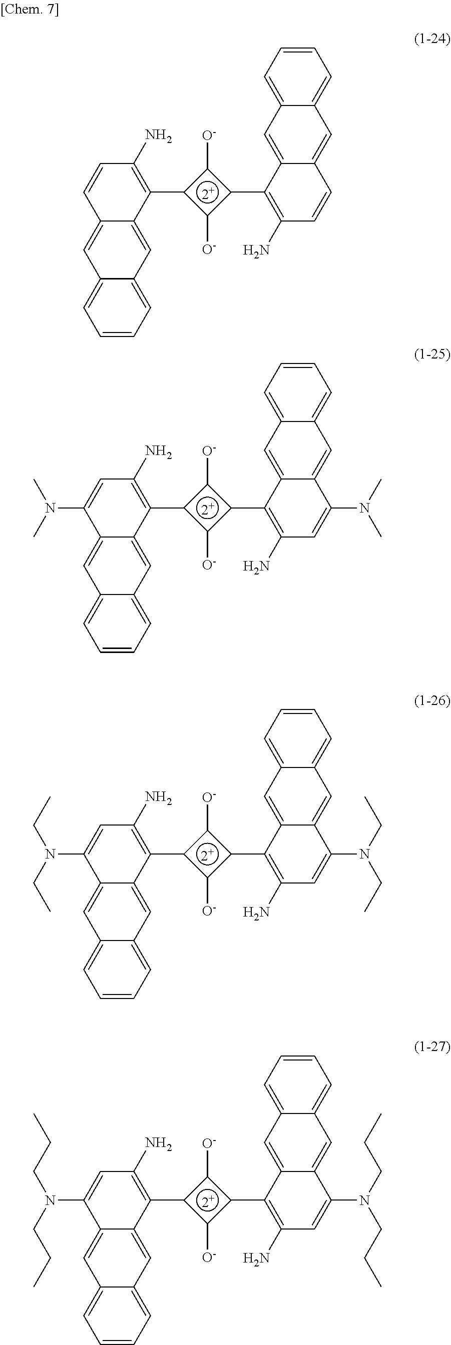

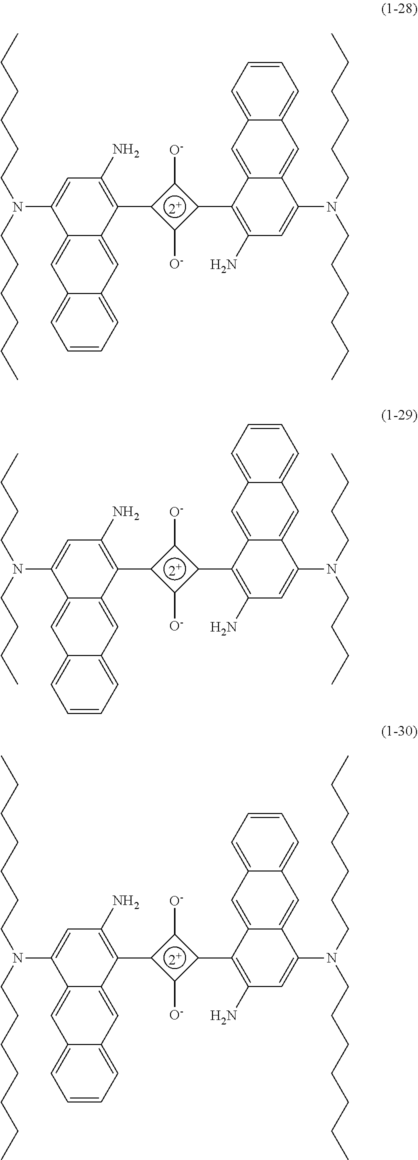

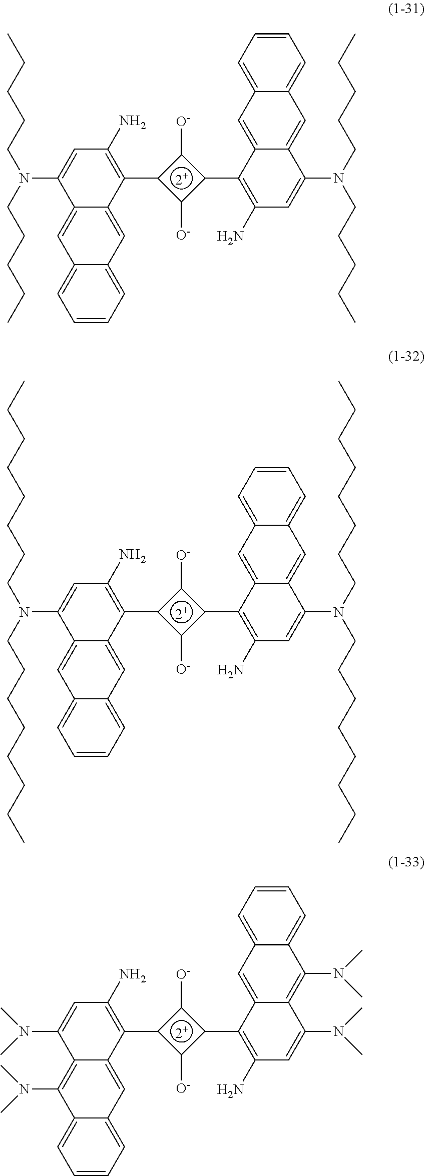

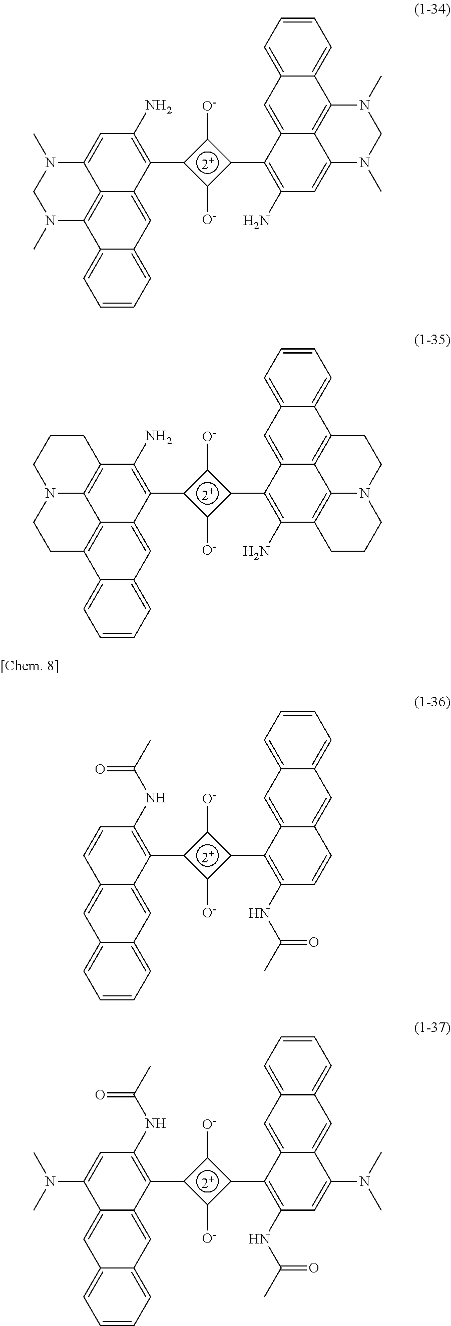

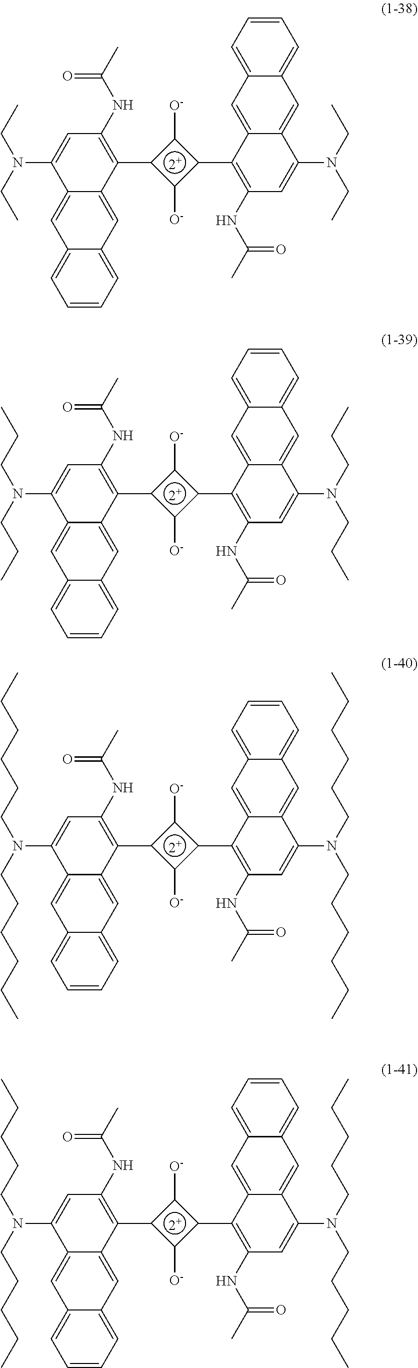

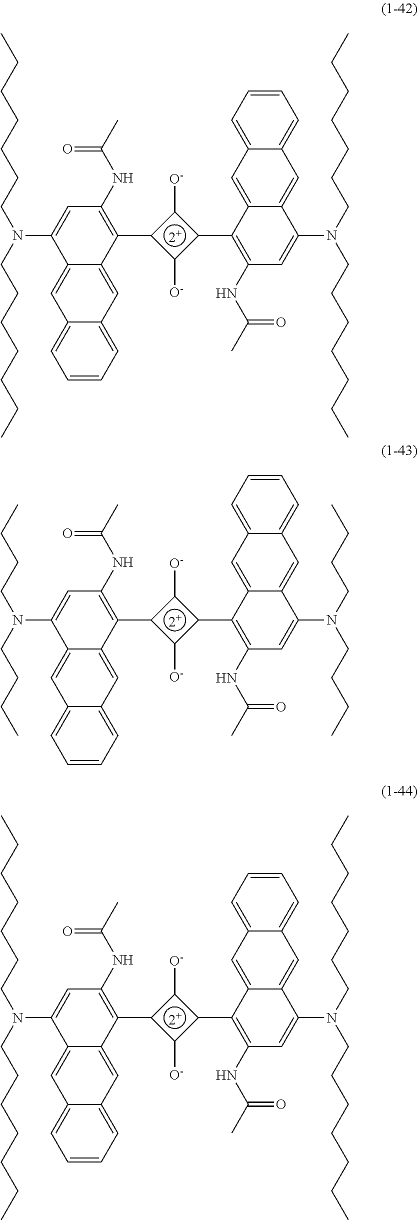

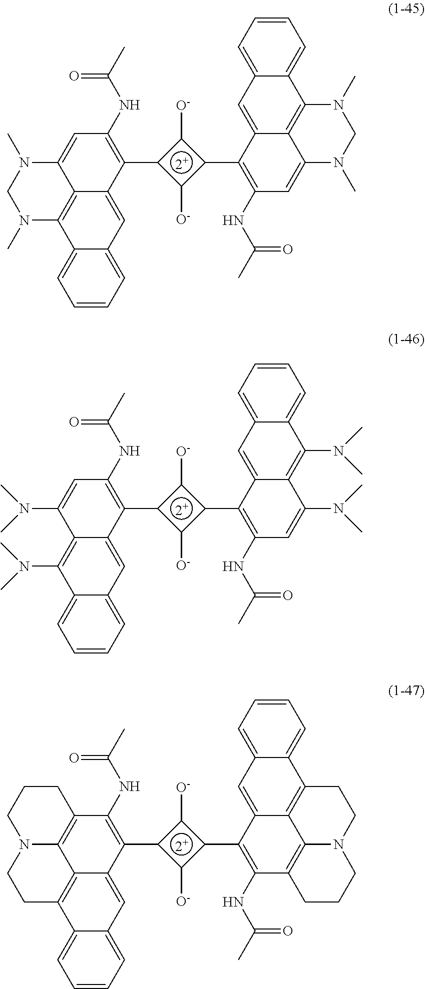

Moreover, the squarylium compound is not necessarily the squarylium compound having the symmetric structure, and a squarylium compound having an asymmetric structure in which anthracene backbone parts of the squarylium compounds represented by the formulas (1-1) to (1-47) are combined as appropriate may be used. Examples thereof include squarylium compounds represented by the following formulas (1-48) to (1-54).

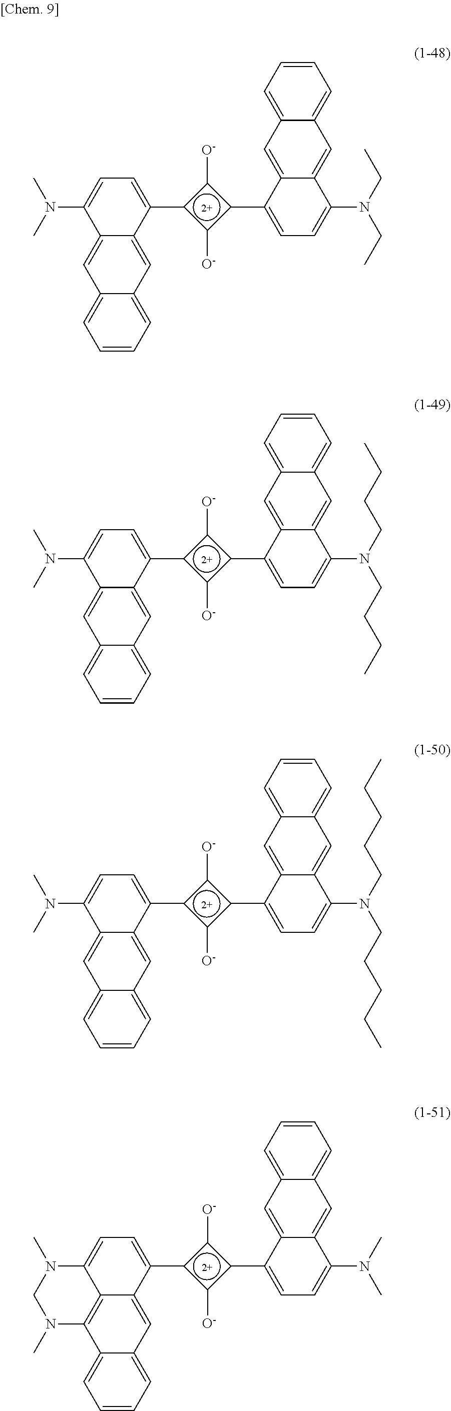

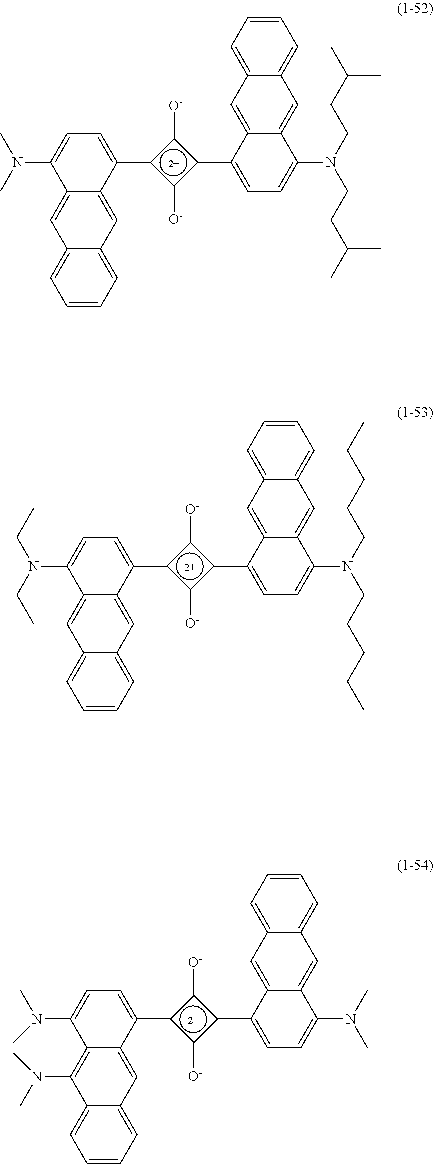

Further examples thereof include squarylium compounds, as represented by the following formulas (2-1) to (2-47), having a symmetric structure in which one of second and fourth sites (X1 and X2) of a squaric acid is substituted by a dicyanomethylene group, and anthracene derivatives having a same molecular structure are bonded to first and third sites.

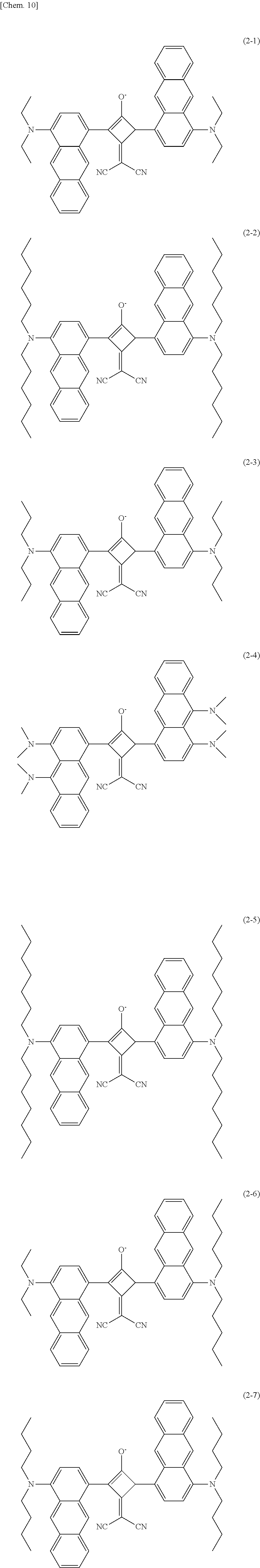

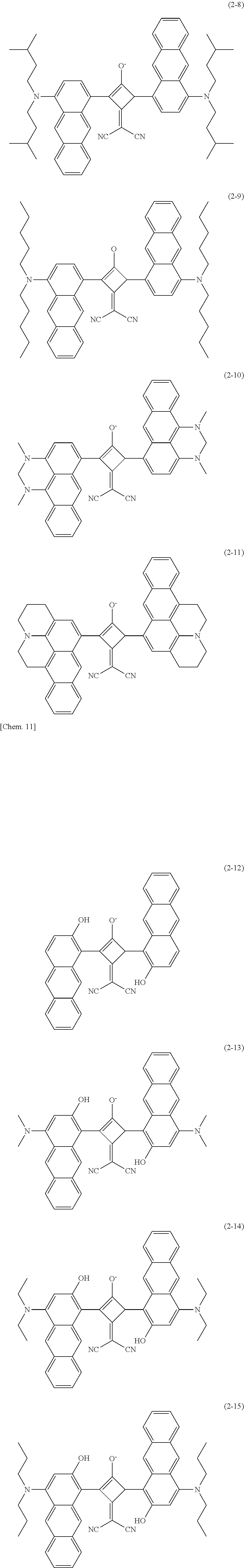

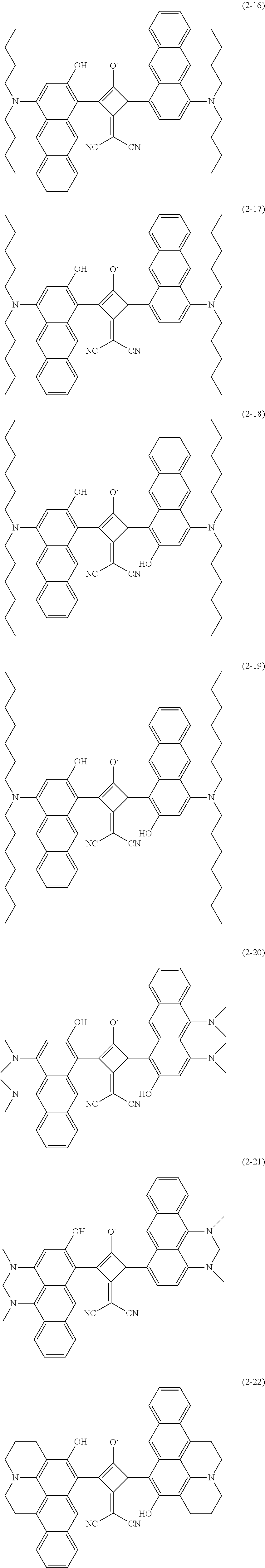

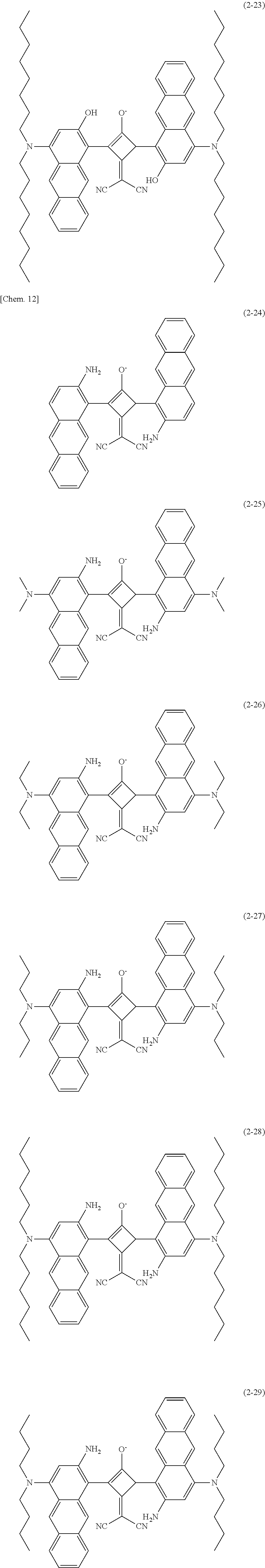

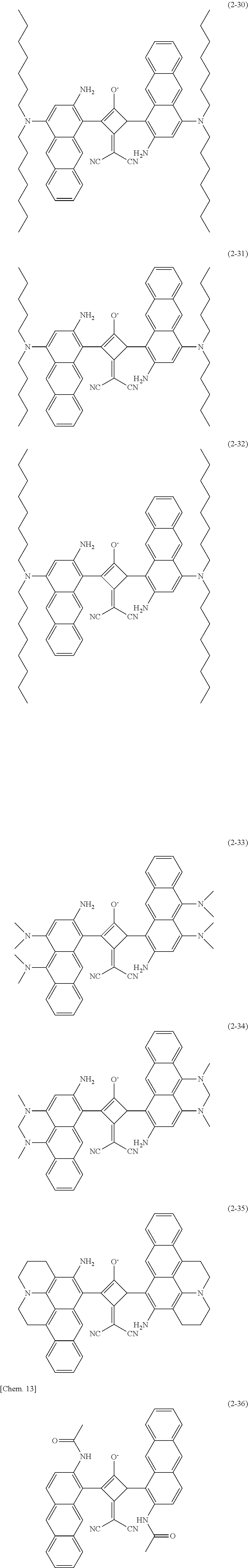

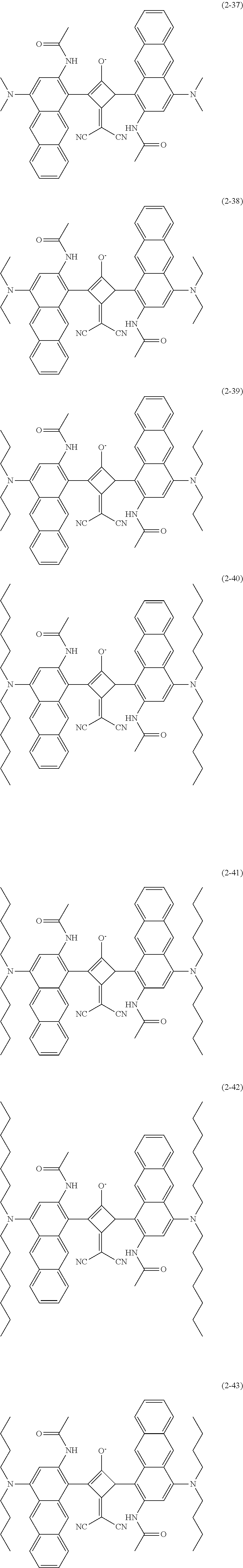

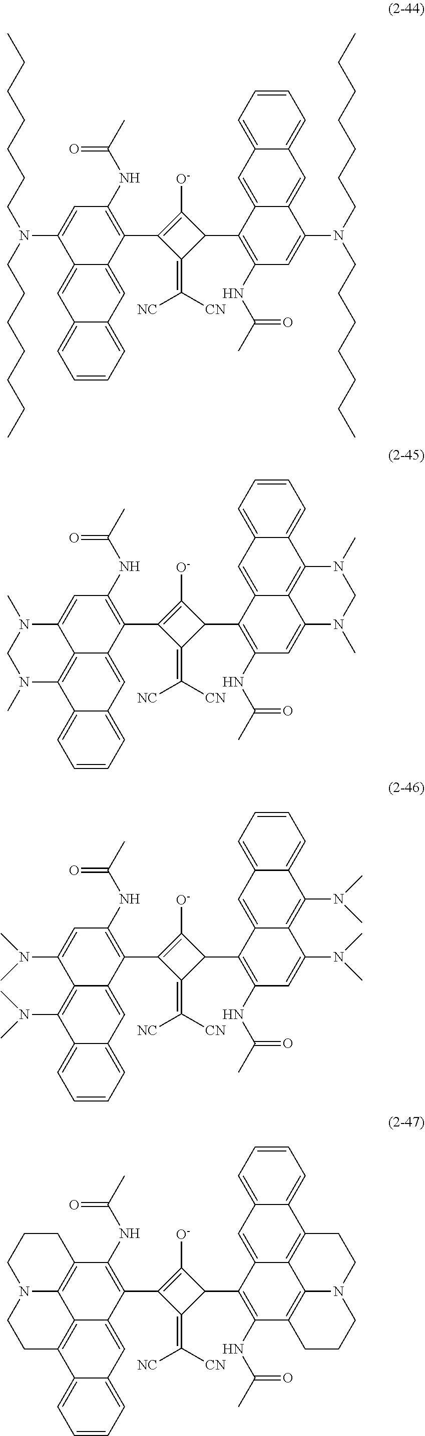

Furthermore, these squarylium compounds in which one of the second and fourth sites (X1 and X2) of the squaric acid is substituted by a dicyanomethylene group may also have an asymmetric structure in addition to the symmetric structure. Examples thereof include squarylium compounds represented by the following formulas (2-48) to (2-54).

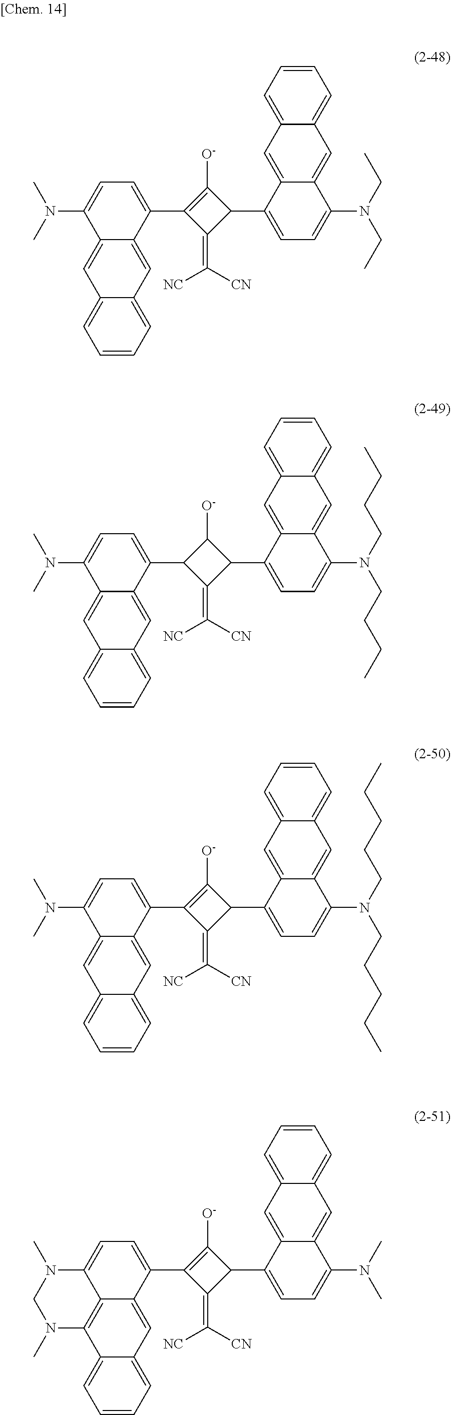

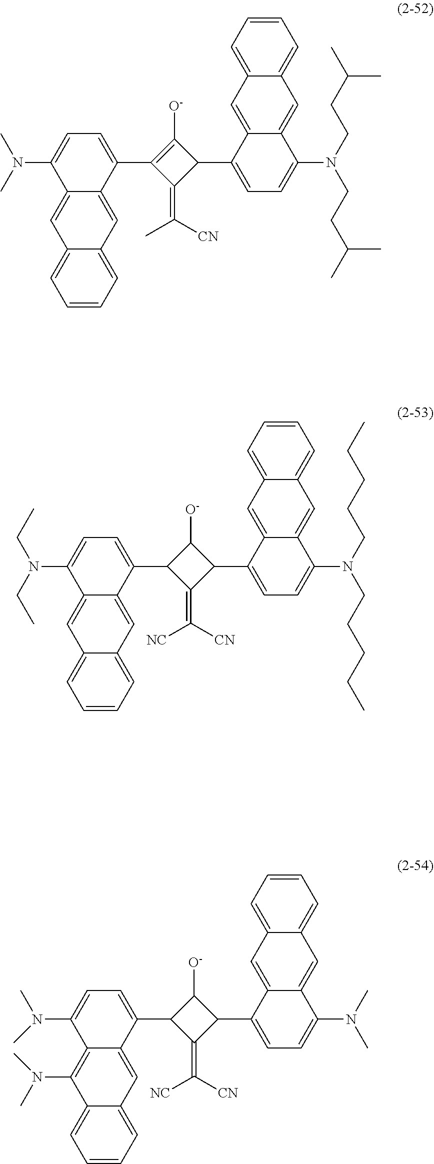

In addition, examples of the squarylium compound represented by the general formula (2) include squarylium compounds, as represented by the following formulas (3-1) to (3-54), having a symmetric structure in which oxygen atoms are provided at second and fourth sites (X3 and X4) of a squaric acid and anthracene derivatives having a same molecular structure are bonded to first and third sites.

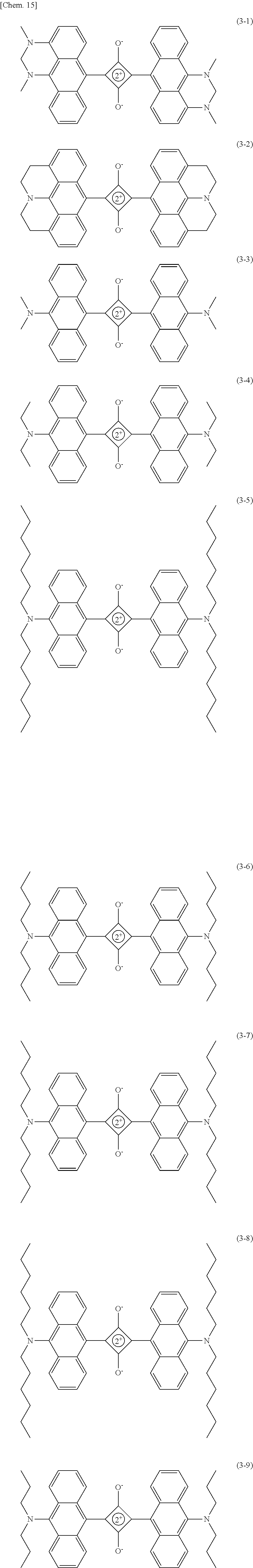

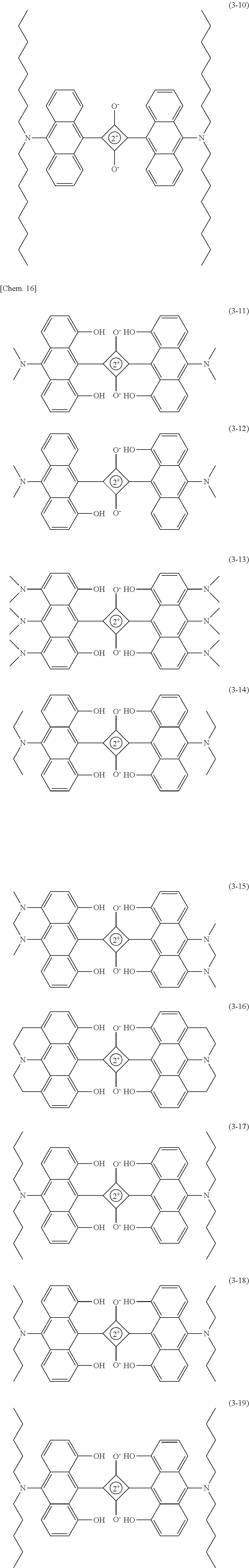

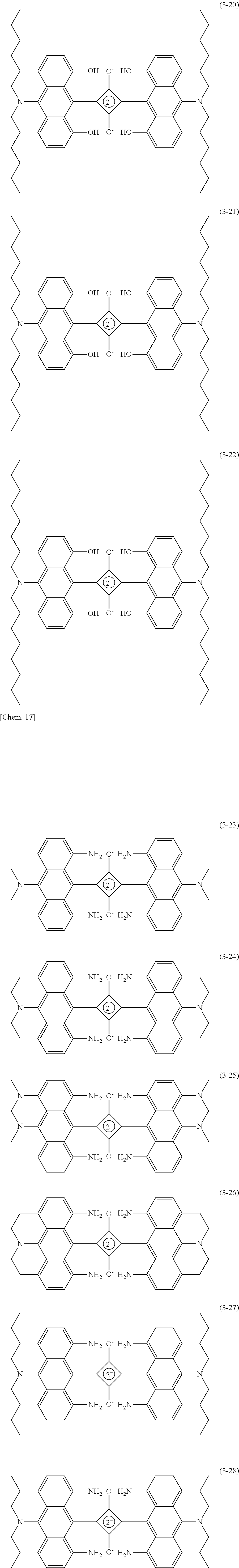

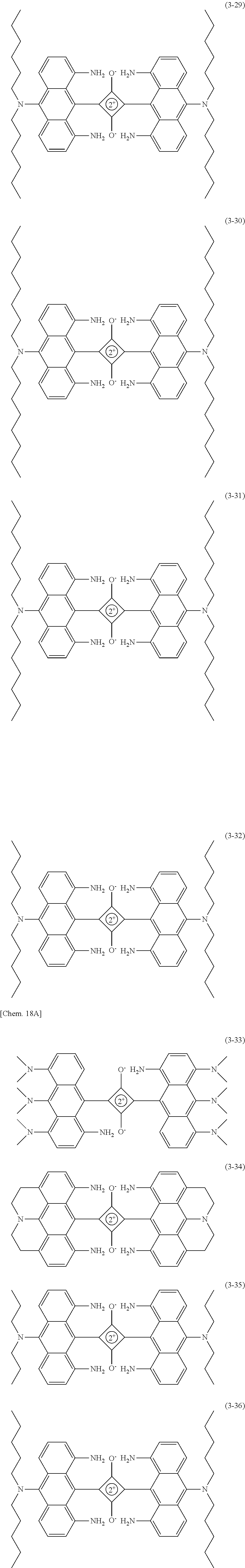

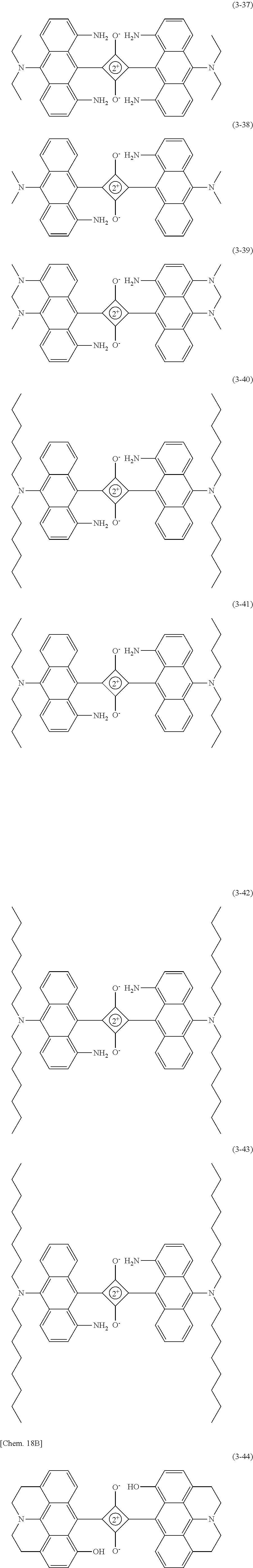

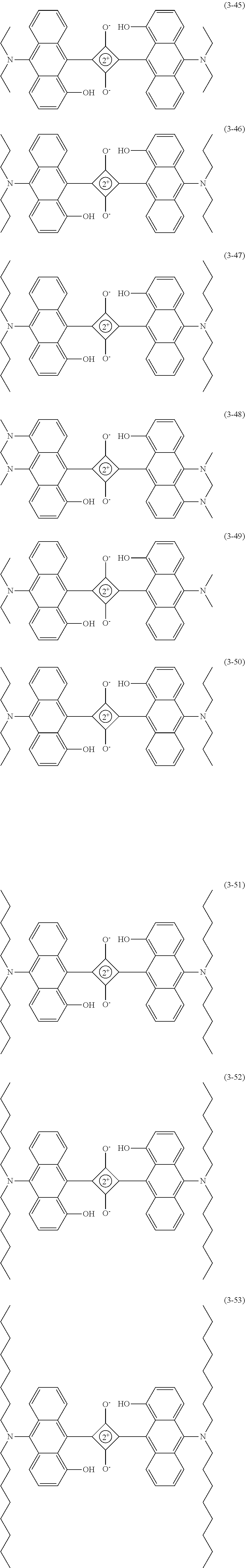

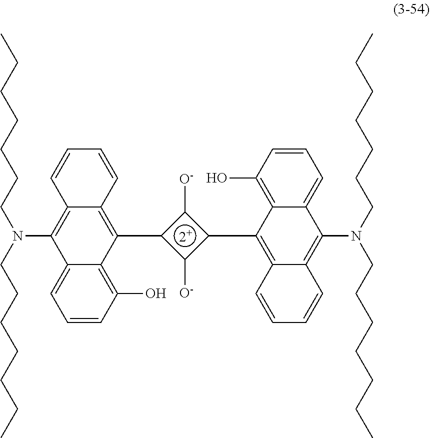

Moreover, the squarylium compound is not necessarily the squarylium compound having the symmetric structure, and a squarylium compound having an asymmetric structure in which anthracene backbone parts of squarylium compounds represented by the formulas (3-1) to (3-54) are combined as appropriate may be used. Examples thereof include squarylium compounds represented by the following formulas (3-55) to (1-132).

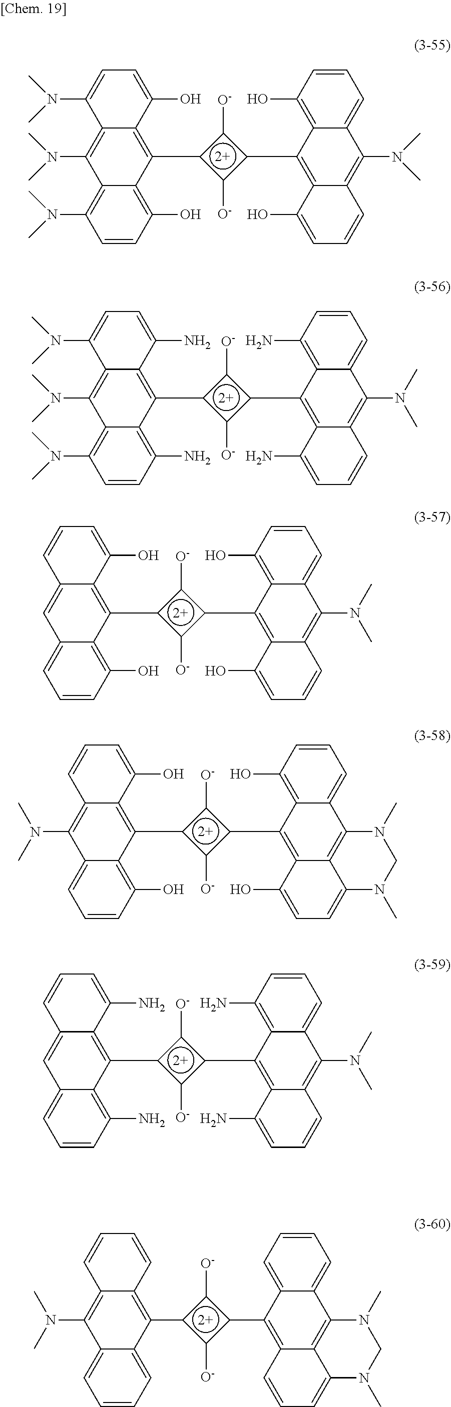

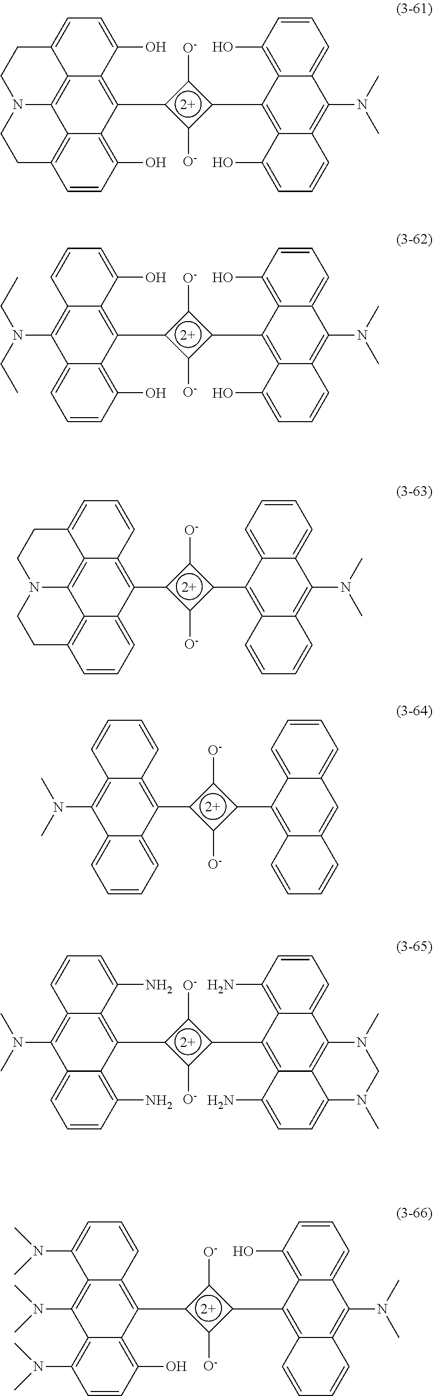

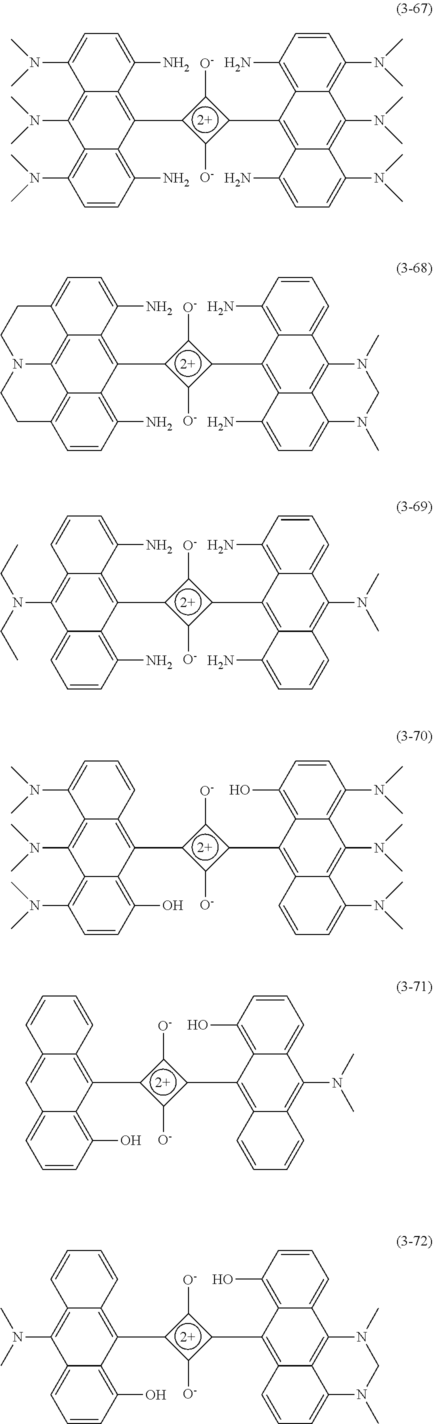

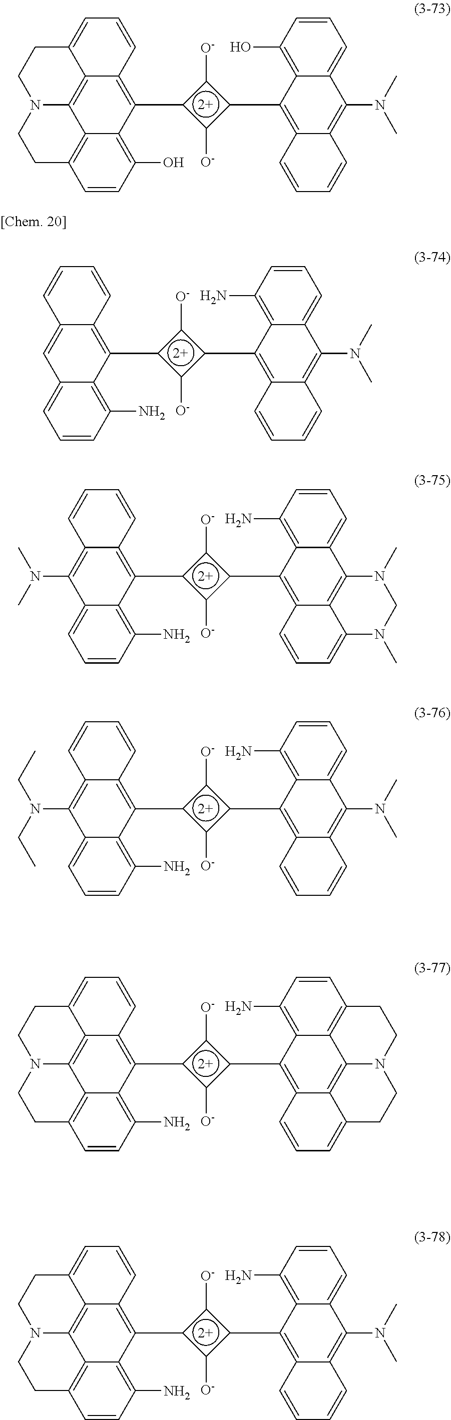

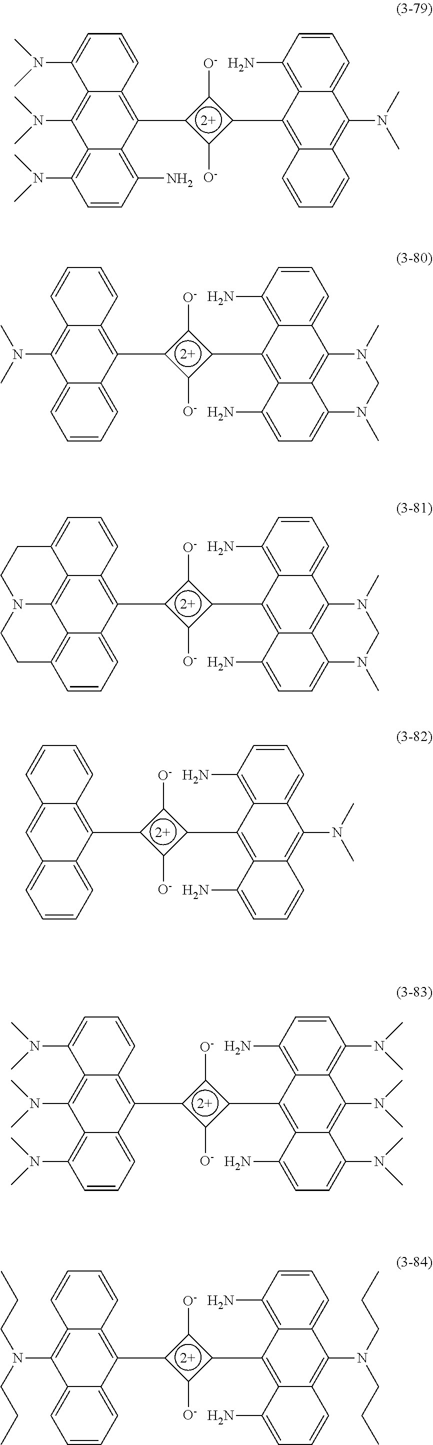

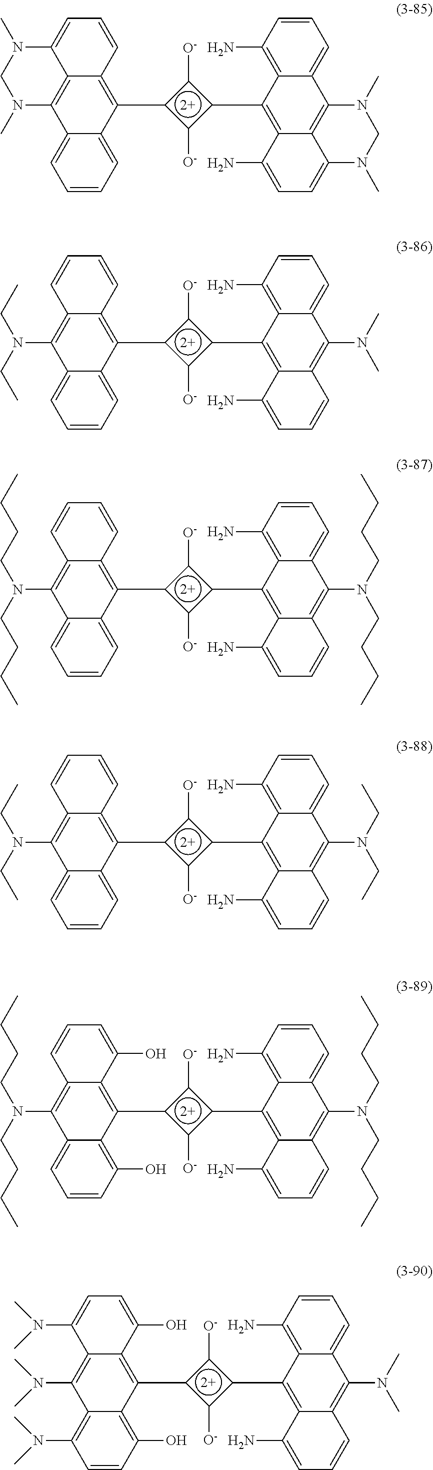

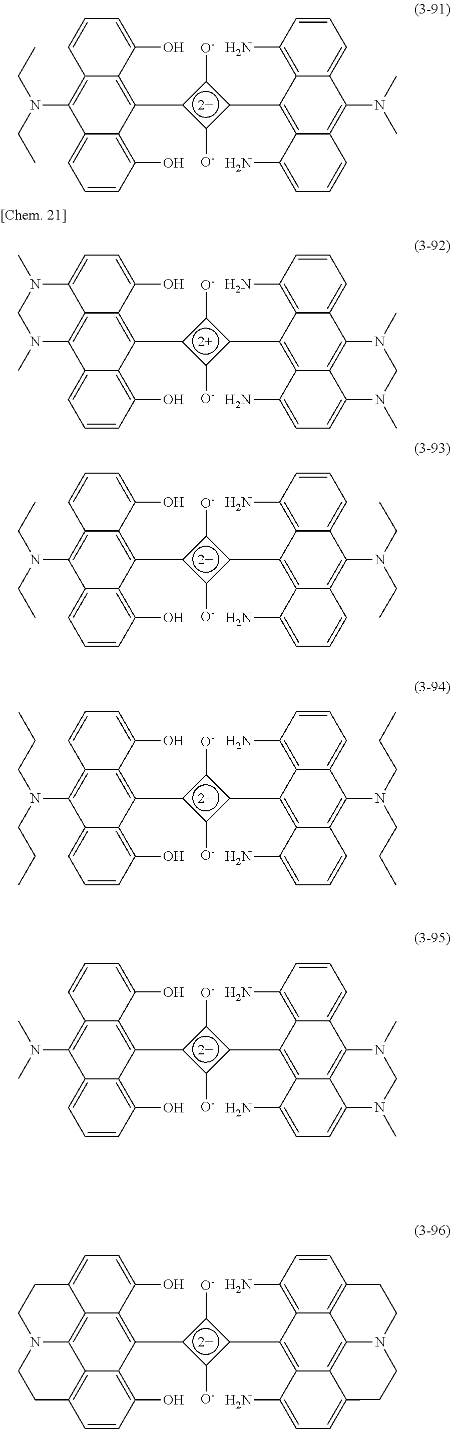

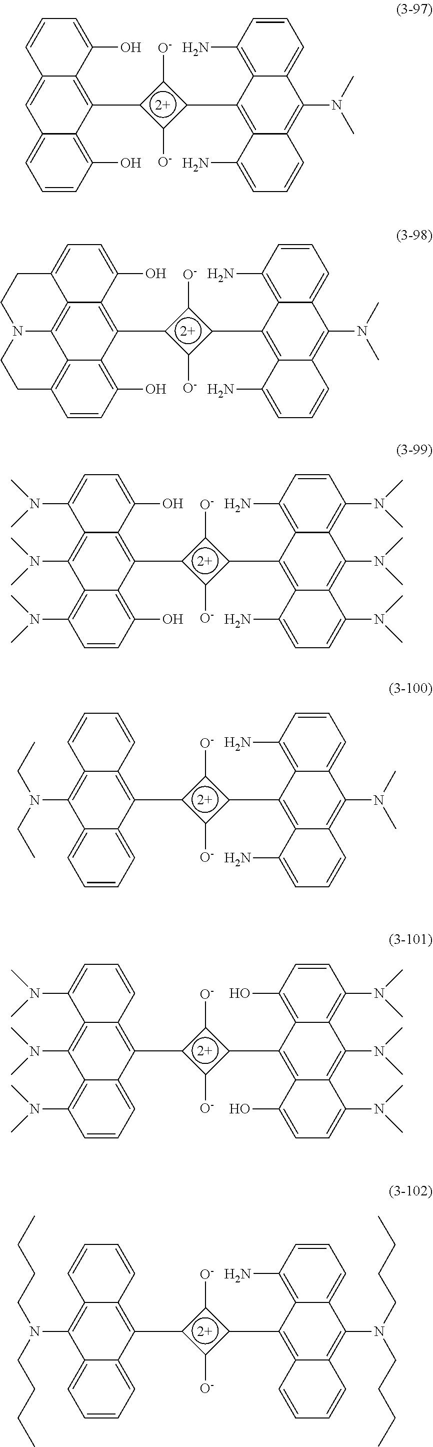

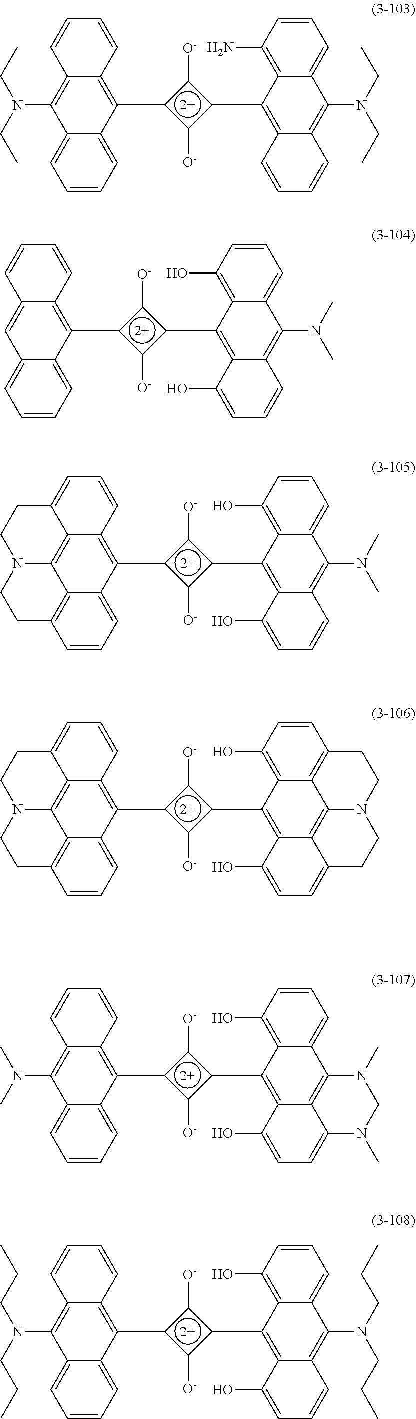

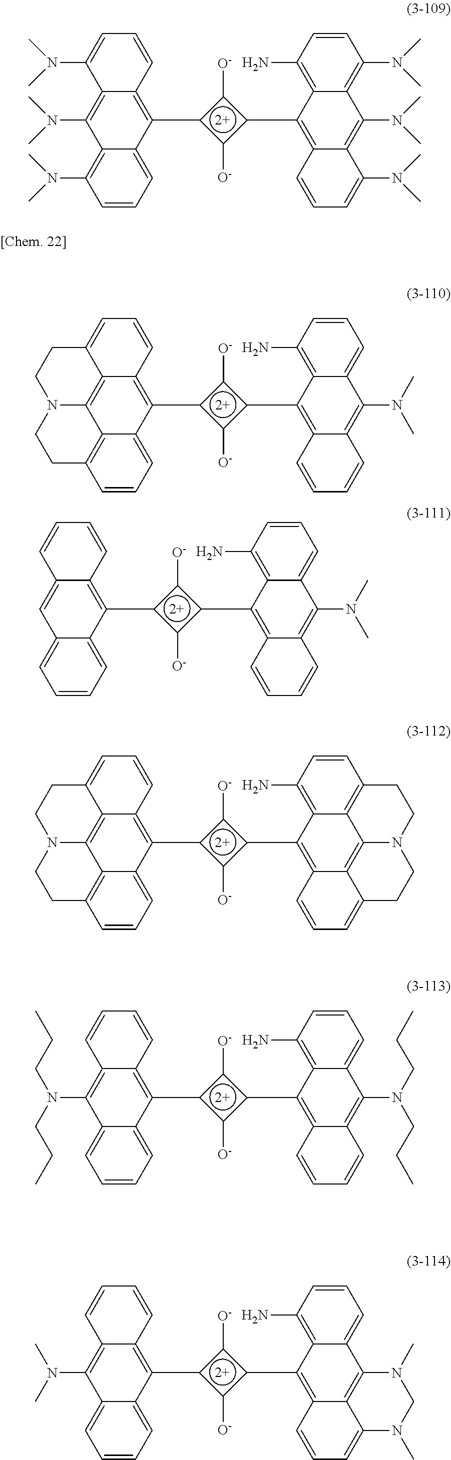

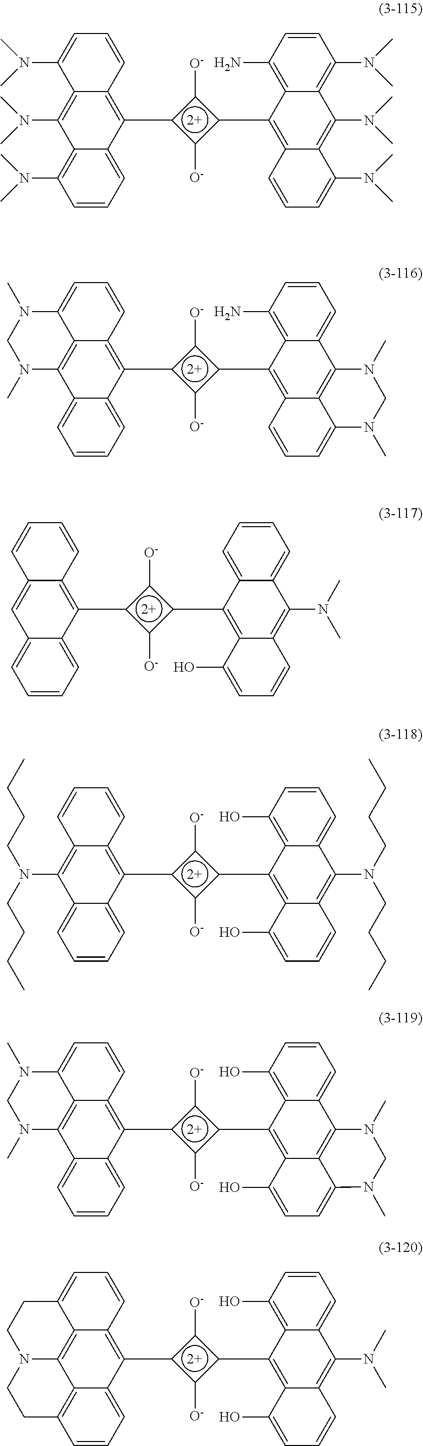

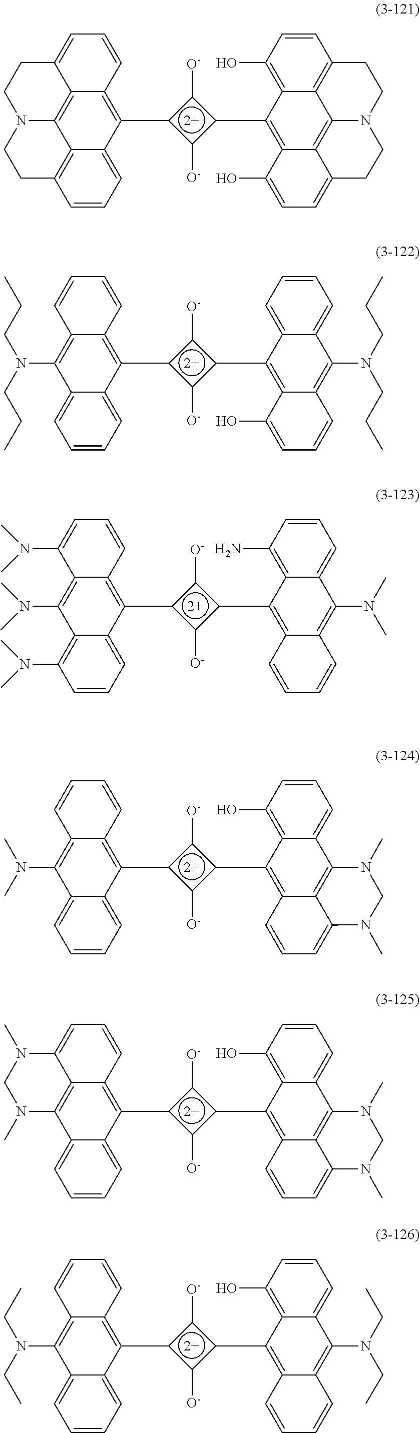

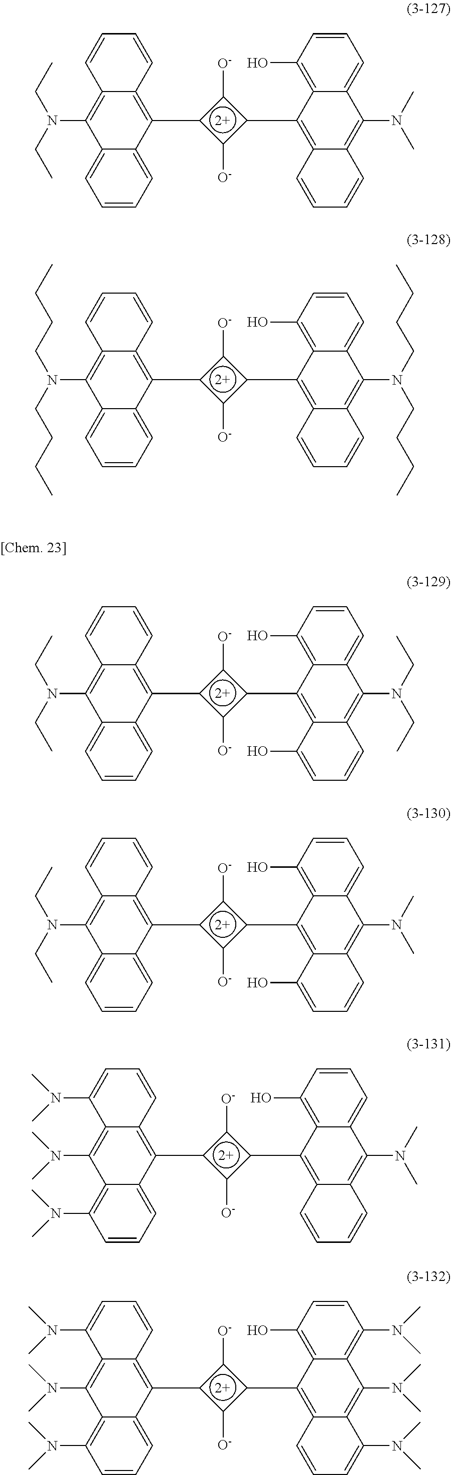

Further examples thereof include squarylium compounds, as represented by the following formulas (4-1) to (4-54), having a symmetric structure in which one of second and fourth sites (X1 and X2) of a squaric acid is substituted by a dicyanomethylene group, and anthracene derivatives having a same molecular structures are bonded to first and third sites.

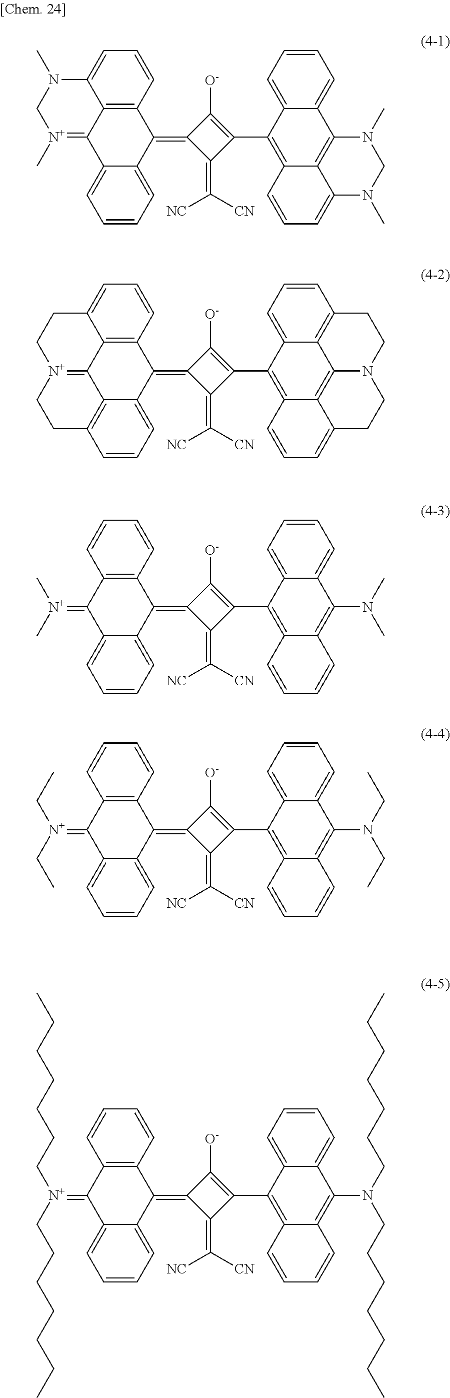

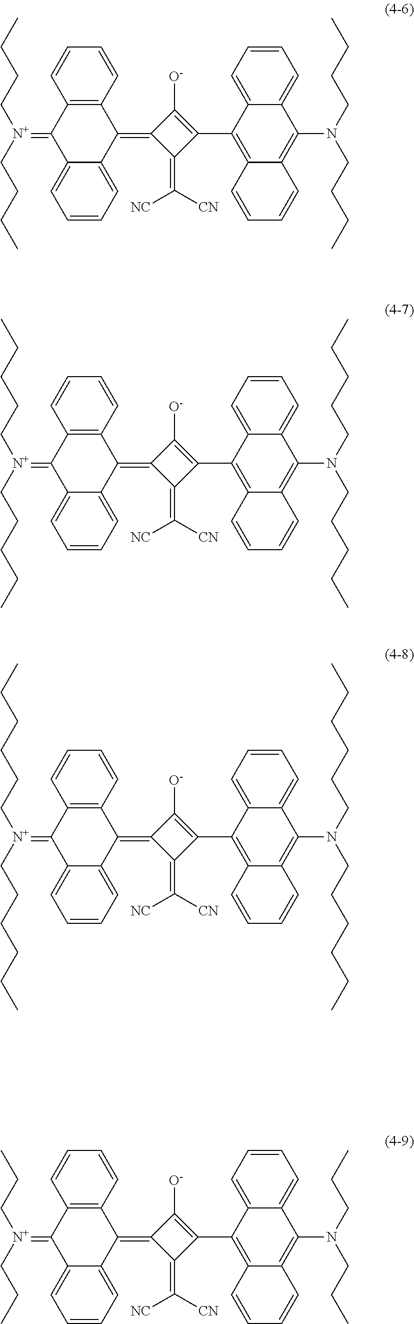 [SMILES: CCCCN(CCCC)c1c2ccccc2c(C2=C([O-])C(=C3c4ccccc4C(=[N+](CCCC)CCCC)c4ccccc43)C2=C(C#N)C#N)c2ccccc12 ; CCCCCN(CCCCC)c1c2ccccc2c(C2=C([O-])C(=C3c4ccccc4C(=[N+](CCCCC)CCCCC)c4ccccc43)C2=C(C#N)C#N)c2ccccc12 ; CCCCCCN(CCCCCC)c1c2ccccc2c(C2=C([O-])C(=C3c4ccccc4C(=[N+](CCCCCC)CCCCCC)c4ccccc43)C2=C(C#N)C#N)c2ccccc12 ; CCCN(CCC)c1c2ccccc2c(C2=C([O-])C(=C3c4ccccc4C(=[N+](CCC)CCC)c4ccccc43)C2=C(C#N)C#N)c2ccccc12]

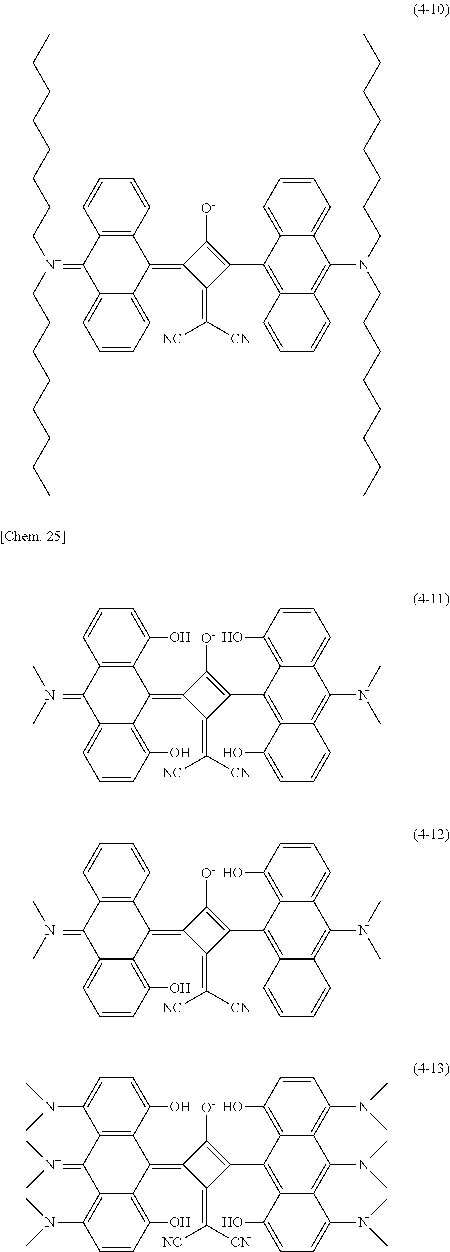

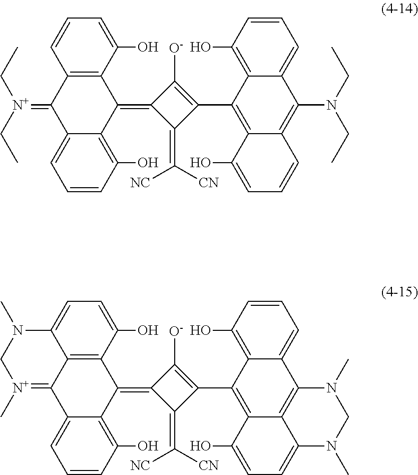 [SMILES: CCN(CC)c1c2cccc(O)c2c(C2=C([O-])C(=C3c4c(O)cccc4C(=[N+](CC)CC)c4cccc(O)c43)C2=C(C#N)C#N)c2c(O)cccc12 ; CN1CN(C)c2c3cccc(O)c3c(C3=C([O-])/C(=c4/c5c(O)cccc5c5c6c(ccc(O)c46)N(C)C[N+]=5C)C3=C(C#N)C#N)c3c(O)ccc1c23]

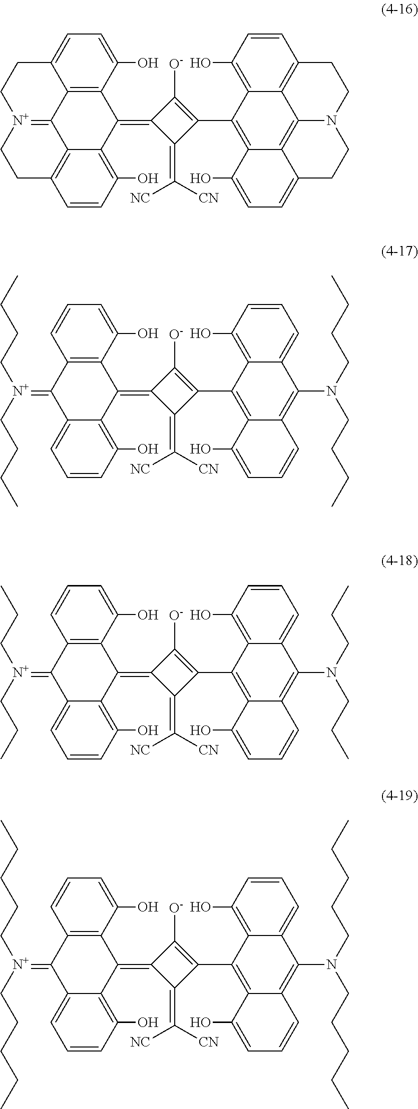 [SMILES: N#CC(C#N)=C1C(c2c3c(O)ccc4c3c3c5c(ccc(O)c25)CCN3CC4)=C([O-])C1=c1c2c(O)ccc3c2c2c4c(ccc(O)c14)CC[N+]=2CC3 ; CCCCN(CCCC)c1c2cccc(O)c2c(C2=C([O-])C(=C3c4c(O)cccc4C(=[N+](CCCC)CCCC)c4cccc(O)c43)C2=C(C#N)C#N)c2c(O)cccc12 ; CCCN(CCC)c1c2cccc(O)c2c(C2=C([O-])C(=C3c4c(O)cccc4C(=[N+](CCC)CCC)c4cccc(O)c43)C2=C(C#N)C#N)c2c(O)cccc12 ; CCCCCN(CCCCC)c1c2cccc(O)c2c(C2=C([O-])C(=C3c4c(O)cccc4C(=[N+](CCCCC)CCCCC)c4cccc(O)c43)C2=C(C#N)C#N)c2c(O)cccc12]

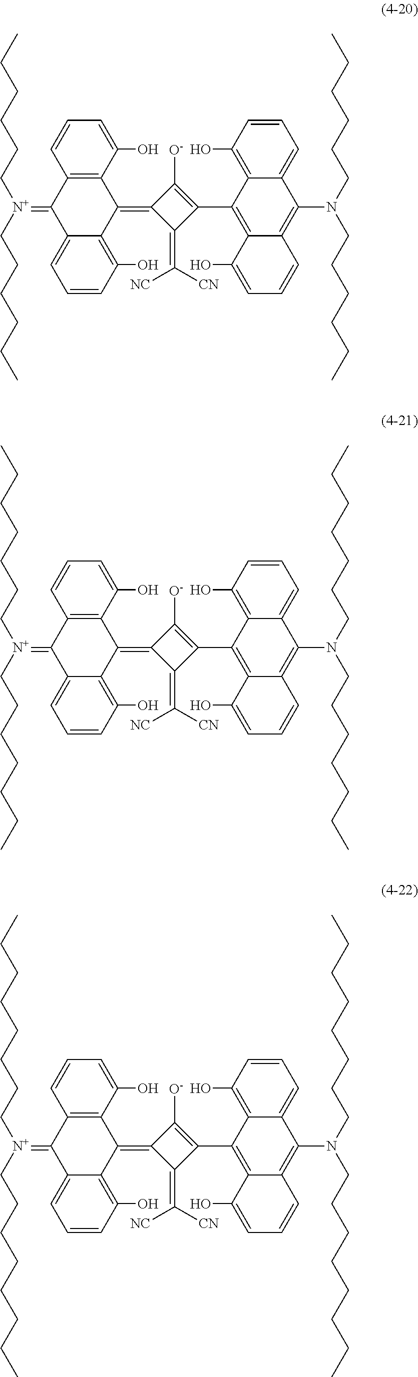 [SMILES: CCCCCCN(CCCCCC)c1c2cccc(O)c2c(C2=C([O-])C(=C3c4c(O)cccc4C(=[N+](CCCCCC)CCCCCC)c4cccc(O)c43)C2=C(C#N)C#N)c2c(O)cccc12 ; CCCCCCCN(CCCCCCC)c1c2cccc(O)c2c(C2=C([O-])C(=C3c4c(O)cccc4C(=[N+](CCCCCCC)CCCCCCC)c4cccc(O)c43)C2=C(C#N)C#N)c2c(O)cccc12 ; CCCCCCCCN(CCCCCCCC)c1c2cccc(O)c2c(C2=C([O-])C(=C3c4c(O)cccc4C(=[N+](CCCCCCCC)CCCCCCCC)c4cccc(O)c43)C2=C(C#N)C#N)c2c(O)cccc12]

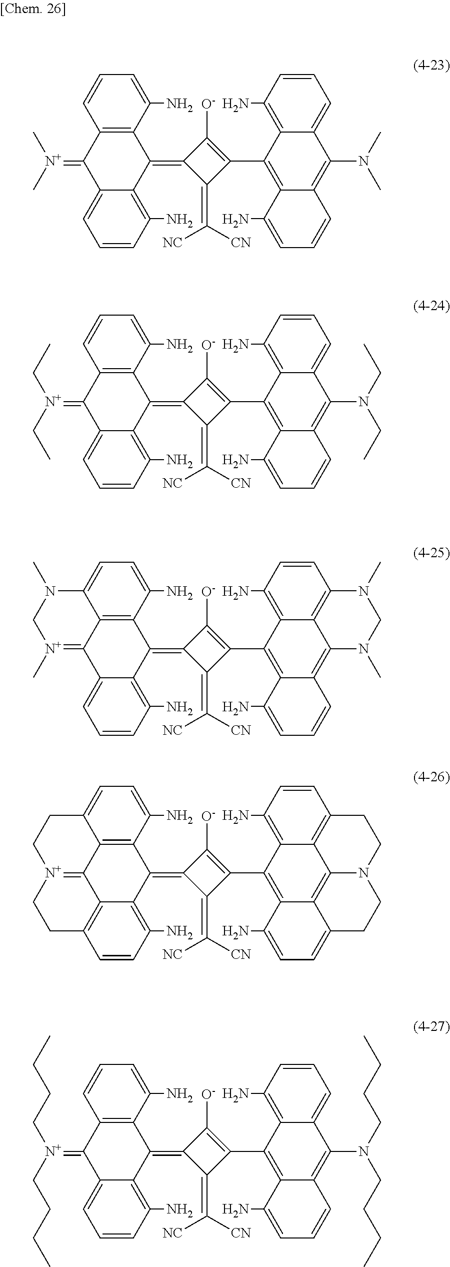

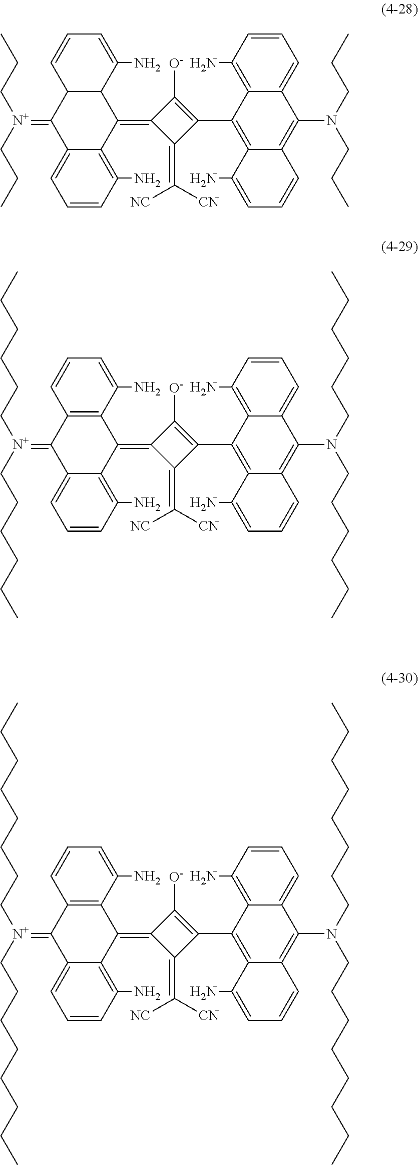 [SMILES: CCCN(CCC)c1c2cccc(N)c2c(C2=C([O-])/C(=C3/c4c(N)cccc4C(=[N+](CCC)CCC)C4C=CC=C(N)C34)C2=C(C#N)C#N)c2c(N)cccc12 ; CCCCCCN(CCCCCC)c1c2cccc(N)c2c(C2=C([O-])C(=C3c4c(N)cccc4C(=[N+](CCCCCC)CCCCCC)c4cccc(N)c43)C2=C(C#N)C#N)c2c(N)cccc12 ; CCCCCCCCN(CCCCCCCC)c1c2cccc(N)c2c(C2=C([O-])C(=C3c4c(N)cccc4C(=[N+](CCCCCCCC)CCCCCCCC)c4cccc(N)c43)C2=C(C#N)C#N)c2c(N)cccc12]

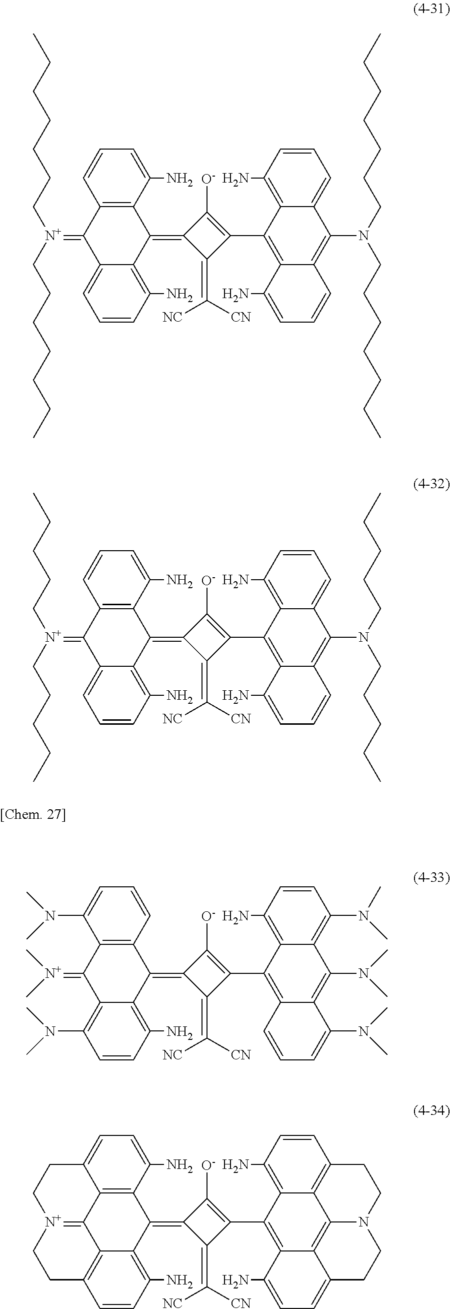

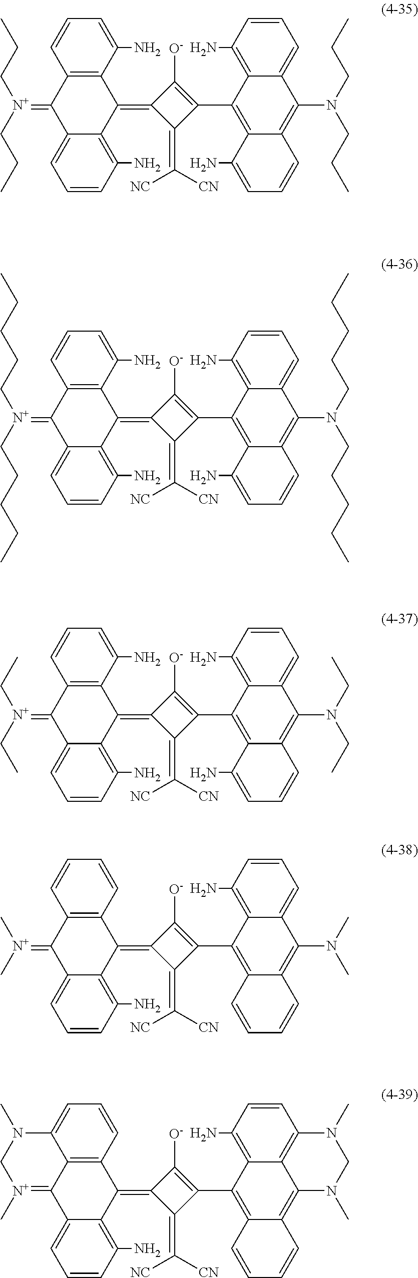

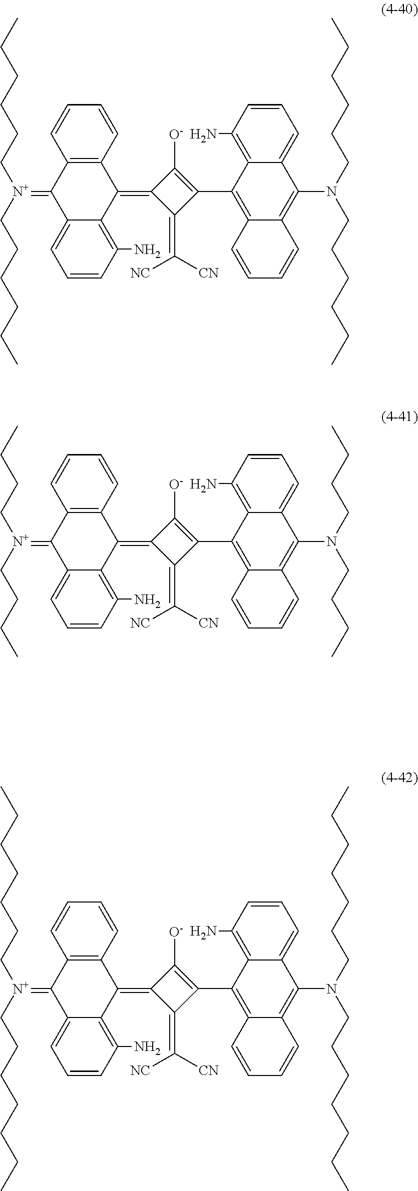 [SMILES: CCCCCCN(CCCCCC)c1c2ccccc2c(C2=C([O-])/C(=C3\c4ccccc4C(=[N+](CCCCCC)CCCCCC)c4cccc(N)c43)C2=C(C#N)C#N)c2c(N)cccc12 ; CCCCN(CCCC)c1c2ccccc2c(C2=C([O-])/C(=C3\c4ccccc4C(=[N+](CCCC)CCCC)c4cccc(N)c43)C2=C(C#N)C#N)c2c(N)cccc12 ; CCCCCCCN(CCCCCCC)c1c2ccccc2c(C2=C([O-])/C(=C3\c4ccccc4C(=[N+](CCCCCCC)CCCCCCC)c4cccc(N)c43)C2=C(C#N)C#N)c2c(N)cccc12]

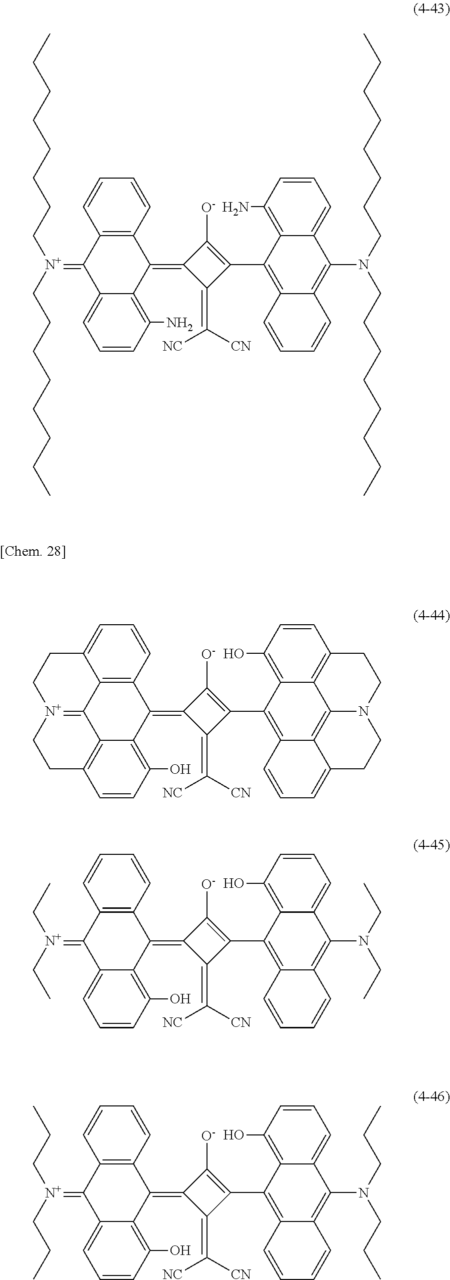 [SMILES: CCCCCCCCN(CCCCCCCC)c1c2ccccc2c(C2=C([O-])/C(=C3\c4ccccc4C(=[N+](CCCCCCCC)CCCCCCCC)c4cccc(N)c43)C2=C(C#N)C#N)c2c(N)cccc12 ; N#CC(C#N)=C1C(c2c3cccc4c3c3c5c(ccc(O)c25)CCN3CC4)=C([O-])/C1=c1\c2cccc3c2c2c4c(ccc(O)c14)CC[N+]=2CC3 ; CCN(CC)c1c2ccccc2c(C2=C([O-])/C(=C3\c4ccccc4C(=[N+](CC)CC)c4cccc(O)c43)C2=C(C#N)C#N)c2c(O)cccc12 ; CCCN(CCC)c1c2ccccc2c(C2=C([O-])/C(=C3\c4ccccc4C(=[N+](CCC)CCC)c4cccc(O)c43)C2=C(C#N)C#N)c2c(O)cccc12]

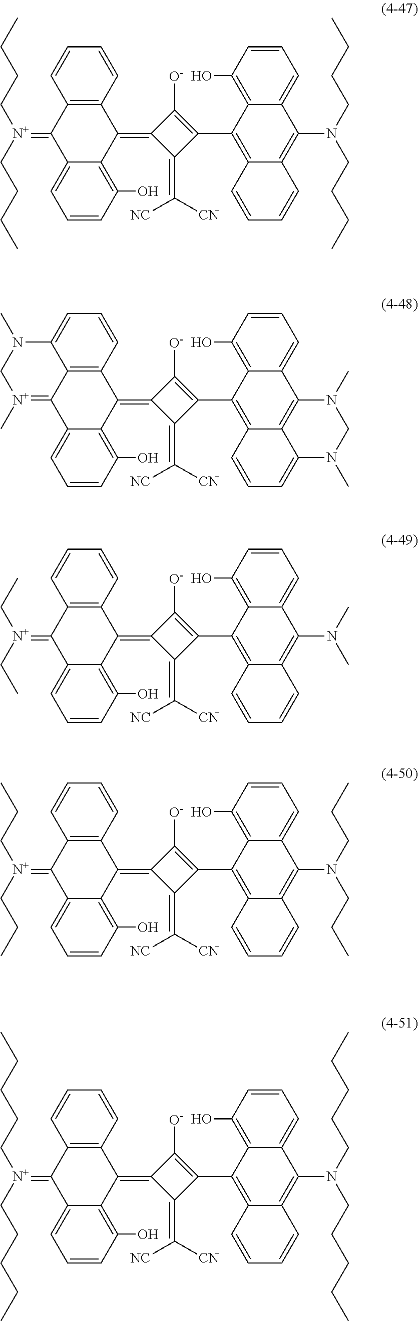

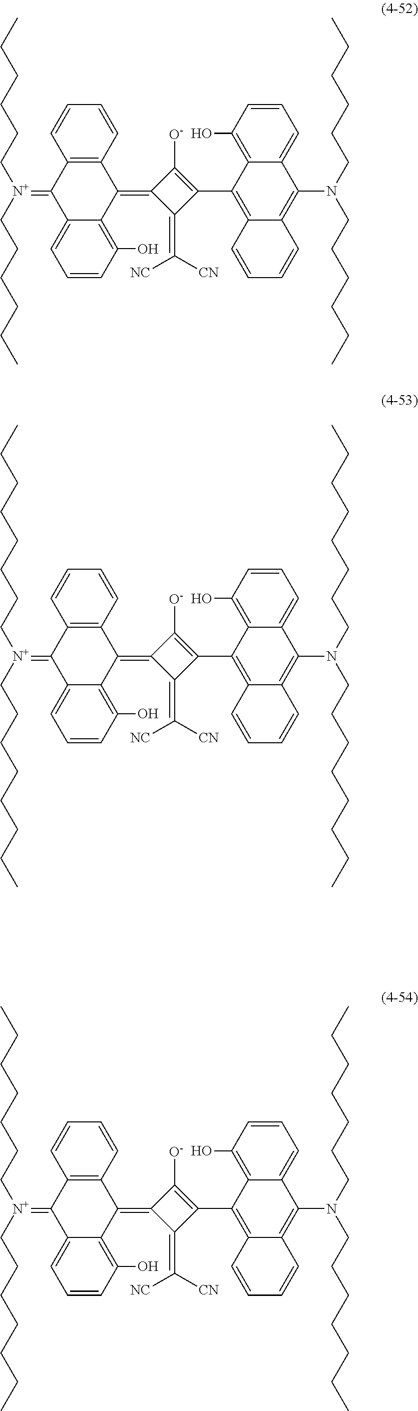 [SMILES: CCCCCCN(CCCCCC)c1c2ccccc2c(C2=C([O-])/C(=C3\c4ccccc4C(=[N+](CCCCCC)CCCCCC)c4cccc(O)c43)C2=C(C#N)C#N)c2c(O)cccc12 ; CCCCCCCCN(CCCCCCCC)c1c2ccccc2c(C2=C([O-])/C(=C3\c4ccccc4C(=[N+](CCCCCCCC)CCCCCCCC)c4cccc(O)c43)C2=C(C#N)C#N)c2c(O)cccc12 ; CCCCCCCN(CCCCCCC)c1c2ccccc2c(C2=C([O-])/C(=C3\c4ccccc4C(=[N+](CCCCCCC)CCCCCCC)c4cccc(O)c43)C2=C(C#N)C#N)c2c(O)cccc12]

Furthermore, these squarylium compounds in which one of the second and fourth sites (X3 and X4) of the squaric acid is substituted by a dicyanomethylene group may also have an asymmetric structure in addition to the symmetric structure. Examples thereof include squarylium compounds represented by the formulas (4-55) to (4-132).

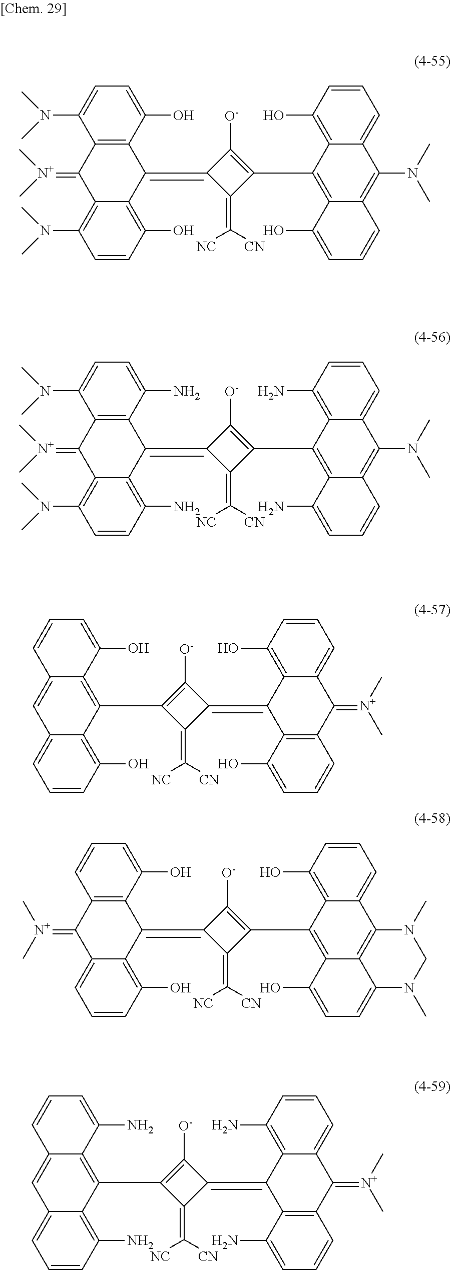

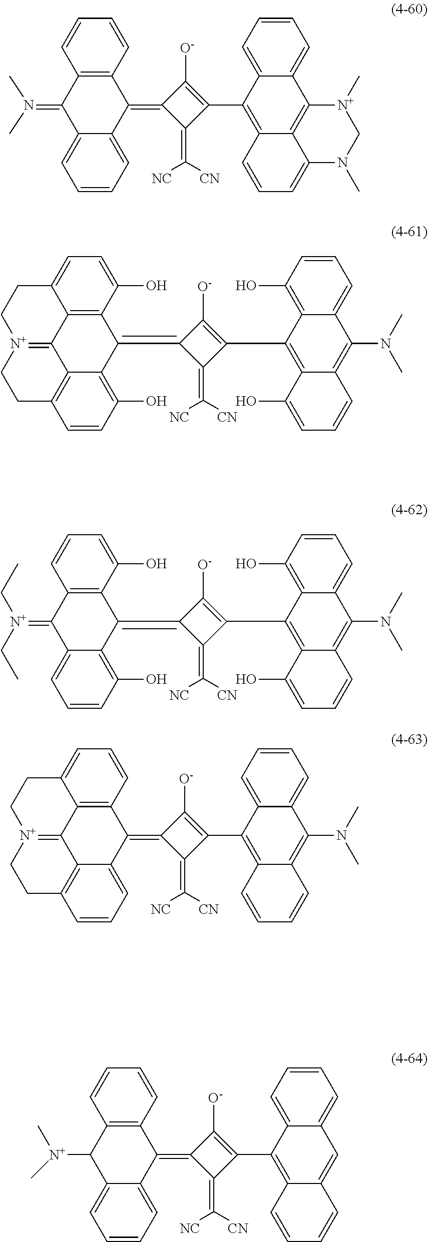

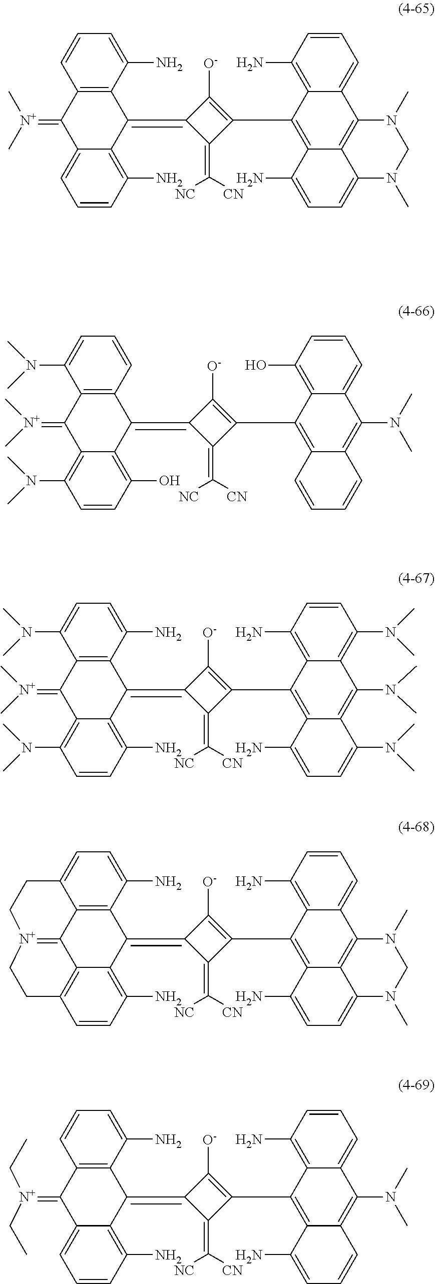

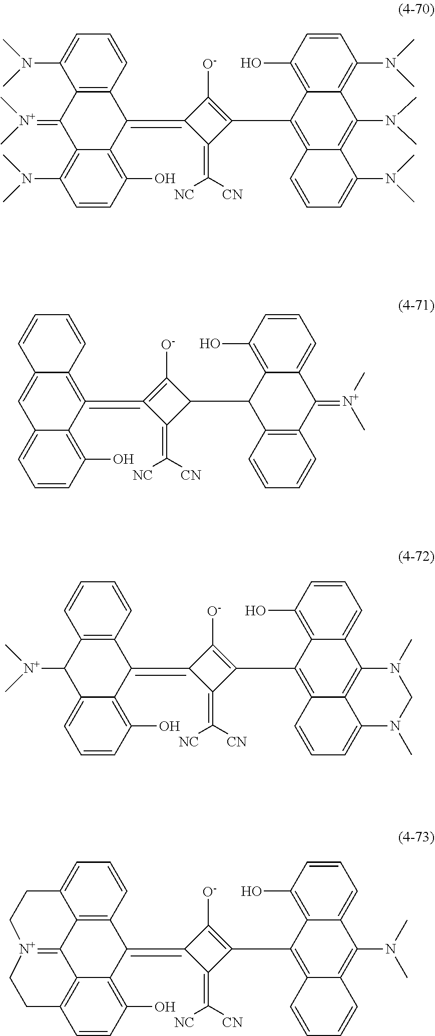

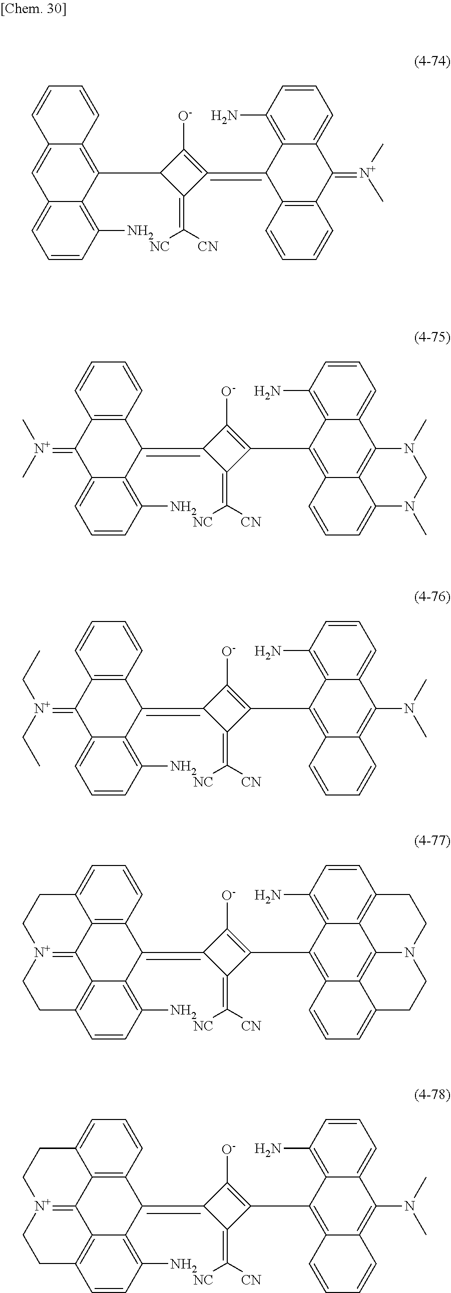

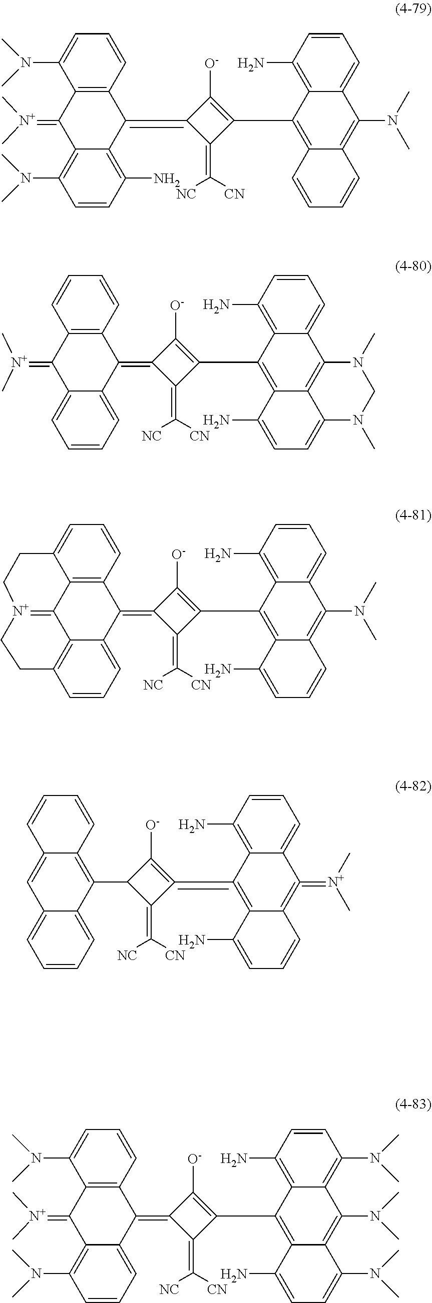

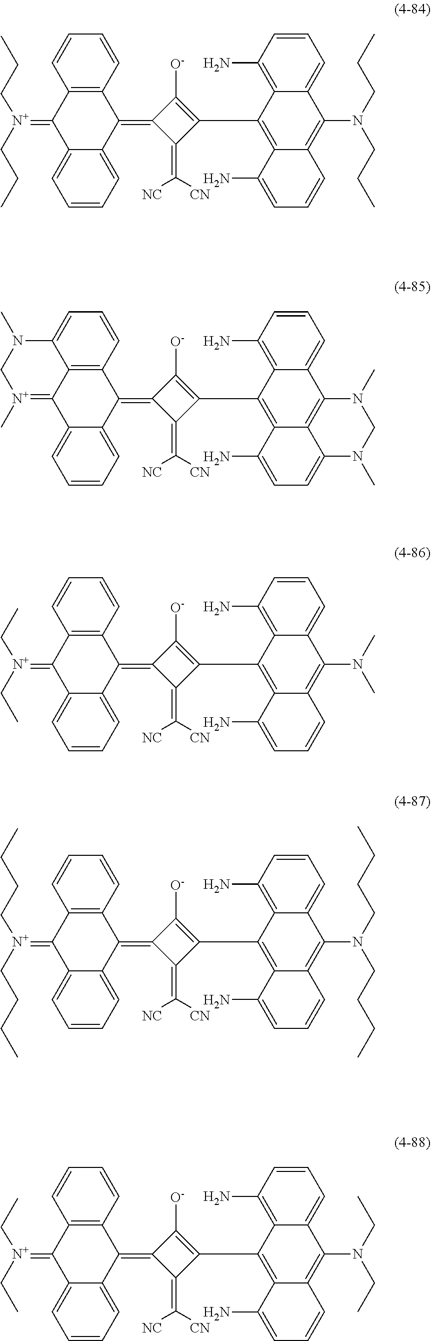

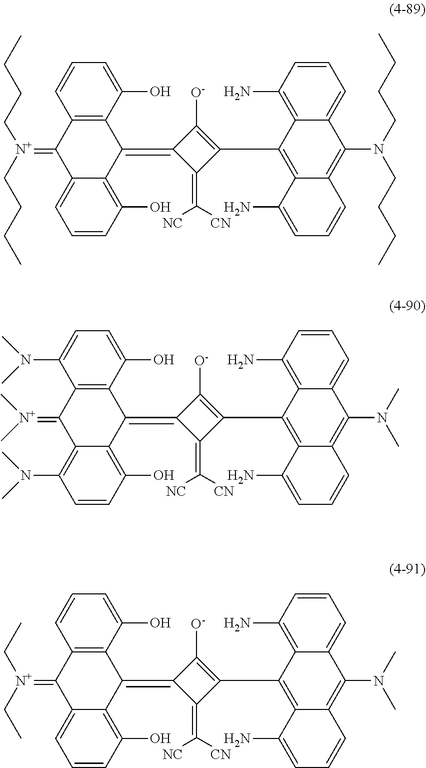

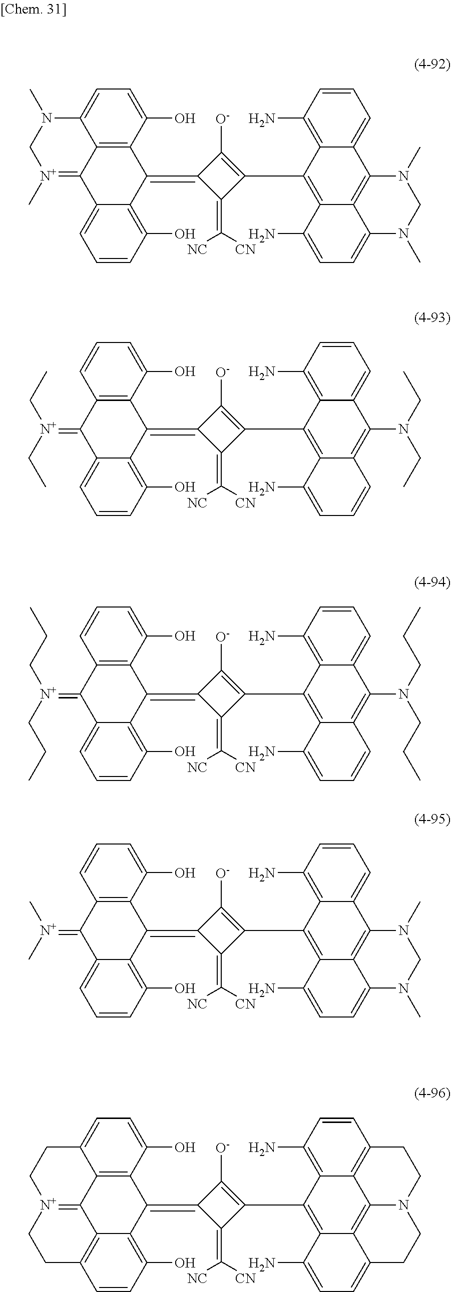

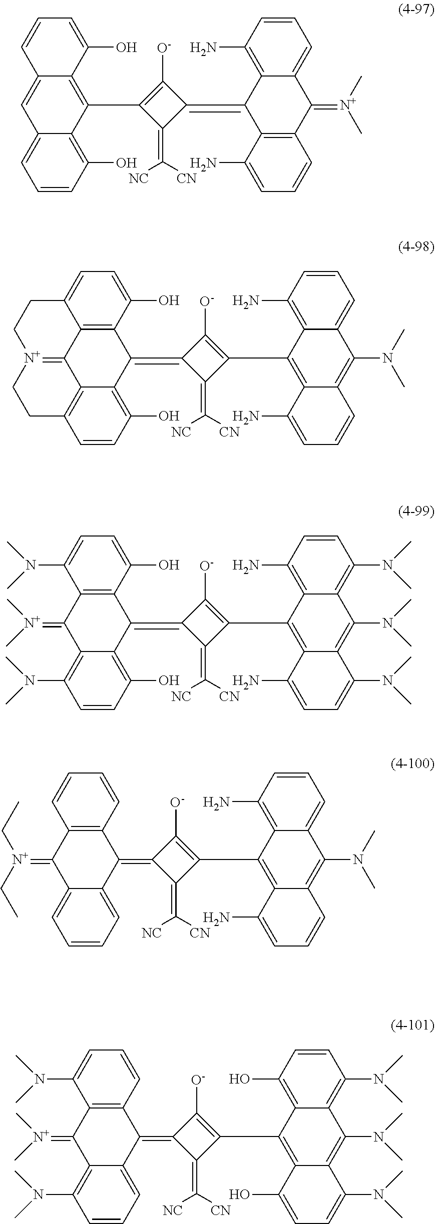

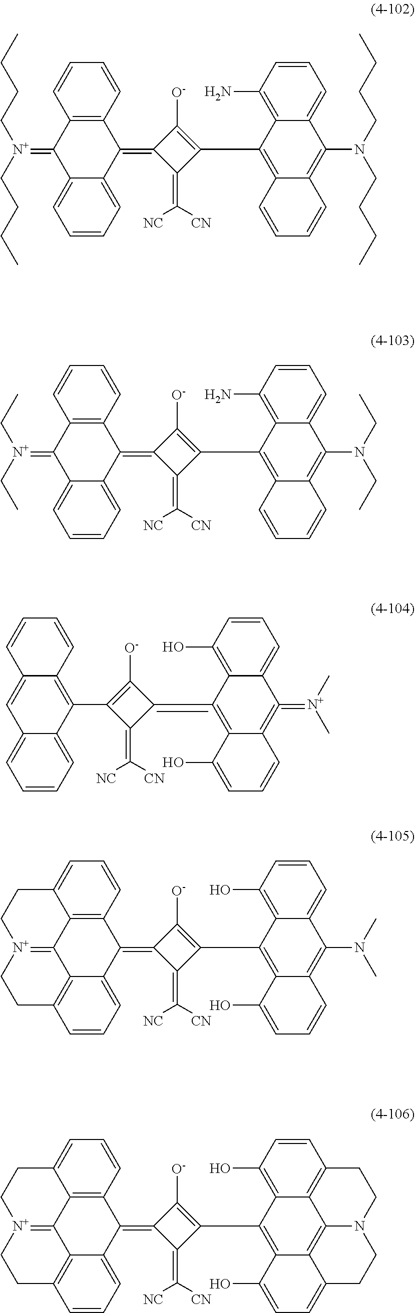

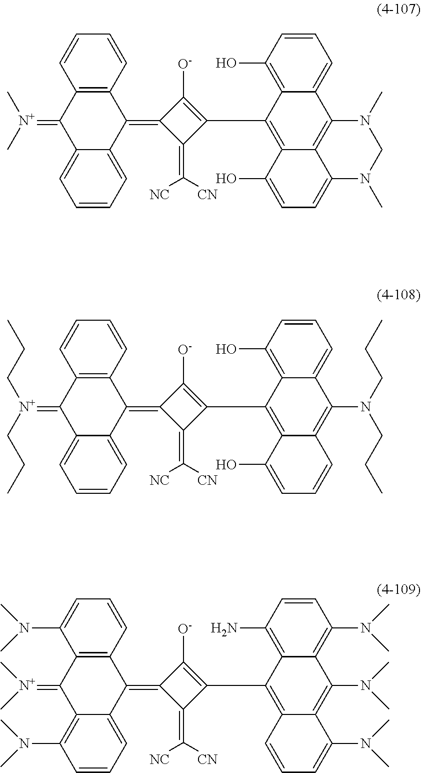

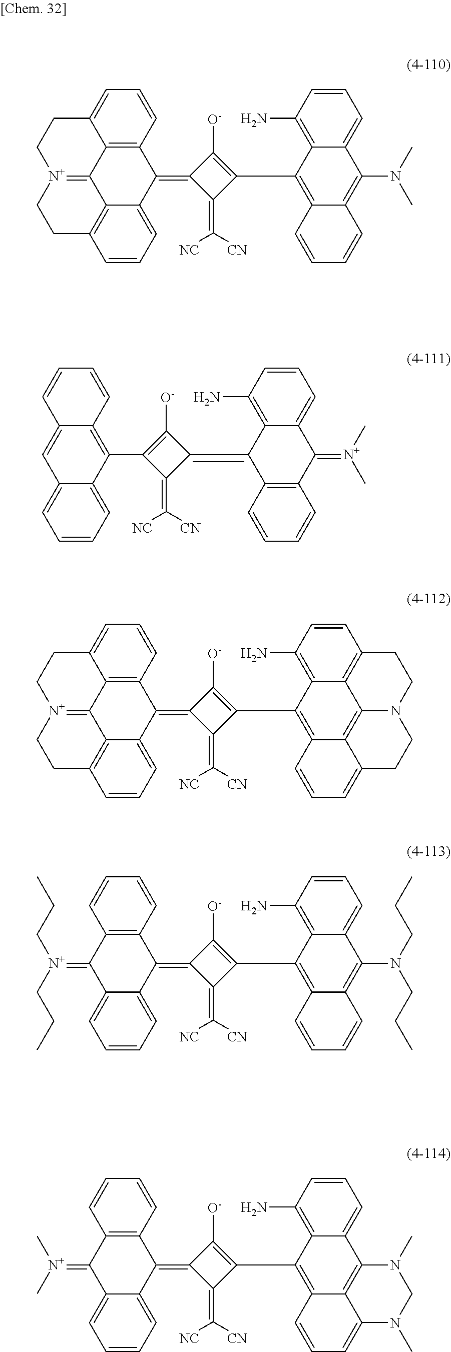

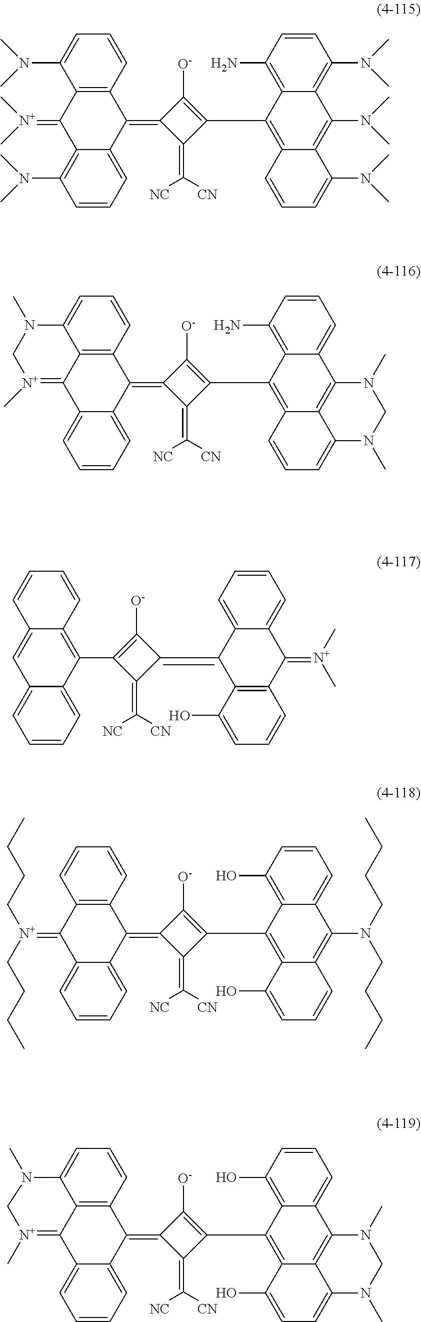

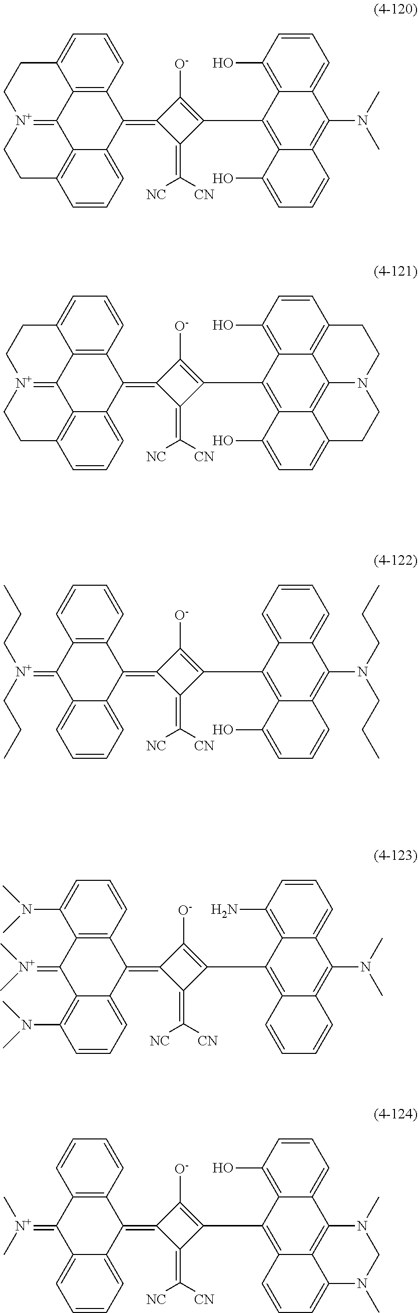

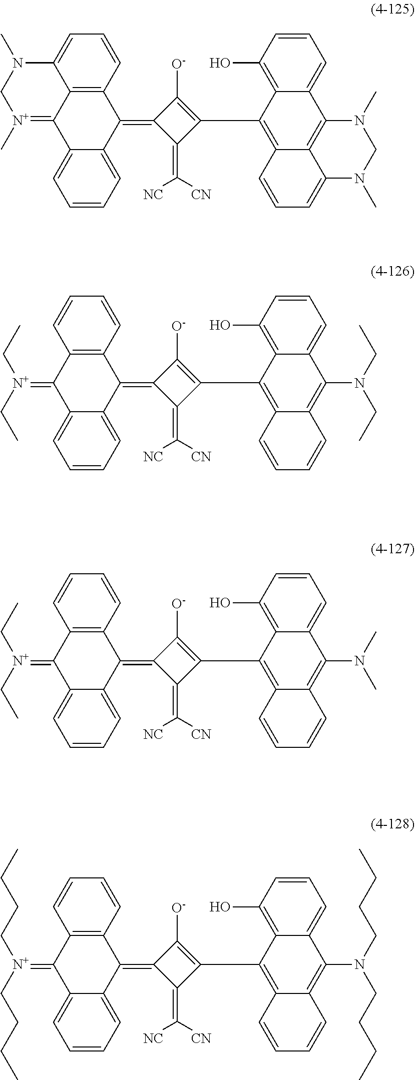

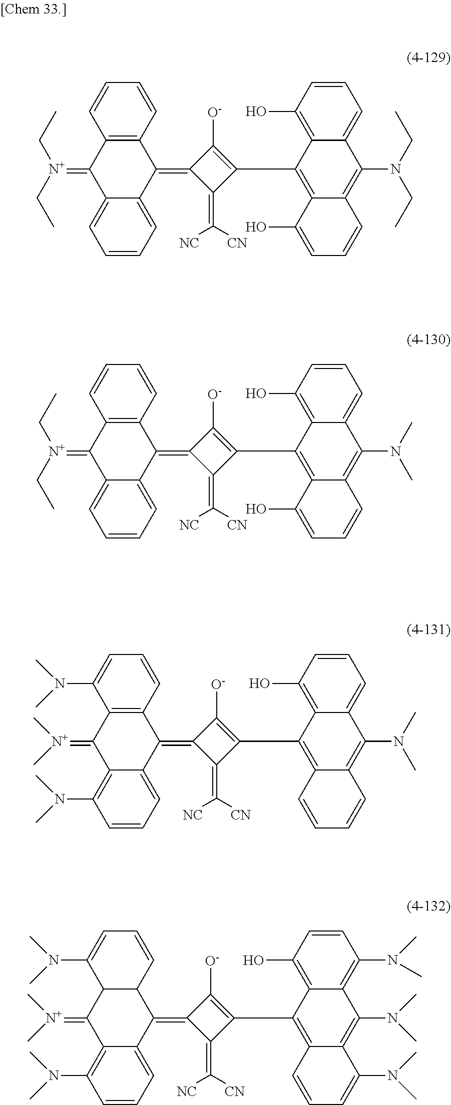

It is possible to form the infrared absorption layer 15 using a resin composition including the foregoing squarylium compound and a binder resin. The binder resin used for the infrared absorption layer 15 is not particularly limited, and, for example, any of various resins such as thermoplastic resin, a thermosetting resin, and a photocuring resin may be used. Note that in terms of heat resistance and imaging performance, the binder resin preferably has, for example, a glass transition point Tg equal to or higher than 150° C., and more preferably also has a melting point equal to or higher than 150° C., and still more preferably has a heating yellowing temperature equal to or higher than 150° C. Examples of such a binder resin include an epoxy-based resin, an acrylic-based resin, a silicone (siloxane)-based resin, a polycarbonate-based resin, and a polyethylene-based resin. In particular, among these resins, it is preferable to use a thermosetting or photocuring resin that does not have a maximal absorption wavelength in a range from 400 nm to 600 nm both inclusive.

Moreover, in a case where a resin that includes a functional group, such as a carboxyl group, having high oxidation power is used as a binder resin, there is a possibility that the squarylium compound is oxidized, thereby resulting in a reduction in heat resistance. Hence, the binder resin preferably uses a resin that includes a bond, such as a siloxane bond (—Si—O—) and a carbon-oxygen bond (—C—O—), having high stability and relatively low oxidation power, and in particular, a resin having a siloxane bond as a main backbone is suitable.

It is to be noted that a dispersion state of the squarylium compound in the resin composition is not particularly limited, and may be a molecule dispersion state. However, in terms of an improvement in transparency to a visible region, the dispersion state is preferably a state in which the squarylium compound is compatible with the binder resin.

Moreover, in addition to the squarylium compound and the binder resin mentioned above, a curing agent and a curing assistant agent for curing of the binder resin may be added to the infrared absorption layer 15. The curing agent and the curing assistant agent are selectable as appropriate depending on monomers included in the binder resin; however, for example, a curing agent and a curing assistant agent not having a maximal absorption wavelength in a visible region from 400 nm to 600 nm both inclusive are preferably used.

Further, the infrared absorption layer 15 may include one or more kinds of compounds having a different maximal absorption wavelength from that of the foregoing squarylium compound. Furthermore, the infrared absorption layer 15 may have, for example, a stacked configuration that includes a first absorption layer 15A including the foregoing squarylium compound and a second absorption layer 15B including one or more kinds of compounds having a different maximal absorption wavelength from that of the squarylium compound, as illustrated in FIG. 2. Using a plurality of compounds having different maximal absorption wavelengths together makes it possible to absorb infrared light with a wavelength of which an absorption rate by the squarylium compound is low, and to further improve imaging performance. It is to be noted that the stacking order of the first absorption layer 15A and the second absorption layer 15B does not matter.

Furthermore, the infrared absorption layer 15 may contain, in addition to the foregoing respective components, various kinds of additives including oxide microparticles for an improvement in heat resistance, a leveling agent, a dispersant such as a surface-active agent, an antioxidant, a dye stabilizer such as a squarylium compound. In addition, the infrared absorption layer 15 may further include KCuPO₄, a compound, such as iron oxide and tungsten oxide, including a transition metal belonging to the fourth period of the periodic table, a conductive oxide such as indium tin oxide (ITO), a diimmonium compound, an anthraquinone compound, an cyanine compound, a phthalocyanine compound, an azo complex, a Ni complex, a Co complex, a Cu complex, a Fe complex, a pyrrolopyrrole compound, a thiourea compound, and acetylene polymer that are mentioned as examples of the material configuring the foregoing color filter layer 12.

A thickness of the infrared absorption layer 15 is preferably, for example, from 0.5 μm to 200 μm both inclusive in terms of a reduction in thickness of the solid-state imaging element 10. In the solid-state imaging element 10 according to the present embodiment, the planarization layer 14 is provided on the on-chip lens 13, which makes it possible to form the infrared absorption layer 15 with a uniform thickness irrespective of the shape of the on-chip lens 13. Moreover, in the present embodiment, the thickness of the infrared absorption layer 15 does not exert on a distance between the on-chip lens 13 and the photoelectric converter 11B. Accordingly, it is possible to set the thickness of the infrared absorption layer 15 to a thickness that allows an infrared light component to be sufficiently removed.

It is possible to form the infrared absorption layer 15 by dissolving a resin composition including the squarylium compound, the binder resin, etc. mentioned above in, for example, chloroform to prepare an ink, and applying the ink onto, for example, a base such as a glass substrate, a quartz substrate, and a resin substrate by, for example, a coating method such as a spin coating method, a die coating method, a slit coating method, and a dispensing method. Moreover, the infrared absorption layer 15 may be formed by applying the ink directly onto the planarization layer 14. It is to be noted that a solvent for the foregoing resin composition is not limited to chloroform, and may be appropriately selected in accordance with a coating method and compatibility between squarylium and the binder resin. In addition to chloroform, examples of the solvent include methanol, ethanol, ethyl acetate, butyl acetate, acetone, methyl ethyl ketone, methyl isobutyl ketone, toluene, tetrahydrofuran, methylene chloride, anisole, hexane, cyclohexane, cyclopentanone, dimethylformamide, propylene glycol monomethyl ether, and propylene glycol monomethyl ether acetate.

### 1-2. Operation of Solid-State Imaging Element

In the solid-state imaging element 10 as described above, for example, signal electric charges are obtained in a unit pixel P of the solid-state imaging device 1 in the following manner. That is, an infrared light component is removed from light (incident light L) having entered the solid-state imaging element 10, as illustrated in FIG. 1. The incident light L from which the infrared light component is removed is diffracted at an interface between the planarization layer 14 and the on-chip lens 13, and the color filters 12R, 12G, and 12B of the color filter layer 12 remove a component other than a predetermined wavelength region from the incident light L, and thereafter, the incident light L is concentrated onto each of the photoelectric converters 11B. The concentrated light is photoelectrically converted in each of the photoelectric converters 11B to obtain signal electric charges.

### 1-3. Workings and Effects

As described above, in order to improve image quality, an optical filter that cuts light other than the visible region regarded as a noise component is provided in a solid-state imaging element (image sensor) mounted in an imaging device such as a video camera and a digital still camera. An infrared cut filter that removes light in the infrared wavelength region of the optical filter uses an infrared absorbing dye such as a cyanine-based compound, a phthalocyanine-based compound, and a squarylium-based compound. In particular, the squarylium-based compound has a steep absorption peak around 650 nm, and has attracted attention accordingly.

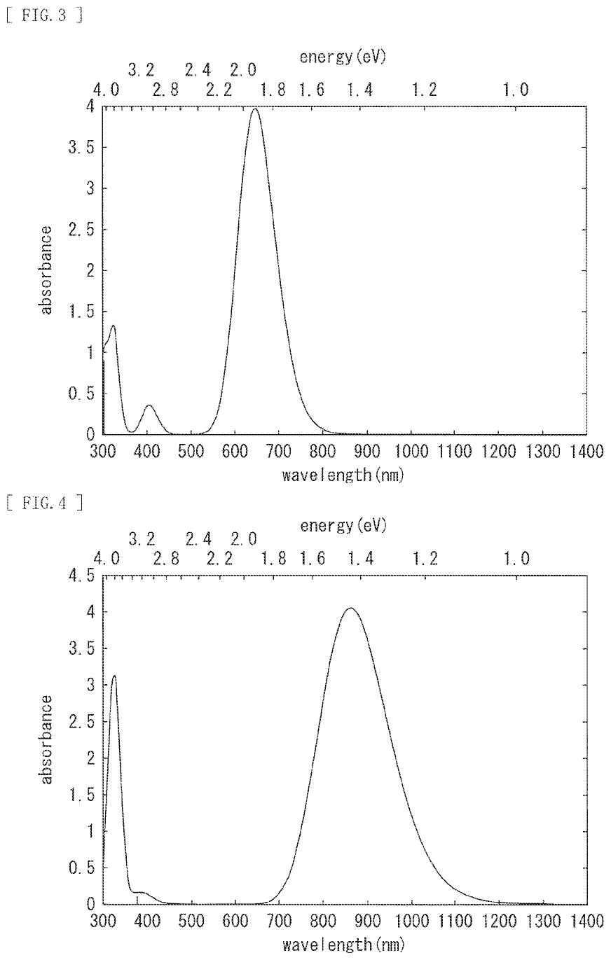

However, the infrared absorbing dye including a typically used squarylium-based compound (for example, a formula (5)) has a slight absorption property in the visible region, as illustrated in FIG. 3. For example, in a case where transparency to the visible region is defined by (maximum light absorbance in the visible region (equal to or more than 400 nm and less than 600 nm)/(maximum light absorbance in the infrared region (from 600 nm to 1500 nm both inclusive), the maximum absorbance in the visible region with respect to the maximum light absorbance in the infrared region in the typically used infrared cut filter is, for example, equal to or more than 0.05.

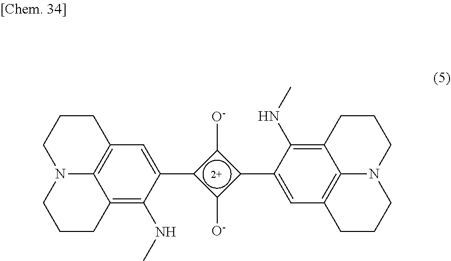

In contrast, the optical filter (the infrared absorption layer 15) according to the present embodiment is formed using the squarylium compound represented by the foregoing general formula (1) or (2) as the infrared absorbing dye, which reduces the absorption property in the visible region, as illustrated in FIG. 4. Specifically, the maximum light absorbance in the visible region with respect to the maximum light absorbance in the infrared region is less than 0.05.

As described above, in the solid-state imaging element 10 according to the present embodiment, the squarylium compound represented by the foregoing general formula (1) or (2) is used as the infrared absorbing dye forming the infrared absorption layer 15. This makes it possible to reduce the light absorption property in the visible region of the typically used squarylium compound and to improve transparency in the visible region of the infrared absorption layer 15. Accordingly, it is possible to provide the solid-state imaging element 10 having high optical characteristics.

Moreover, providing the infrared absorption layer 15 using, as the infrared absorbing dye, the squarylium compound having a group that is able to form a hydrogen bond in a molecule at one or both of R1 and R10 in the general formula (1) or the squarylium compound having a group that is able to form a hydrogen bond in a molecule at one or more of R19, R27, R28, and R36 in the general formula (2) makes it possible to improve heat resistance of the infrared absorption layer 15 in addition to transparency in the visible region.

Further, using the qauarylium compound that includes the foregoing group having a higher electron donation property than that of hydrogen (H) at R₃ and R₁₂ in the general formula (1) and R23 and R32 in the general formula (2) makes it possible to reduce difficulty in synthesis of the squarylium compound.

### 2. MODIFICATION EXAMPLES

Hereinafter, description is given of modification examples (modification examples 1 to 4) of the foregoing first embodiment, and a second embodiment. It is to be noted that components similar to those in the foregoing embodiment are denoted by same reference numerals, and description thereof is omitted.

### 2-1. Modification Example 1

FIG. 5 illustrates a cross-sectional configuration of a solid-state imaging element (a solid-state imaging element 20) according to the modification example 1 of the present disclosure. The solid-state imaging element 20 is different from the foregoing first embodiment in that a protective layer 16 is provided on the infrared absorption layer 15. It is to be noted that an example in which the protective layer 16 is provided on the infrared absorption layer 15 is described herein; however, the protective layer 16 may be formed, for example, continuously on a top surface and a side surface of the infrared absorption layer 15, or may be formed only on the side surface.

The protective layer 16 chemically and physically protects the infrared absorption layer 15. Materials forming the protective layer 16 include, but not limited to, silver (I) oxide (Ag₂O), silver monoxide (AgO), aluminum oxide (Al₂O₃), aluminum fluoride (AlF₃), barium fluoride (BaF₂), cerium (IV) oxide (CeO₂), chromium (III) oxide (Cr₂O₃), chromium (III) sulfide (Cr₂S₃), gadolinium fluoride (GdF₃), hafnium (IV) oxide (HfO₂), indium tin oxide (ITO), lanthanum fluoride (LaF₃), lithium niobate (LiNbO₃), magnesium fluoride (MgF₂), magnesium oxide (MgO), sodium hexafluoroaluminate (Na₃AlF₆), niobium pentoxide (Nb₂O₅), an nickel-chromium alloy (Ni—Cr), a nitride of an nickel-chromium alloy (NiCrNx), an oxynitride (OxNy), silicon nitride (SiN₄), silicon oxide (SiO), silicon dioxide (SiO₂), tantalum pentoxide (Ta₂O₅), titanium trioxide (Ti₂O₃), titanium pentoxide (Ti₃O₅), titanium oxide (TiO), titanium dioxide (TiO₂), tungsten oxide (WO₃), yttrium oxide (Y₂O₃), yttrium fluoride (YF₃), zinc sulfide (ZnS), zirconium dioxide (ZrO₂), and indium oxide (In₂O₃).

In the present modification example, the protective layer 16 is provided on the infrared absorption layer 15, which makes it possible to reduce occurrence of decomposition and alteration of the material configuring the infrared absorption layer 15 resulting from an influence of light, oxygen, etc. This achieves, in addition to the effects in the foregoing embodiment, an effect that it is possible to stably obtain superior imaging performance for a long period.

### 2-2. Modification Example 2

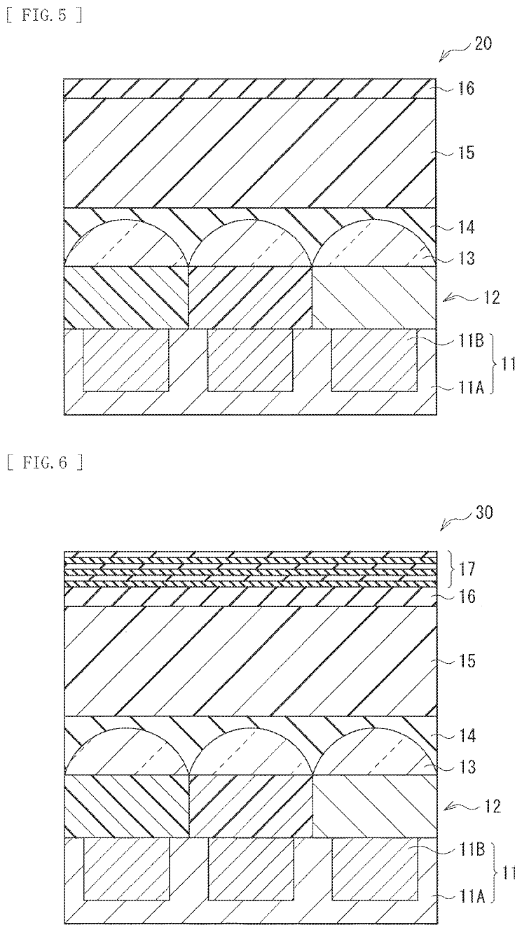

FIG. 6 illustrates a cross-sectional configuration of a solid-state imaging element (a solid-state imaging element 30) according to the modification example 2 of the present disclosure. The solid-state imaging element 30 is different from the first embodiment and the modification example 1 mentioned above in that a light antireflection layer 17 is provided in an uppermost layer on a side on which a light incident surface is located, for example, on the protective layer 16. It is to be noted that the protective layer 16 may not be provided as necessary. In this case, the light antireflection layer 17 may be formed on the infrared absorption layer 15.

High refractive index materials forming the light antireflection layer 17 include TiO₂, Nb₂O₅, TiO₂, Nb₂O₅, CeO₂, Ta₂O₅, ZnO, ZrO₂, In₂O₃, SnO₂, HfO₂, etc. Only one of these high refractive index materials may be used, or a combination of two or more of these high refractive index materials may be used. Moreover, low refractive index materials include MgF₂, AlF₃, MgF₂, AlF₃, SiO₂, etc. Only one of these low refractive index materials may be used, or a combination of two or more of these low refractive index material may be used.

In general, in some cases, incident light on the solid-state imaging element is slightly reflected at an interface of each layer. In a case where light (reflected light) reflected by the interface reaches the photoelectric converter 11B, light that is not proper image-forming light enters the photoelectric converter 11B, which causes degradation in imaging characteristics.

In the present modification example, the light antireflection layer 17 is provided in the uppermost layer on the side on which the light incident surface is located of the solid-state imaging element 30, which makes it possible to reduce another reflection of the reflected light. This achieves, in addition to the effects in the embodiment and the modification example 1 mentioned above, an effect that it is possible to suppress degradation in imaging performance resulting from another reflection of the reflected light.

### 2-3. Modification Example 3

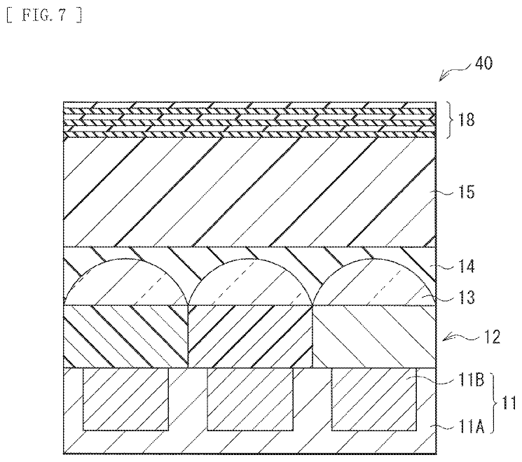

FIG. 7 illustrates a cross-sectional configuration of a solid-state imaging element (a solid-state imaging element 40) according to the modification example 3 of the present disclosure. The solid-state imaging element 40 is different from the foregoing first embodiment in that a band-pass layer 18 is provided on a side closer to the light incident surface than the infrared absorption layer 15. It is to be noted that even in the solid-state imaging element 40 according to the present modification example, the foregoing protective layer 16 may be provided. In this case, the protective layer 16 may be provided above the band-pass layer 18, or may be provided between the band-pass layer 18 and the infrared absorption layer 15. Moreover, in the solid-state imaging element 40 according to the present modification example, as with the foregoing modification example 2, the light antireflection layer 17 may be provided in the uppermost layer of the solid-state imaging element 40.

The band-pass layer 18 reflects (blocks) a part or the entirety of violet light and one or both of light with a shorter wavelength than the violet light and infrared light, and has a configuration in which first reflection layers including a high refractive index material and second reflection layers including a lower refractive index material than the first reflection layer are alternately stacked.

Herein, the high refractive index materials forming the first reflection layers include TiO₂, Nb₂O₅, TiO₂, Nb₂O₅, CeO₂, Ta₂O₅, ZnO, ZrO₂, In₂O₃, SnO₂, HfO₂, etc. Only one of these high refractive index materials may be used, or a combination of two or more of these high refractive index materials may be used. Moreover, the low refractive index materials forming the second reflection layers include MgF₂, AlF₃, MgF₂, AlF₃, SiO₂, etc. Only one of these low refractive index materials may be used, or a combination of two or more of these low refractive index materials may be used. It is to be noted that the numbers of first reflection layers and second reflection layers that are stacked are not particularly limited, and it is possible to appropriately set the numbers in accordance with demanded performance.

In the present modification example, the band-pass layer 18 is provided on the infrared absorption layer 15 of the solid-state imaging element 40, which makes it possible to remove an infrared light component from the incident light in the band-pass layer 18 together with the infrared absorption layer 15. The band-pass layer 18 uses interference of light in a multilayer film; therefore, in some cases, a shift of a transmitted wavelength occurs depending on an incident angle of the incident light. Even in such a case, the infrared absorption layer 15 that does not cause the shift of the transmitted wavelength in principle makes it possible to maintain a transmitted wavelength band, thereby maintaining superior imaging performance.

### 2-4. Modification Example 4

FIG. 8 illustrates a cross-sectional configuration of a solid-state imaging element (a solid-state imaging element 50) according to the modification example 4 of the present disclosure. The solid-state imaging element 50 is different from the foregoing first embodiment in that the solid-state imaging element 50 includes a supporting substrate 21 that supports the infrared absorption layer 15 and the infrared absorption layer 15 is stacked on the planarization layer 15 with an adhesive layer 22 in between. It is to be noted that even in the present modification example, the protective layer 16 in the foregoing modification example 1, the light antireflection layer 17 in the modification example 17, and the band-pass layer 18 in the modification example 3 may be provided.

The supporting substrate 21 includes a material having enough strength to support the infrared absorption layer 15, and transparency such as, for example, glass, quartz, and a transparent resin sheet including PET, TED, etc.

The adhesive layer 22 bonds the planarization layer 14 and the infrared absorption layer 15 together, and is formable using a material having transparency. Examples of the material of the adhesive layer 22 include a synthetic resin.

In the present modification example, the infrared absorption layer 15 is formed on a side on which the supporting substrate 21 is located; therefore, it is possible to manufacture the infrared absorption layer 15 in a process different from other layers, which improves manufacturing flexibility.

### 3. SECOND EMBODIMENT

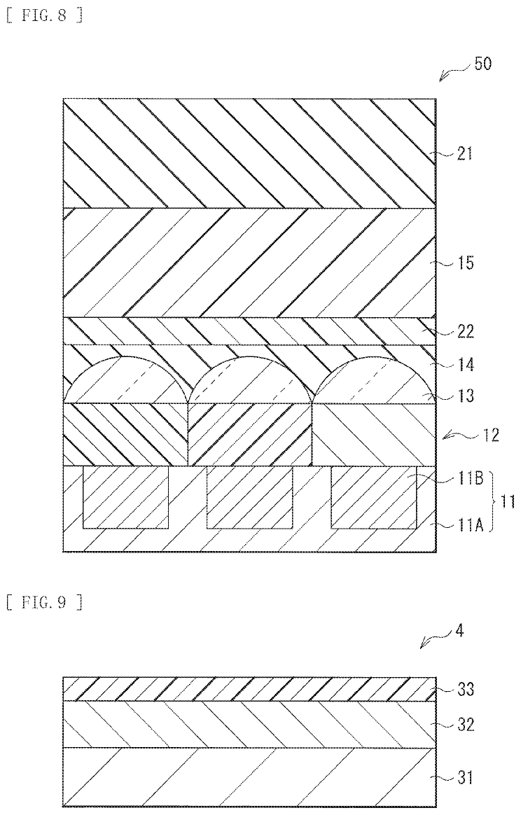

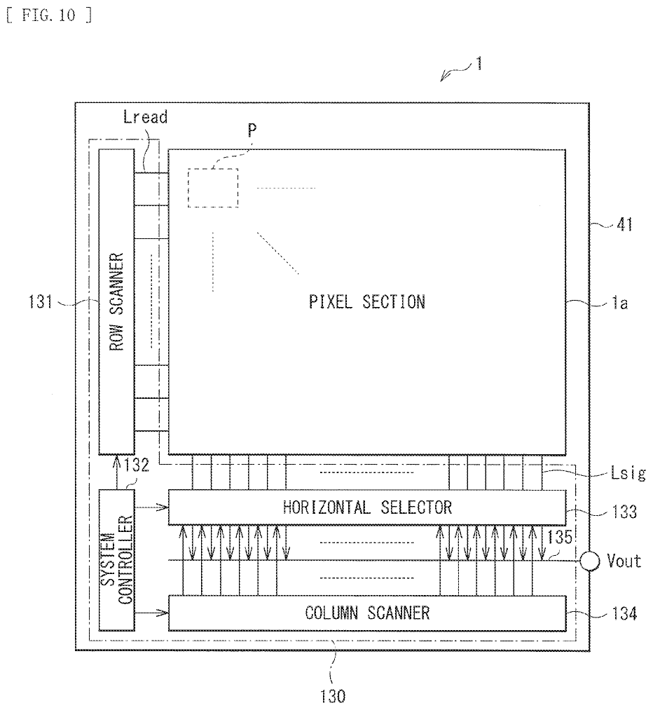

FIG. 9 illustrates a cross-sectional configuration of a reversible recording medium (a reversible recording medium 4) according to a second embodiment of the present disclosure. In the reversible recording medium 4, for example, a recording layer 32 as a display medium that is allowed to reversibly record or erase information by heat is provided on a supporting substrate 31. A protective layer 33 is stacked on the recording layer 32. It is to be noted that FIG. 9 schematically illustrates the configuration of the reversible recording medium 4 and dimensions and shape thereof are different from actual ones in some cases.

### 3-1. Configuration of Reversible Recording Medium

For the supporting substrate 31, a known material having superior heat resistance and high dimension stability in a planar direction is usable as appropriate, and the supporting substrate 31 includes, for example, an inorganic material, a metal material, a plastic material, or the like. Examples of the inorganic material include silicon (Si), silicon oxide (SiOx), silicon nitride (SiNx), aluminum oxide (AlOx), etc. Silicon oxide encompasses glass, spin-on glass (SOG), etc. Examples of the metal material include aluminum (Al), nickel (Ni), stainless steel, etc. Examples of the plastic material include polycarbonate (PC), polyethylene terephthalate (PET), polyethylene naphthalate (PEN), polyethyletherketone (PEEK), etc.

The supporting substrate 31 may have light transparency or light non-transparency. An image is displayed on a side on which the protective layer 33 is located; therefore the supporting substrate 31 does not necessarily have light transparency. The supporting substrate 31 may be a substrate having rigidity such as a wafer, or may include a thin layer glass or film, etc. having flexibility. Using a flexible material for the supporting substrate 31 makes it possible to achieve a flexible (foldable) reversible recording medium. It is to be noted that using a material having high reflectivity with respect to visible light having white or a metal color for the supporting substrate 31 makes it possible to improve visibility upon recording of information.

The recording layer 32 is allowed to reversibly record and erase information, and is formed using, for example, a material that is allowed to reversibly control, for example, a color reaction (coloring) state or a decoloring state by heat. Specifically, for example, the recording layer 32 is formed using, for example, a polymer material including a coloring compound, a photothermal conversion material, and a color developing/reducing agent. The polymer material is preferably a polymer material that allows the coloring compound, the photothermal conversion material, and the color developing/reducing agent to be easily and uniformly dispersed therein. Specific examples of the polymer material include polyvinyl chloride, polyvinyl acetate, a vinyl chloride-vinyl acetate copolymer, ethyl cellulose, polystyrene, a styrene-based copolymer, a phenoxy resin, polyester, aromatic polyester, polyurethane, polycarbonate, polyacrylic acid ester, polymethacrylic acid ester, acrylic acid-based copolymer, a maleic acid-based polymer, polyvinyl alcohol, modified polyvinyl alcohol, hydroxyethyl cellulose, carboxymethyl cellulose, starch, etc.

Examples of the coloring compound include a leuco dye. Examples of the leuco dye include an existing dye for thermal paper. Specific examples thereof include a compound, represented by the following formula (10), that includes a group having, for example, an electron donation property in a molecule.

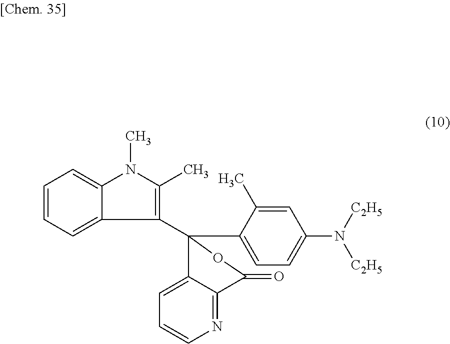 [SMILES: CCN(CC)c1ccc(C2(c3c(C)n(C)c4ccccc34)OC(=O)c3ncccc32)c(C)c1]

For example, the color developing/reducing agent colors a colorless coloring compound or decolors a coloring compound having an optional color. The color developing/reducing agent is a phenol derivative, a salicylic acid derivative, a urea derivative, etc. A specific example thereof is a compound, represented by the following general formula (11), that includes a group having an electron accepting property in a molecule.

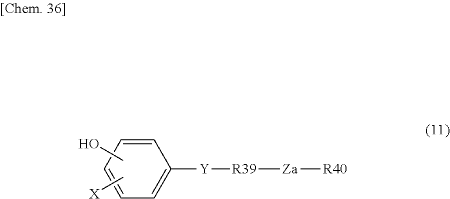

(where X is H, OH, COOH, or a halogen, Y is —NHCO—, —CONH—, —NHCONH—, —CONHCO—, —NHNHCO—, —CONHNH—, —CONHNHCO—, —NHCOCONH—, —NHCONHCO—, —CONHCONH—, —NHNHCONH—, —NHCONHNH—, —CONHNHCONH—, —NHCONHNHCO—, or —CONHNHCONH—, each of R39 and R40 is independently a hydrocarbon group having a carbon number of 2 to 26, the total carbon number in R39 and R40 is from 9 to 30 both inclusive, Z is one of —COO—, —OCO—, —O—, —CONH—, —NHCO—, —NHCONH—, —NHNHCO—, —CONHNH—, and —CH(CₙH₂ₙOH)— (where n=0 to 5), and a is 0 or 1.)

The photothermal conversion material absorbs light in a specific wavelength region (e.g. laser light) to convert the light into heat. As the photothermal conversion material, for example, an infrared absorbing dye that hardly absorbs the visible region is preferably used not to impair coloring of the coloring compound. Moreover, the photothermal conversion material preferably has enough ruggedness not to decompose the photothermal conversion material itself during photothermal conversion. Specifically, the photothermal conversion material is the squarylium compound represented by the foregoing general formula (1) or (2) described in the foregoing first embodiment.

It is to be noted that the recording layer 32 may include various kinds of additives such as a sensitizer and an ultraviolet absorbing agent in addition to the coloring compound, the photothermal conversion material, and the color developing/reducing agent. The sensitizer reduces a decoloring temperature to improve erase sensitivity, or reduces a coloring temperature to improve recording sensitivity, and allows for coloring and decoloring at lower energy.

The protective layer 33 protects a surface of the recording layer 32, and is formable using, for example, a known ultraviolet curing resin or a thermosetting resin. A thickness of the protective layer 33 is preferably, for example, from 0.1 μm to 20 μm both inclusive, and further desirably from 0.5 μm to 5 μm both inclusive. It is because if the protective layer 33 is too thin, a sufficient protection effect is not achieved, and if the protective layer 33 is too thick, heat is less prone to be transferred.

### 3-2. Workings and Effects

In the present embodiment, as the photothermal conversion material configuring the recording layer 32 of the reversible recording medium 4, the squarylium compound represented by the foregoing general formula (1) or (2) is used. The squarylium compound represented by the general formula (1) or (2) has a low absorption property in the visible region, that is, high transparency with respect to a wavelength region to be absorbed by the coloring compound, as described above, which makes it possible to improve display performance of the reversible recording medium 4.

Moreover, the squarylium compound having a group that is able to form a hydrogen bond in a molecule at one or both of R1 and R10 in the general formula (1) or the squarylium compound having a group that is able to form a hydrogen bond in a molecule at one or more of R19, R27, R28, and R36 in the general formula (2) has transparency in the visible region and high heat resistance, as described above. Accordingly, using, as the photothermal conversion material, the squarylium compound having a group that is able to form a hydrogen bond in a molecule at one or both of R1 and R10 in the general formula (1) or the squarylium compound having a group that is able to form a hydrogen bond in a molecule at one or more of R19, R27, R28, and R36 in the general formula (2) makes it possible to improve durability of the reversible recording medium 4.

Further, both the squarylium compounds represented by the general formulas (1) and (2) hold promise as the photothermal conversion material; however, the squarylium compound represented by the general formula (2) is more desirable. In a typical squarylium compound, it is difficult to shift a main absorption peak position to, for example, a wavelength equal to or longer than 850 nm while maintaining transparency in the visible region. In contrast, the squarylium compound represented by the general formula (2) easily shifts the main absorption peak position to a longer wavelength. Accordingly, using the squarylium compound represented by the general formula (2) as the photothermal conversion material configuring the recording layer 32 of the reversible recording medium 4 according to the present embodiment makes it possible to improve flexibility of wavelength selection of a laser used for recording or erase.

### 4. APPLICATION EXAMPLES

The solid-state imaging elements 10 to 50 described in the first embodiment and the modification examples 1 to 4 described above are applicable to a solid-state imaging device 1 to be described later and an electronic apparatus 2 (e.g. a camera) etc. that includes an imaging device. Moreover, the infrared absorption layer 15 used for the solid-state imaging elements 10 to 50 may be applicable as not only an optical filter in, for example, a plasma display 3 to be described later but also, for example, a heat-ray shielding film.

### Application Example 1

FIG. 10 illustrates an entire configuration of an solid-state imaging device (the solid-state imaging device 1) using any of the solid-state imaging elements 10 to 50 described in the foregoing embodiments etc. as each of unit pixels P. The solid-state imaging device 1 is a CMOS image sensor, and includes a pixel section 1a as an imaging region and a peripheral circuit section 130 in a peripheral region of the pixel section 1a on a semiconductor substrate (a substrate 41). The peripheral circuit section 130 includes, for example, a row scanner 131, a horizontal selector 133, a horizontal selector 133, and a system controller 132.

The pixel section 1a includes, for example, a plurality of unit pixels P (each corresponding to the solid-state imaging device 1) that are two-dimensionally arranged in rows and columns. The unit pixels P are wired with pixel driving lines Lread (specifically, row selection lines and reset control lines) for respective pixel rows, and are wired with vertical signal lines Lsig for respective pixel columns. The pixel driving lines Lread transmit drive signals for signal reading from the pixels. The pixel driving lines Lread each have one end coupled to a corresponding one of output terminals, corresponding to the respective rows, of the row scanner 131.

The row scanner 131 includes a shift register, an address decoder, etc., and is, for example, a pixel driver that drives the respective unit pixels P of the pixel section 1a on a row basis. Signals outputted from the respective unit pixels P of a pixel row selected and scanned by the row scanner 131 are supplied to the horizontal selector 133 through the respective vertical signal lines Lsig. The horizontal selector 133 includes, for example, an amplifier, a horizontal selection switch, etc. that are provided for each of the vertical signal lines Lsig.

The horizontal selector 133 includes a shift register, an address decoder, etc., and drives the respective horizontal selection switches of the horizontal selector 133 in order while sequentially performing scanning of those horizontal selection switches. Such selection and scanning performed by the horizontal selector 133 allow the signals of the respective pixels transmitted through the respective vertical signal lines Lsig to be sequentially outputted to a horizontal signal line 135. The thus-outputted signals are transmitted to outside of the substrate 41 through the horizontal signal line 135.

A circuit portion including the row scanner 131, the horizontal selector 133, a column scanner 134, and the horizontal signal line 135 may be provided directly on the substrate 41, or may be disposed in an external control IC. Alternatively, the circuit portion may be provided in any other substrate coupled by means of a cable or the like.

The system controller 132 receives a clock supplied from the outside of the substrate 41, data on instructions of operation modes, and the like, and outputs data such as internal information of the solid-state imaging device 1. Furthermore, the system controller 132 includes a timing generator that generates various timing signals, and performs drive control of peripheral circuits such as the row scanner 131, the horizontal selector 133, and the horizontal selector 133 on the basis of the various timing signals generated by the timing generator.

### Application Example 2

The foregoing solid-state imaging device 1 is applicable to various kinds of electronic apparatuses having imaging functions. Examples of the electronic apparatuses include camera systems such as digital still cameras and video cameras, mobile phones having imaging functions, and the like. FIG. 11 illustrates, for purpose of an example, a schematic configuration of an electronic apparatus 2 (a camera). The electronic apparatus 2 is, for example, a video camera that allows for shooting of a still image or a moving image. The electronic apparatus 2 includes the solid-state imaging device 1, an optical system (an optical lens) 210, a shutter device 211, a driver 213, and a signal processor 212. The driver 213 drives the solid-state imaging device 1 and the shutter device 211.

The optical system 210 guides image light (incident light) from an object toward the pixel section 1a of the solid-state imaging device 1. The optical system 210 may include a plurality of optical lenses. The shutter device 211 controls a period in which the solid-state imaging device 1 is irradiated with the light and a period in which the light is blocked. The driver 213 controls a transfer operation of the solid-state imaging device 1 and a shutter operation of the shutter device 211. The signal processor 212 performs various signal processes on signals outputted from the solid-state imaging device 1. A picture signal Dout having been subjected to the signal processes is stored in a storage medium such as a memory, or is outputted to a monitor or the like.

### Application Example 3

Moreover, the infrared absorption layer 15 described in the foregoing embodiments may be used, for example, as an infrared cut filter (IR cut filter) used for a plasma display unit (a plasma display 3). FIG. 12 illustrates a schematic configuration of the plasma display 3. The plasma display 3 mainly includes, for example, a display panel 55, an A/D converter 51, an image memory 52, a sustain driver 53, and a data driver 54. The A/D converter 51 performs A/D conversion on an inputted image signal SV to generate image data DV. The image memory 52 stores the generated image data DV. The sustain driver 53 outputs a driving pulse to the display panel 55. Herein, for simplification, an unillustrated timing controller performs timing control on operations of the A/D converter 51, the image memory 52, the sustain driver 53, and the data driver 54.

### 5. EXAMPLES

Next, examples of the present disclosure are described. First, an infrared absorption ink in which the squarylium compound represented by the foregoing formula (1-7) and a polycarbonate resin were dissolved and mixed in cyclopentanone was prepared. This ink was applied onto a glass substrate with use of a spin coater, and thereafter, was dried by heating to form an infrared absorption layer having a film thickness of 5 μm as a sample (an experimental example 1). In addition, as materials of the infrared absorption layer, a squarylium compound represented by the following formula (6) (an experimental example 2), the squarylium compound represented by the foregoing formula (3-3) (an experimental example 3), and squarylium compounds represented by the following formulas (7) to (9) (experimental examples 4 to 6) were used to form infrared absorption layers as samples (the experimental examples 2 to 6) by a method similar to the method described above.

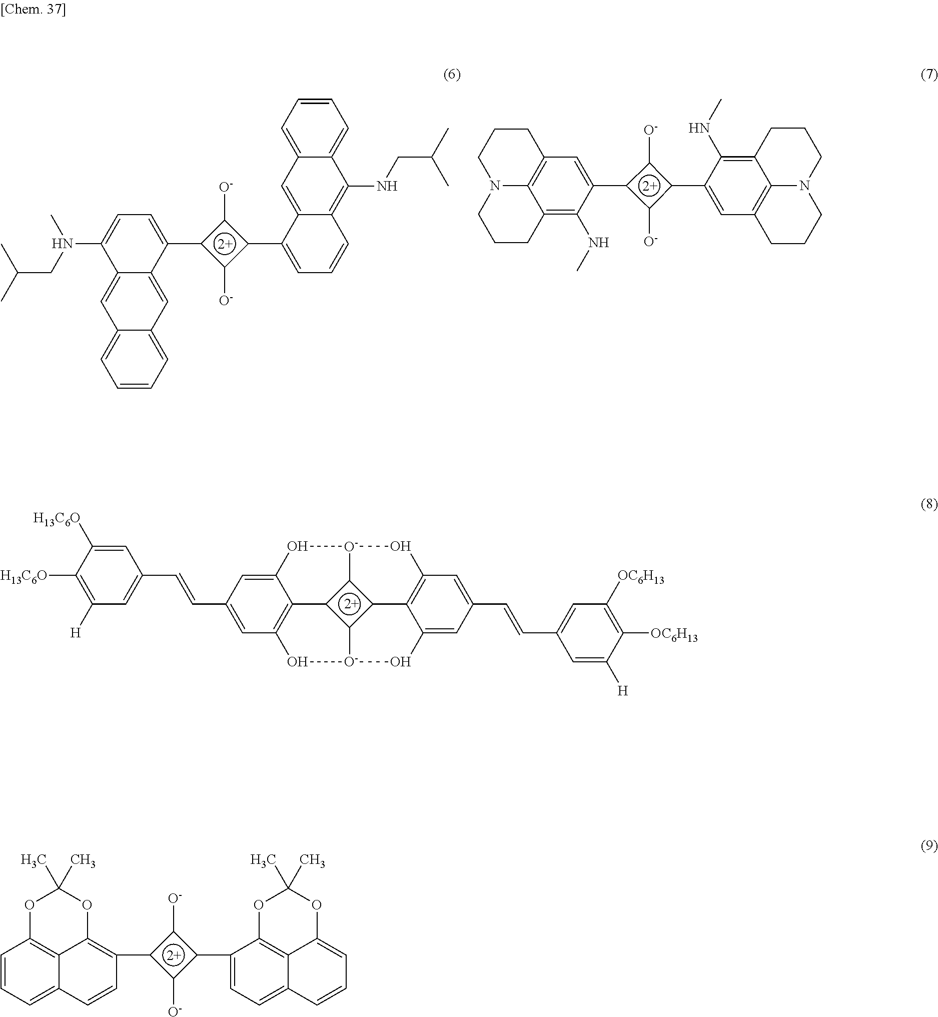

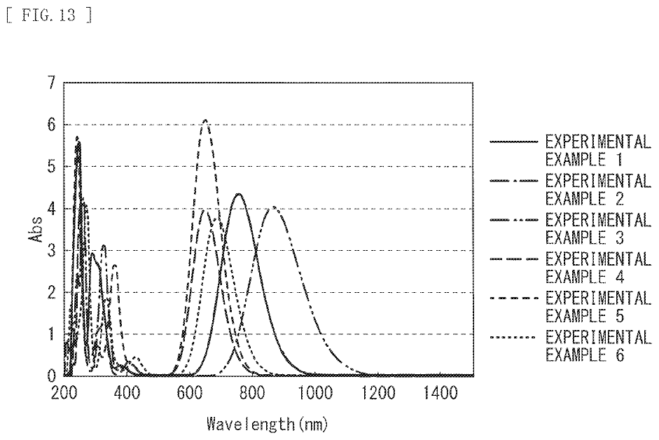

Light absorption spectra of the infrared absorption layers in the experimental examples 1 to 6 were measured with use of a ultraviolet-visible-near infrared spectroscopic altimeter to evaluate transparency in the visible region (maximum light absorbance in the visible region with respect to maximal light absorbance in the infrared region; an absorption intensity ratio). FIG. 13 illustrates light absorption characteristics at respective wavelengths in the experimental examples 1 to 6, and Table 1 summarizes constituent materials of the infrared absorption layers and absorption intensity ratios in the experimental examples 1 to 6.

TABLE 1

| | Configuration of | | Absorption |
|---|---|---|---|
| | Photoelectric | | Intensity |
| | Conversion Layer | | Ratio |
| Experimental Example 1 | Formula | (1-7) | 0.036 |
| Experimental Example 2 | Formula | (6) | 0.039 |
| Experimental Example 3 | Formula | (3-3) | 0.034 |
| Experimental Example 4 | Formula | (7) | 0.090 |
| Experimental Example 5 | Formula | (8) | 0.059 |
| Experimental Example 6 | Formula | (9) | 0.123 |

As can be seen from Table 1, in photoelectric converters (the experimental examples 1 to 3) that included the infrared absorption layer formed using the squarylium compound in which first and third sites of a squaric acid were substituted by an anthracene derivative, the absorption intensity ratio was largely reduced, as compared with the experimental examples 4 to 6. In other words, it was found that an infrared absorption layer having reduced absorption characteristics in the visible region and improved transparency in the visible region was obtained by using the squarylium compound in which the first and third sites of the squaric acid were substituted by the anthracene derivative.

Although the description has been given by referring to the first and second embodiments, the modification examples 1 to 4, and the examples, the contents of the present disclosure are not limited thereto, and may be modified in a variety of ways. For example, in the solid-state imaging element 30 described in the modification example 2, any other layer such as a coating layer may be provided without impairing effects of the light antireflection layer 17.

Moreover, the foregoing embodiments, etc. involve, as the solid-state imaging element 10, an example in which the respective photoelectric converters 11B individually detect red light (R), green light (G), and blue light (B), but are not limited thereto. A vertical spectroscopic type solid-state imaging element that extracts signals of B/G/R separately from one pixel may be used.

Further, it may not be necessary for the solid-state imaging elements 10 to 50 and the reversible recording medium 4, etc. of the present disclosure to include all components described in the foregoing embodiments. Alternatively, the solid-state imaging elements 10 to 50 and the reversible recording medium 4, etc. of the present disclosure may include any other layer. In the reversible recording medium 4, for example, a plurality of recording layers 32 may be stacked. In addition, for example, any other layer such as a thermal insulating layer may be provided between the plurality of recording layers.

It is to be noted that the effects described in the present specification are illustrative and non-limiting, and other effects may be included.

It is to be noted that the present disclosure may have the following configurations.

[1]

An optical filter including one or more kinds of squarylium compounds represented by the following general formula (1) or the following general formula (2),

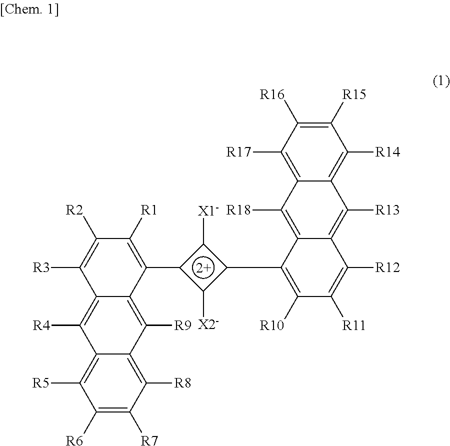

(where each of X1 and X2 is independently an oxygen atom or a dicyanomethylene (—C(CN)₂) group, each of R3 and R12 is independently a straight-chain or cyclic alkyl group having a carbon number of 1 to 8 both inclusive or a derivative thereof, each of R4, R5, R13, and R14 is independently a hydrogen atom, a straight-chain or cyclic alkyl group having a carbon number of 1 to 10 both inclusive, or a derivative thereof, each of R1, R2, R6 to R11, and R15 to R18 is independently a hydrogen atom, a halogen atom, a straight-chain, branched, or cyclic alkyl group, a phenyl group, a group having a straight-chain or condensed ring aromatic compound, a group having a halide, a partial fluoroalkyl group, a perfluoroalkyl group, a silylalkyl group, a silyl alkoxy group, an arylsilyl group, an arylsulfanyl group, an alkylsulfanyl group, an arylsulfonyl group, an alkylsulfonyl group, an arylsulfide group, an alkylsulfide group, an amino group, an alkylamino group, an arylamino group, a hydroxy group, an alkoxy group, an acylamino group, an acyloxy group, a carbonyl group, a carboxy group, a carboxyamide group, a carboalkoxy group, an acyl group, a sulfonyl group, a cyano group, a nitro group, a group having a chalcogenide, a phosphine group, a phosphone group, or a derivative thereof)

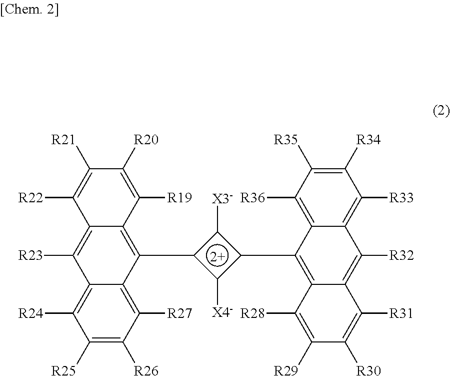

(where each of X3 and X4 is independently an oxygen atom or a dicyanomethylene (—C(CN)₂) group, each of R20 to R22, R24 to R26, R29 to R31, and R33 to R35 is independently a hydrogen atom, or a straight-chain or cyclic alkyl group having a carbon number of 1 to 10 both inclusive or a derivative thereof, each of R23 and R32 is independently a straight-chain or cyclic alkyl group having a carbon number of 1 to 10 both inclusive or a derivative thereof, each of R19, R27, R28, and R36 is independently an hydrogen atom, a halogen atom, a straight-chain, branched, or cyclic alkyl group, a phenyl group, a group having a straight-chain or condensed ring aromatic compound, a group having a halide, a partial fluoroalkyl group, a perfluoroalkyl group, a silylalkyl group, a silyl alkoxy group, an arylsilyl group, an arylsulfanyl group, an alkylsulfanyl group, an arylsulfonyl group, an alkylsulfonyl group, an arylsulfide group, an alkylsulfide group, an amino group, an alkylamino group, an arylamino group, a hydroxy group, an alkoxy group, an acylamino group, an acyloxy group, a carbonyl group, a carboxy group, a carboxyamide group, a carboalkoxy group, an acyl group, a sulfonyl group, a cyano group, a nitro group, a group having a chalcogenide, a phosphine group, a phosphone group, or a derivative thereof.)
[2]

The optical filter according to [1], in which one or both of R1 and R10 in the general formula (1) each are independently a group that is able to form a hydrogen bond.

[3]

The optical filter according to [2], in which the group that forms the hydrogen bond is a hydroxy (—OH) group, an amino (—NH₂) group, or amide (—C(═O)—NR37R38, where each of R37 and R38 is independently a hydrogen atom or an alkyl group).

[4]

The optical filter according to any one of [1] to [3], in which each of R3 and R12 of the squarylium compound represented in the general formula (1) is independently a group having a higher electron donation property than hydrogen (H).

[5]

The optical filter according to any one of [1] to [4], in which one or more of R19, R27, R28, and R36 in the general formula (2) each are independently a group that is able to form a hydrogen bond.

[6]

The optical filter according to [5], in which the group that forms the hydrogen bond is a hydroxy (—OH) group, an amino (—NH₂) group, or amide (—C(═O)—NR37R38, where each of R37 and R38 is independently a hydrogen atom or an alkyl group).

[7]

The optical filter according to any one of [1] to [6], in which each of R23 and R32 of the squarylium compound represented by the general formula (2) is independently a group further having an electron donation property.

[8]

The optical filter according to any one of [1] to [7], in which the squarylium compound represented by the general formula (1) or the general formula (2) has a maximal absorption amount in a range from 650 nm to 1500 nm both inclusive, and maximum light absorbance in a visible region (equal to or more than 400 nm and less than 600 nm) with respect to maximum light absorbance in an infrared region (from 600 nm to 1500 nm both inclusive) is less than 0.05.

[9]

The optical filter according to any one of [1] to [8], in which the squarylium compound represented by the general formula (1) or the general formula (2) and a binder resin are included.

[10]

The optical filter according to [9], in which the binder resin is a thermosetting or photocuring resin that does not have a maximal absorption wavelength in a range from 400 nm to 600 nm both inclusive.

[11]

The optical filter according to [9] or [10], in which the binder resin is a resin having a siloxane bond as a main backbone.

[12]

The optical filter according to any one of [1] to [11], further including one or more dyes having a maximal absorption wavelength different from that of the squarylium compound.

[13]

A solid-state imaging element, including:

a photoelectric converter;

an on-chip lens provided on the photoelectric converter; and

an optical filter provided on the on-chip lens and including one or more kinds of squarylium compounds represented by the following general formula (1) or the following general formula (2),

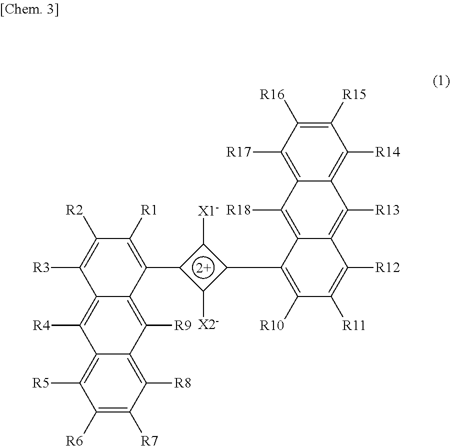

(where each of X1 and X2 is independently an oxygen atom or a dicyanomethylene (—C(CN)₂) group, each of R3 and R12 is independently a straight-chain or cyclic alkyl group having a carbon number of 1 to 8 both inclusive or a derivative thereof, each of R4, R5, R13, and R14 is independently a hydrogen atom, a straight-chain or cyclic alkyl group having a carbon number of 1 to 10 both inclusive, or a derivative thereof, each of R1, R2, R6 to R11, and R15 to R18 is independently a hydrogen atom, a halogen atom, a straight-chain, branched, or cyclic alkyl group, a phenyl group, a group having a straight-chain or condensed ring aromatic compound, a group having a halide, a partial fluoroalkyl group, a perfluoroalkyl group, a silylalkyl group, a silyl alkoxy group, an arylsilyl group, an arylsulfanyl group, an alkylsulfanyl group, an arylsulfonyl group, an alkylsulfonyl group, an arylsulfide group, an alkylsulfide group, an amino group, an alkylamino group, an arylamino group, a hydroxy group, an alkoxy group, an acylamino group, an acyloxy group, a carbonyl group, a carboxy group, a carboxyamide group, a carboalkoxy group, an acyl group, a sulfonyl group, a cyano group, a nitro group, a group having a chalcogenide, a phosphine group, a phosphone group, or a derivative thereof)

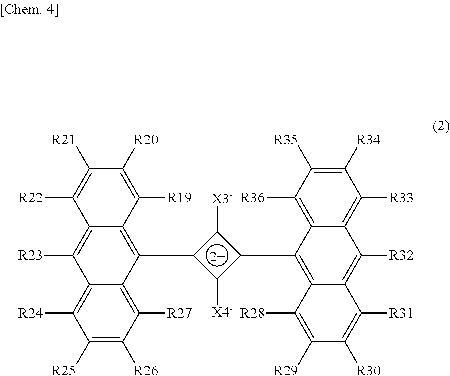

(where each of X3 and X4 is independently an oxygen atom or a dicyanomethylene (—C(CN)₂) group, each of R20 to R22, R24 to R26, R29 to R31, and R33 to R35 is independently a hydrogen atom, or a straight-chain or cyclic alkyl group having a carbon number of 1 to 10 both inclusive or a derivative thereof, each of R23 and R32 is independently a straight-chain or cyclic alkyl group having a carbon number of 1 to 10 both inclusive or a derivative thereof, each of R19, R27, R28, and R36 is independently an hydrogen atom, a halogen atom, a straight-chain, branched, or cyclic alkyl group, a phenyl group, a group having a straight-chain or condensed ring aromatic compound, a group having a halide, a partial fluoroalkyl group, a perfluoroalkyl group, a silylalkyl group, a silyl alkoxy group, an arylsilyl group, an arylsulfanyl group, an alkylsulfanyl group, an arylsulfonyl group, an alkylsulfonyl group, an arylsulfide group, an alkylsulfide group, an amino group, an alkylamino group, an arylamino group, a hydroxy group, an alkoxy group, an acylamino group, an acyloxy group, a carbonyl group, a carboxy group, a carboxyamide group, a carboalkoxy group, an acyl group, a sulfonyl group, a cyano group, a nitro group, a group having a chalcogenide, a phosphine group, a phosphone group, or a derivative thereof.)

[14]

The solid-state imaging element according to [13], in which the optical filter includes a first absorption layer and a second absorption layer that are stacked, the first absorption layer including the squarylium compound and the second absorption layer including a dye having a maximal absorption wavelength different from that of the squarylium compound.

[15]

The solid-state imaging element according to [13] or [14], in which a thickness of the optical filter is from 0.5 μm to 200 μm both inclusive.

[16]

An electronic apparatus provided with pixels each of which includes one or more solid-state imaging elements, the solid-state imaging elements each including:

a photoelectric converter;

an on-chip lens provided on the photoelectric converter; and

an optical filter provided on the on-chip lens and including one or more kinds of squarylium compounds represented by the following general formula (1) or the following general formula (2),

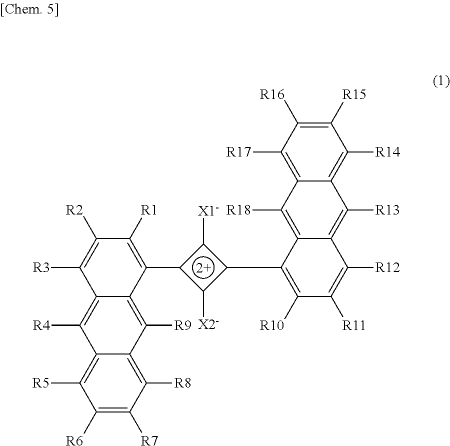

(where each of X1 and X2 is independently an oxygen atom or a dicyanomethylene (—C(CN)₂) group, each of R3 and R12 is independently a straight-chain or cyclic alkyl group having a carbon number of 1 to 8 both inclusive or a derivative thereof, each of R4, R5, R13, and R14 is independently a hydrogen atom, a straight-chain or cyclic alkyl group having a carbon number of 1 to 10 both inclusive, or a derivative thereof, each of R1, R2, R6 to R11, and R15 to R18 is independently a hydrogen atom, a halogen atom, a straight-chain, branched, or cyclic alkyl group, a phenyl group, a group having a straight-chain or condensed ring aromatic compound, a group having a halide, a partial fluoroalkyl group, a perfluoroalkyl group, a silylalkyl group, a silyl alkoxy group, an arylsilyl group, an arylsulfanyl group, an alkylsulfanyl group, an arylsulfonyl group, an alkylsulfonyl group, an arylsulfide group, an alkylsulfide group, an amino group, an alkylamino group, an arylamino group, a hydroxy group, an alkoxy group, an acylamino group, an acyloxy group, a carbonyl group, a carboxy group, a carboxyamide group, a carboalkoxy group, an acyl group, a sulfonyl group, a cyano group, a nitro group, a group having a chalcogenide, a phosphine group, a phosphone group, or a derivative thereof)

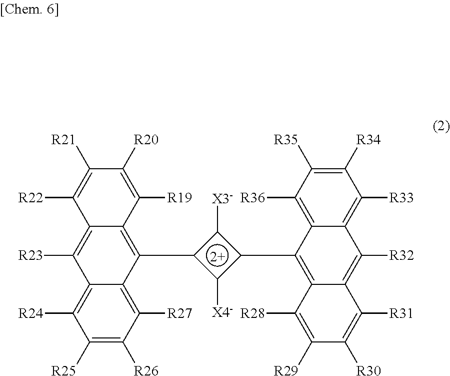

(where each of X3 and X4 is independently an oxygen atom or a dicyanomethylene (—C(CN)₂) group, each of R20 to R22, R24 to R26, R29 to R31, and R33 to R35 is independently a hydrogen atom, or a straight-chain or cyclic alkyl group having a carbon number of 1 to 10 both inclusive or a derivative thereof, each of R23 and R32 is independently a straight-chain or cyclic alkyl group having a carbon number of 1 to 10 both inclusive or a derivative thereof, each of R19, R27, R28, and R36 is independently an hydrogen atom, a halogen atom, a straight-chain, branched, or cyclic alkyl group, a phenyl group, a group having a straight-chain or condensed ring aromatic compound, a group having a halide, a partial fluoroalkyl group, a perfluoroalkyl group, a silylalkyl group, a silyl alkoxy group, an arylsilyl group, an arylsulfanyl group, an alkylsulfanyl group, an arylsulfonyl group, an alkylsulfonyl group, an arylsulfide group, an alkylsulfide group, an amino group, an alkylamino group, an arylamino group, a hydroxy group, an alkoxy group, an acylamino group, an acyloxy group, a carbonyl group, a carboxy group, a carboxyamide group, a carboalkoxy group, an acyl group, a sulfonyl group, a cyano group, a nitro group, a group having a chalcogenide, a phosphine group, a phosphone group, or a derivative thereof.)

This application claims the benefit of Japanese Priority Patent Application JP2015-253068 filed on Dec. 25, 2015 and Japanese Priority Patent Application JP2016-096163 filed on May 12, 2016, the entire contents of which are incorporated herein by reference.

It should be understood by those skilled in the art that various modifications, combinations, sub-combinations and alterations may occur depending on design requirements and other factors insofar as they are within the scope of the appended claims or the equivalents thereof.

1. An optical filter comprising one or more kinds of squarylium compounds represented by the following general formula (1) or the following general formula (2), 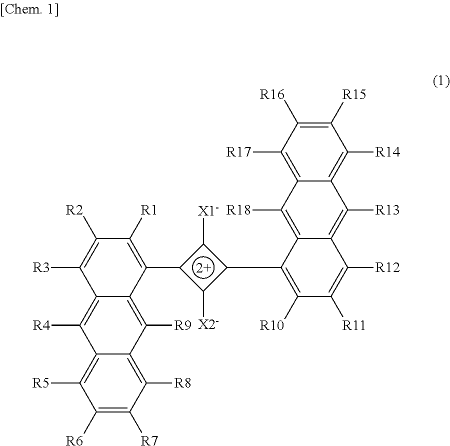
(where each of X1 and X2 is independently an oxygen atom or a dicyanomethylene (—C(CN)₂) group, each of R3 and R12 is independently a straight-chain or cyclic alkyl group having a carbon number of 1 to 8 both inclusive or a derivative thereof, each of R4, R5, R13, and R14 is independently a hydrogen atom, a straight-chain or cyclic alkyl group having a carbon number of 1 to 10 both inclusive, or a derivative thereof, each of R1, R2, R6 to R11, and R15 to R18 is independently a hydrogen atom, a halogen atom, a straight-chain, branched, or cyclic alkyl group, a phenyl group, a group having a straight-chain or condensed ring aromatic compound, a group having a halide, a partial fluoroalkyl group, a perfluoroalkyl group, a silylalkyl group, a silyl alkoxy group, an arylsilyl group, an arylsulfanyl group, an alkylsulfanyl group, an arylsulfonyl group, an alkylsulfonyl group, an arylsulfide group, an alkylsulfide group, an amino group, an alkylamino group, an arylamino group, a hydroxy group, an alkoxy group, an acylamino group, an acyloxy group, a carbonyl group, a carboxy group, a carboxyamide group, a carboalkoxy group, an acyl group, a sulfonyl group, a cyano group, a nitro group, a group having a chalcogenide, a phosphine group, a phosphone group, or a derivative thereof) 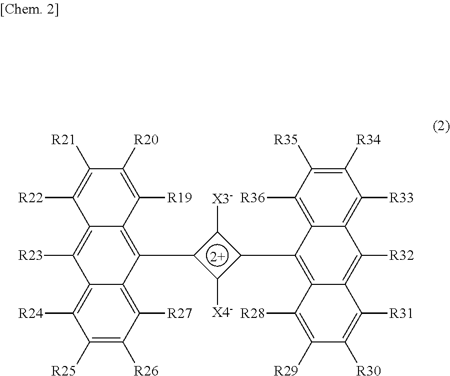
(where each of X3 and X4 is independently an oxygen atom or a dicyanomethylene (—C(CN)₂) group, each of R20 to R22, R24 to R26, R29 to R31, and R33 to R35 is independently a hydrogen atom, or a straight-chain or cyclic alkyl group having a carbon number of 1 to 10 both inclusive or a derivative thereof, each of R23 and R32 is independently a straight-chain or cyclic alkyl group having a carbon number of 1 to 10 both inclusive or a derivative thereof, each of R19, R27, R28, and R36 is independently an hydrogen atom, a halogen atom, a straight-chain, branched, or cyclic alkyl group, a phenyl group, a group having a straight-chain or condensed ring aromatic compound, a group having a halide, a partial fluoroalkyl group, a perfluoroalkyl group, a silylalkyl group, a silyl alkoxy group, an arylsilyl group, an arylsulfanyl group, an alkylsulfanyl group, an arylsulfonyl group, an alkylsulfonyl group, an arylsulfide group, an alkylsulfide group, an amino group, an alkylamino group, an arylamino group, a hydroxy group, an alkoxy group, an acylamino group, an acyloxy group, a carbonyl group, a carboxy group, a carboxyamide group, a carboalkoxy group, an acyl group, a sulfonyl group, a cyano group, a nitro group, a group having a chalcogenide, a phosphine group, a phosphone group, or a derivative thereof.)

2. The optical filter according to claim 1, wherein one or both of R1 and R10 in the general formula (1) each are independently a group that is able to form a hydrogen bond.

3. The optical filter according to claim 2, wherein the group that forms the hydrogen bond is a hydroxy (—OH) group, an amino (—NH₂) group, or amide (—C(═O)—NR37R38, where each of R37 and R38 is independently a hydrogen atom or an alkyl group).

4. The optical filter according to claim 1, wherein each of R3 and R12 of the squarylium compound represented in the general formula (1) is independently a group having a higher electron donation property than hydrogen (H).

5. The optical filter according to claim 1, wherein one or more of R19, R27, R28, and R36 in the general formula (2) each are independently a group that is able to form a hydrogen bond.

6. The optical filter according to claim 5, wherein the group that forms the hydrogen bond is a hydroxy (—OH) group, an amino (—NH₂) group, or amide (—C(═O)—NR37R38, where each of R37 and R38 is independently a hydrogen atom or an alkyl group).

7. The optical filter according to claim 1, wherein each of R23 and R32 of the squarylium compound represented by the general formula (2) is independently a group further having an electron donation property.

8. The optical filter according to claim 1, wherein the squarylium compound represented by the general formula (1) or the general formula (2) has a maximal absorption amount in a range from 650 nm to 1500 nm both inclusive, and maximum light absorbance in a visible region (equal to or more than 400 nm and less than 600 nm) with respect to maximum light absorbance in an infrared region (from 600 nm to 1500 nm both inclusive) is less than 0.05.

9. The optical filter according to claim 1, wherein the squarylium compound represented by the general formula (1) or the general formula (2) and a binder resin are included.

10. The optical filter according to claim 9, wherein the binder resin is a thermosetting or photocuring resin that does not have a maximal absorption wavelength in a range from 400 nm to 600 nm both inclusive.

11. The optical filter according to claim 9, wherein the binder resin is a resin having a siloxane bond as a main backbone.

12. The optical filter according to claim 1, further comprising one or more dyes having a maximal absorption wavelength different from that of the squarylium compound.

13. A solid-state imaging element, comprising:
a photoelectric converter;
an on-chip lens provided on the photoelectric converter; and
an optical filter provided on the on-chip lens and including one or more kinds of squarylium compounds represented by the following general formula (1) or the following general formula (2), 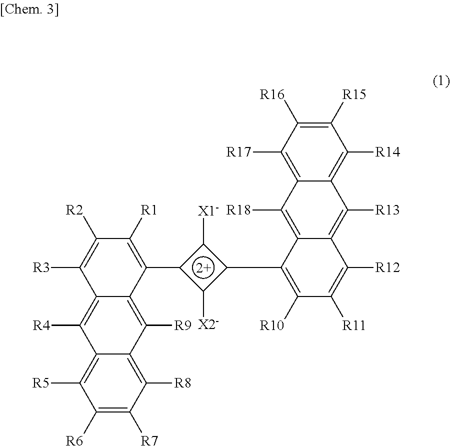
(where each of X1 and X2 is independently an oxygen atom or a dicyanomethylene (—C(CN)₂) group, each of R3 and R12 is independently a straight-chain or cyclic alkyl group having a carbon number of 1 to 8 both inclusive or a derivative thereof, each of R4, R5, R13, and R14 is independently a hydrogen atom, a straight-chain or cyclic alkyl group having a carbon number of 1 to 10 both inclusive, or a derivative thereof, each of R1, R2, R6 to R11, and R15 to R18 is independently a hydrogen atom, a halogen atom, a straight-chain, branched, or cyclic alkyl group, a phenyl group, a group having a straight-chain or condensed ring aromatic compound, a group having a halide, a partial fluoroalkyl group, a perfluoroalkyl group, a silylalkyl group, a silyl alkoxy group, an arylsilyl group, an arylsulfanyl group, an alkylsulfanyl group, an arylsulfonyl group, an alkylsulfonyl group, an arylsulfide group, an alkylsulfide group, an amino group, an alkylamino group, an arylamino group, a hydroxy group, an alkoxy group, an acylamino group, an acyloxy group, a carbonyl group, a carboxy group, a carboxyamide group, a carboalkoxy group, an acyl group, a sulfonyl group, a cyano group, a nitro group, a group having a chalcogenide, a phosphine group, a phosphone group, or a derivative thereof) 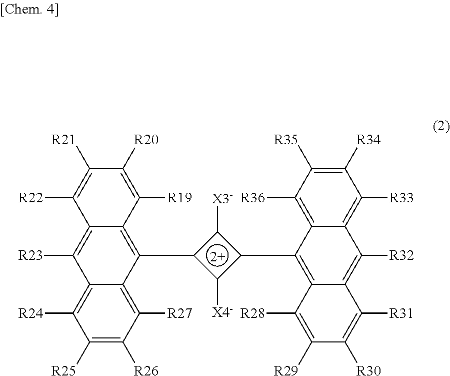
(where each of X3 and X4 is independently an oxygen atom or a dicyanomethylene (—C(CN)₂) group, each of R20 to R22, R24 to R26, R29 to R31, and R33 to R35 is independently a hydrogen atom, or a straight-chain or cyclic alkyl group having a carbon number of 1 to 10 both inclusive or a derivative thereof, each of R23 and R32 is independently a straight-chain or cyclic alkyl group having a carbon number of 1 to 10 both inclusive or a derivative thereof, each of R19, R27, R28, and R36 is independently an hydrogen atom, a halogen atom, a straight-chain, branched, or cyclic alkyl group, a phenyl group, a group having a straight-chain or condensed ring aromatic compound, a group having a halide, a partial fluoroalkyl group, a perfluoroalkyl group, a silylalkyl group, a silyl alkoxy group, an arylsilyl group, an arylsulfanyl group, an alkylsulfanyl group, an arylsulfonyl group, an alkylsulfonyl group, an arylsulfide group, an alkylsulfide group, an amino group, an alkylamino group, an arylamino group, a hydroxy group, an alkoxy group, an acylamino group, an acyloxy group, a carbonyl group, a carboxy group, a carboxyamide group, a carboalkoxy group, an acyl group, a sulfonyl group, a cyano group, a nitro group, a group having a chalcogenide, a phosphine group, a phosphone group, or a derivative thereof.)

14. The solid-state imaging element according to claim 13, wherein the optical filter includes a first absorption layer and a second absorption layer that are stacked, the first absorption layer including the squarylium compound and the second absorption layer including a dye having a maximal absorption wavelength different from that of the squarylium compound.

15. The solid-state imaging element according to claim 13, wherein a thickness of the optical filter is from 0.5 μm to 200 μm both inclusive.

16. An electronic apparatus provided with pixels each of which includes one or more solid-state imaging elements, the solid-state imaging elements each comprising:
a photoelectric converter;
an on-chip lens provided on the photoelectric converter; and
an optical filter provided on the on-chip lens and including one or more kinds of squarylium compounds represented by the following general formula (1) or the following general formula (2), 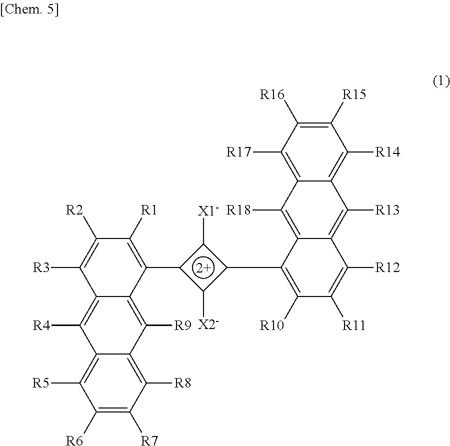
(where each of X1 and X2 is independently an oxygen atom or a dicyanomethylene (—C(CN)₂) group, each of R3 and R12 is independently a straight-chain or cyclic alkyl group having a carbon number of 1 to 8 both inclusive or a derivative thereof, each of R4, R5, R13, and R14 is independently a hydrogen atom, a straight-chain or cyclic alkyl group having a carbon number of 1 to 10 both inclusive, or a derivative thereof, each of R1, R2, R6 to R11, and R15 to R18 is independently a hydrogen atom, a halogen atom, a straight-chain, branched, or cyclic alkyl group, a phenyl group, a group having a straight-chain or condensed ring aromatic compound, a group having a halide, a partial fluoroalkyl group, a perfluoroalkyl group, a silylalkyl group, a silyl alkoxy group, an arylsilyl group, an arylsulfanyl group, an alkylsulfanyl group, an arylsulfonyl group, an alkylsulfonyl group, an arylsulfide group, an alkylsulfide group, an amino group, an alkylamino group, an arylamino group, a hydroxy group, an alkoxy group, an acylamino group, an acyloxy group, a carbonyl group, a carboxy group, a carboxyamide group, a carboalkoxy group, an acyl group, a sulfonyl group, a cyano group, a nitro group, a group having a chalcogenide, a phosphine group, a phosphone group, or a derivative thereof) 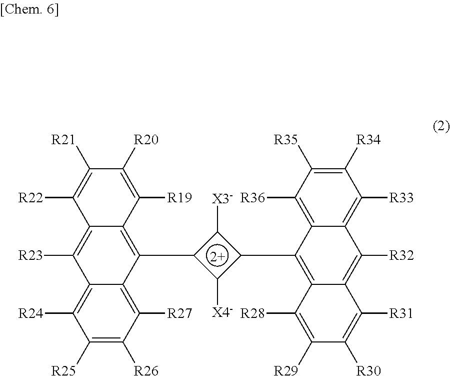
(where each of X3 and X4 is independently an oxygen atom or a dicyanomethylene (—C(CN)₂) group, each of R20 to R22, R24 to R26, R29 to R31, and R33 to R35 is independently a hydrogen atom, or a straight-chain or cyclic alkyl group having a carbon number of 1 to 10 both inclusive or a derivative thereof, each of R23 and R32 is independently a straight-chain or cyclic alkyl group having a carbon number of 1 to 10 both inclusive or a derivative thereof, each of R19, R27, R28, and R36 is independently an hydrogen atom, a halogen atom, a straight-chain, branched, or cyclic alkyl group, a phenyl group, a group having a straight-chain or condensed ring aromatic compound, a group having a halide, a partial fluoroalkyl group, a perfluoroalkyl group, a silylalkyl group, a silyl alkoxy group, an arylsilyl group, an arylsulfanyl group, an alkylsulfanyl group, an arylsulfonyl group, an alkylsulfonyl group, an arylsulfide group, an alkylsulfide group, an amino group, an alkylamino group, an arylamino group, a hydroxy group, an alkoxy group, an acylamino group, an acyloxy group, a carbonyl group, a carboxy group, a carboxyamide group, a carboalkoxy group, an acyl group, a sulfonyl group, a cyano group, a nitro group, a group having a chalcogenide, a phosphine group, a phosphone group, or a derivative thereof.)
